(19) United States
(12) Patent Application Publication
(10) Pub. No.: US 2026/0253150 A1
(43) Pub. Date: Aug. 27, 2026

(54) SYSTEMS AND METHODS FOR BUILDING MATERIAL DATA MANAGEMENT

(71) Applicant: Octagon I/O Ltd, London (GB)

(72) Inventors: Emidio Antonio Piermarini, London (GB); Kiran Singh, London (GB); Oliver Nicholas Bennet Greet, London (GB); Gideon Thorne Farrell, London (GB); Raphael Scheps, London (GB); Kyle Michael Scheps, London (GB); Djelal Osman, London (GB); James Innes, London (GB); James Louis Routledge, London (GB); Vlad Podgurschi, London (GB); Vivek Madhav, London (GB)

(73) Assignee: Octagon I/O Ltd, London (GB)

(21) Appl. No.: 19/644,548

(22) Filed: Apr. 10, 2026

Related U.S. Application Data
(63) Continuation of application No. PCT/US24/51001, filed on Oct. 11, 2024.
(60) Provisional application No. 63/544,091, filed on Oct. 13, 2023.
(60) Provisional application No. 63/605,990, filed on Dec. 4, 2023.
(60) Provisional application No. 63/663,989, filed on Jun. 25, 2024.
(60) Provisional application No. 63/669,054, filed on Jul. 9, 2024.
(60) Provisional application No. 63/670,047, filed on Jul. 11, 2024.

(51) Int. Cl. G06Q 50/08

(52) U.S. Cl. CPC G06Q 50/08

(57) ABSTRACT

Systems, computer program products, and methods are described herein for building material data management. With reference to an example method, the method receives a first dataset formed of first data entries associated with a building material data source and generates a building material data entity based on the building material data source. The method includes outputting a representation of the building material data entity. The first dataset may be formed of data records (e.g., construction documents, user inputs, sensor data, or machines data), and the representation may be a visual representation may include notifications, visual presentations of the building material entity, etc.

### CROSS-REFERENCE TO RELATED APPLICATIONS

The present application is a continuation of International Patent Application No. PCT/US24/51001, filed Oct. 11, 2024, which claims priority to U.S. Provisional Patent Application No. 63/544,091, filed Oct. 13, 2023, U.S. Provisional Patent Application No. 63/605,990, filed Dec. 4, 2023, U.S. Provisional Patent Application No. 63/663,989, filed Jun. 25, 2024, U.S. Provisional Patent Application No. 63/669,054, filed Jul. 9, 2024, and U.S. Provisional Patent Application No. 63/670,047, filed Jul. 11, 2024, the entire contents of which applications are incorporated by reference in their entirety.

### TECHNOLOGICAL FIELD

Example embodiments of the present disclosure relate generally to building materials, and more particularly, to systems and methods for building material data management.

### BACKGROUND

Data management, such as in the construction industry, often involves the management of various building materials (e.g., concrete, steel, glass, etc.) as well as their associated characteristics, properties, performance, and/or the like. For example, construction industry data management may include the management of concrete and/or other building materials as well as their performance (e.g., compressive strength, carbon impact, etc.). Existing methods for the management of such data are often manual and time-consuming. This leads to lags in defect discovery and errors in data reconciliation which can cause costly rework and waste. Through applied effort, ingenuity, and innovation, many of these identified problems have been solved by developing solutions that are included in embodiments of the present disclosure, many examples of which are described in detail herein.

### BRIEF SUMMARY

Embodiments of the present disclosure therefore provide for methods, systems, apparatuses, and computer program products for building material data management. With reference to an example computer-implemented method for building material data management, the method may include receiving a first dataset comprising one or more first data entries. The first data series may be associated with a building material data source. The method may include generating a building material data entity based upon the first dataset associated with the building material data source. The method may further include outputting a representation of the building material data entity.

In some embodiments, receiving the first dataset includes ingesting a plurality of data records.

In some embodiments, the plurality of data records includes at least one of a construction document, a user input, sensor data, or machine data.

In some embodiments, the construction document includes at least one of a material data, delivery data, or a regulation data.

In some embodiments, the method further includes comparing material data of the building material data entity with one or more crush rules. In some embodiments, in an instance in which the material data fails to satisfy the one or more crush rules, the method may include generating a failure alert. In some embodiments, in an instance in which the material data satisfies the one or more crush rules, the method includes generating a passage alert. In some embodiments, in an instance in which the material data is within a warning threshold associated with the one or more crush rules, the method includes generating a warning alert.

In some embodiments, the building material data source includes a sensor device configured to generate data associated with the building material data source.

In some embodiments, the first dataset includes carbon data including an amount of carbon associated with a building material associated with the building material data source.

In some embodiments, the method further includes performing a data operation of the first dataset to generate the building material data entity.

In some embodiments, the method further includes receiving the first dataset including a construction document and receiving sensor data including sensor data from the building material data source.

In some embodiments, the method includes comparing the first dataset and a second dataset. In some embodiments, the first dataset includes the sensor data including the construction document. In some embodiments, the second dataset includes the sensor data from the building material data source. In some embodiments, the method includes generating the building material data entity based at least in part on the comparison.

In some embodiments, the data operation further includes a functional computation. In some embodiments, the functional computation includes at least one of data preparation including transforming the building material data entity from a first format to a second format, data association including generating linkages associated with the building material data entity, or data analysis including performing a statistical analysis on the building material data entity.

In some embodiments, the representation includes the data association of the building material data entity.

In some embodiments, the data analysis further includes deploying an artificial intelligence (AI) engine to perform the statistical analysis on the building material data entity.

In some embodiments, the representation includes the statistical analysis on the building material data entity performed by the AI engine.

In some embodiments, the representation includes the building material data entity.

In some embodiments, the representation includes generating a notification based on the building material data entity.

In some embodiments, the method further includes an AI agent configured to receive the first dataset including the one or more first data entries associated with the building material data source.

In some embodiments, the method further includes an AI agent configured to generate the building material data entity based upon the first dataset associated with the building material data source.

In another embodiment, a system for building material data management may include a building material data source, a processing device, and a non-transitory storage device containing instructions that, when executed by the processing device, causes the processing device to receive, via the processing device, a first dataset including one or more first data entries associated with the building material data source. In some embodiments, the system may generate, via the processing device, a building material data entity based upon the first dataset associated with the building material data source. In some embodiments, the system may output, via the processing device, a representation of the building material data entity.

In yet another embodiment, a computer program product for building material data management may include a non-transitory computer-readable medium including code causing an apparatus to receive a first dataset including one or more first data entries associated with a building material data source. In some embodiments, the computer program product may generate a building material data entity based upon the first dataset associated with the building material data source. In some embodiments, the computer program product may output a representation of the building material data entity.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having thus described embodiments of the disclosure in general terms, reference will now be made the accompanying drawings. The components illustrated in the figures may or may not be present in certain embodiments described herein. Some embodiments may include fewer (or more) components than those shown in the figures.

FIG. 1 illustrates an example system for building material data management in accordance with an embodiment of the present disclosure;

FIG. 2 illustrates a block diagram of example circuitry of a server that may be specifically configured in accordance with an example embodiment of the present disclosure;

FIG. 3 illustrates an example supply chain for generating a building material data entity in accordance with an example embodiment of the present disclosure;

FIG. 4 illustrates a process flow of outputting a representation of the building material data entity in accordance with an example embodiment of the present disclosure;

FIG. 5 illustrates a process flow of generating a building material data entity in accordance with an example embodiment of the present disclosure;

FIG. 6 illustrates a process flow of generating an alert based on comparing cube data with cube rules in accordance with an example embodiment of the present disclosure;

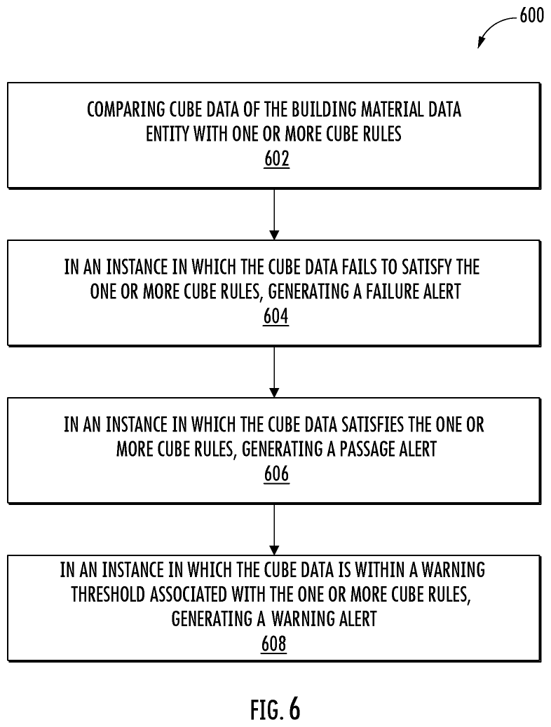

FIG. 7 illustrates a process flow of outputting a representation of carbon data in accordance with an example embodiment of the present disclosure;

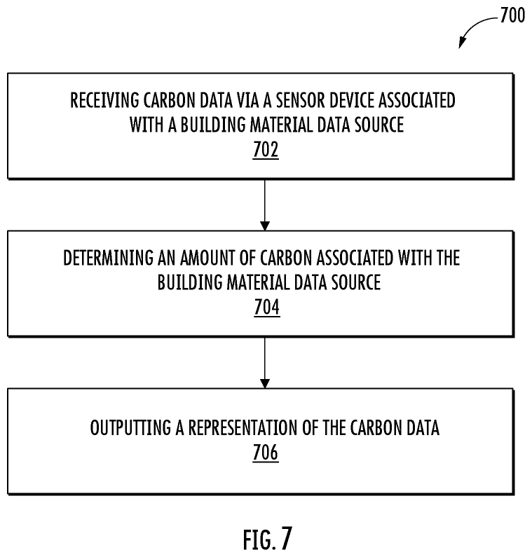

FIG. 8 illustrates a process for comparing a first dataset and a second dataset to generate a building material data entity in accordance with an embodiment of the present disclosure;

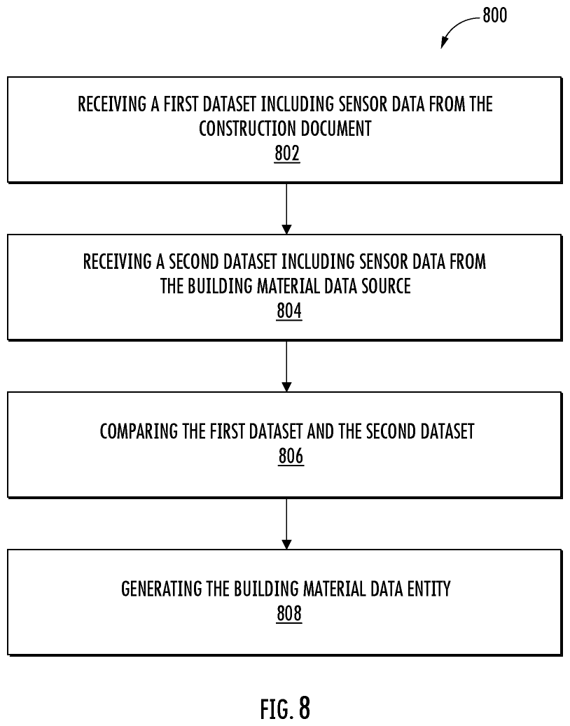

FIG. 9 illustrates an example embodiment of an overview of the disclosure as provided herein in accordance with an example embodiment of the present disclosure;

FIG. 10 illustrates an implementation of an artificial intelligence (AI) agent to perform one or more steps as provided herein in accordance with an example embodiment of the present disclosure;

FIG. 11 illustrates a comparison of a crush test result with a cube rule in accordance with an example embodiment of the present disclosure;

FIG. 12 illustrates generating a linkage between data in accordance with an example embodiment of the present disclosure;

FIG. 13 illustrates an example of a plurality of records in accordance with an example embodiment of the present disclosure;

FIG. 14 illustrates an embodied carbon calculation process in accordance with an example embodiment of the present disclosure;

FIG. 15A illustrates extracting a building material data entity from a plurality of records in accordance with an example embodiment of the present disclosure;

FIG. 15B illustrates structuring the building material data entity into a database in accordance with an example embodiment of the present disclosure;

FIG. 15C illustrates outputting the building material data entity in accordance with an example embodiment of the present disclosure;

FIG. 16A illustrates an overview of data extraction in accordance with an example embodiment of the present disclosure;

FIG. 16B illustrates an overview of data structuring in accordance with an example embodiment of the present disclosure;

FIG. 17 illustrates generating a direct match data linkage in accordance with an example embodiment of the present disclosure;

FIG. 18 illustrates a carbon optioneering process in accordance with an example embodiment of the present disclosure;

FIG. 19A illustrates determining embodied carbon by element and by waste in accordance with an example embodiment of the present disclosure;

FIG. 19B illustrates updating a database based on user input in accordance with an example embodiment of the present disclosure;

FIG. 19C illustrates outputting an embodied carbon by element in accordance with an example embodiment of the present disclosure;

FIG. 20A illustrates real time tracking of embodied carbon compared with a carbon budget in accordance with an example embodiment of the present disclosure;

FIG. 20B illustrates updating data with carbon budget information in accordance with an example embodiment of the present disclosure;

FIG. 20C illustrates displaying a representation of the carbon budget in accordance with an example embodiment of the present disclosure;

FIG. 21 illustrates an AI agent comparing one of the plurality of records to determine a predicted amount of embodied carbon in accordance with an example embodiment of the present disclosure;

FIG. 22A illustrates determining a total amount of embodied carbon in real time in accordance with an example embodiment of the present disclosure; and

FIG. 22B illustrates updating and outputting the total amount of embodied carbon in accordance with an example embodiment of the present disclosure.

### DETAILED DESCRIPTION

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

### Definitions

As described herein, a “user” may be an individual associated with a company, business, vendor, supplier, distributor, or the like. As such, in some embodiments, the user may be an individual having past relationships, current relationships or potential future relationships with a company. In some embodiments, the user may be an employee (e.g., a worker, a project manager, a manager, an administrator, an operations analyst, or the like) of the company or enterprises affiliated with the company. Further, the user may be employed, contracted, or otherwise associated with the company.

As used herein, the term “project” may refer to any physical construction forming part of the built environment at any stage of its existence, including but not limited to its conception, design, construction, operation, decommissioning, and demolition. Examples of a project include but are not limited to a bridge project, building project, tunnel project, or other commercial infrastructure or industrial project. As used herein, the term “site” may refer to any self-contained location associated with the project (e.g., a construction project), or a plurality of projects. For example, a site may refer to a jobsite, a precast factory, a batching plant, and/or the like without limitation.

As used herein, an “element” may refer to any discrete portion of a project, construction build, or the like, at any stage of its existence, including but not limited to its conception, design, construction, operation, decommissioning, demolition, or reuse. Examples of an element include but are not limited to a column, a slab, a façade, a wall, a beam, a floor, a subfloor, a ceiling, a foundation, a mechanical assembly, an electrical assembly, a plumbing assembly, or any other element that may be used and/or built during a construction project. Further, the element may include the use of one or more building materials to create and/or construct the element and may include the discrete building materials used in its construction. In this regard, reference to an element may include, but does not necessitate, reference to the building materials used in the element's construction. For example, when referencing data related to an element, the data may also include reference to the underlying building materials used to create the element. Further, the element may include the use of one or more plants, machinery, equipment and/or tools to create and/or construct the element and may include the discrete building materials used in its construction.

As used herein, a “material test result,” “material test record,” “crush result,” or “crush record” may include data associated with a testing of a material (e.g., an element, a building material). For instance, the testing associated with a material may include the testing of the material under mechanical tests, chemical tests, physical tests, durability tests, condition-based tests, and the like. In this way, the tests may produce data associated with the material relating to how well the material performed during the test. For example, a mechanical test may yield results relating to a compressive strength of a building material, which may be recorded in a crush record or result. It is to be understood that the materials tested to produce the material test results and records may include a variety of shapes, sizes, configurations, or the like, which allow for results that may or may not be specific to the shape, size, and configuration of the material. For example, concrete in the shape of a cube, cylinder, prism, and/or the like may be used during a crush result to gather data relating to not only the shape of the concrete, but also data relating to the performance of the concrete. Further, this may be true for other tests and other building materials, without limitation.

As used herein, “embodied carbon” may refer to the total amount of carbon dioxide associated with a building material, such as related to environmental impact. In this way, the carbon dioxide may include carbon dioxide, carbon equivalents, methane, or other materials or substances that produce greenhouse gases, associated with the building material's lifecycle, from production to transportation and installation. The embodied carbon may include the energy consumed during processes such as mining, excavation, refining, manufacturing, delivering, installing, and the like, the building material. Further, the embodied carbon may include carbon dioxide emissions that may be tangential to or otherwise related to the building material, such as embodied carbon associated with storing the building material (e.g., carbon produced by logistics associated with the storage of the building material). In this way, the embodied carbon of a building material may include the carbon footprint of the building material that is directly and indirectly related to the building material.

As used herein, an “Environmental Product Declaration” (EPD) is a standardized document that provides detailed information about the environmental impact of a building material throughout its entire lifecycle, as described above. In this way, the EPD may include data on aspects such as the embodied carbon, energy usage, water consumption, emissions generated during extraction, manufacturing, transport, use, and disposal of the building material. The EPD may follow standard framework and conform to international standards, such as ISO 14025. The EPD may allow for stakeholders to compare environmental performance metrics of different materials associated with a construction project.

As used herein, a “building material data source” may refer to any object, asset, device, system, etc. that may be used in the construction of a structure including the manufacturing, production or construction of any of its prefabricated components, readymix batches, or other constituent components). By way of a non-limiting example, a building material data source may refer to raw materials, composite materials, support structure or formwork, etc. used in the formation of structures. Additionally, a building material data source may refer to transportation devices or systems (e.g., trucks, cranes, etc.), manufacturing equipment or systems (e.g. precast ovens, production lines, batching machines), harvesting devices or systems (e.g., raw material related devices located at quarries or the like), and/or the personnel that operate these devices and systems. Furthermore, a building material data source may refer to the sensors, sensor devices, transducers and actuators used, in some embodiments, to perform the operations of the present disclosure. As such, the present disclosure contemplates that any of the assets described herein as associated with or otherwise related to the use of building materials to construct structures may be considered a building material data source, without limitation.

As used herein, the terms “first dataset” and associated “first data entries” are used to refer to data that, in some embodiments, is received by the systems, models, etc. of the present disclosure as an input. By way of a non-limiting example, the first dataset and/or first data entries may include data associated with various materials properties that are input by a user, generated by a sensor device (for example, a maturity or temperature sensor), other device, received from a database, received from a prior iteration of one or more of the models described herein, and/or the like, such as in the construction resource operations described herein.

As would be evident to one of ordinary skill in the art in light of the present disclosure, the first dataset and associated first data entries may be associated with, indicative of, or otherwise related to any of the attributes, characteristics, parameters, metrics, etc. of the construction or construction resource operations, systems, devices, etc. described herein without limitation. Said differently, the first dataset and associated first data entries may refer to the data structure by which data associated with the embodiments described herein is stored, regardless of data type, model used, system deployed, etc. The present disclosure further contemplates that additional datasets (e.g., a second dataset or the like) may include data entries associated with any of the same or different data types described herein with reference to the first dataset. In other words, the present disclosure contemplates that any number of different datasets of any type may be used by the embodiments herein.

As used herein, the terms “sensor,” “sensor device,” “transducer,” “smart device,” and “device” may be used interchangeably and/or collectively to refer to any hardware or circuitry component configured to generate data, such as first data entries, that is associated with a building material, construction resource, contextual awareness, and/or the like without limitation. As described hereinafter, a sensor device may include any relevant circuitry, components, etc. configured to generate data that is indicative of, for example, the material properties (e.g., static material properties, compositional material properties, contextual conditions, contextual material properties, etc.) of a building material. The present disclosure contemplates that each of the techniques, models, etc. of the present disclosure may be implemented with any number of the sensor and/or sensor devices and/or transducers and/or devices described herein, alone or in any combination.

As used herein, a “positioning device” may refer to as device that has capabilities (alone or as part of a system) to make positioning determinations or characterizations. A “gateway” may refer to a network connected device (e.g., Internet connected device, for example over LTE, 5G or NB-IoT) that is configured to locally communicate with beacons (over BLE, BLE Long Range, BLE Mesh, LoRa, Sigfox, and/or the like). A “beacon” may refer to a battery powered device that can send and receive wireless signals to other beacons and/or gateways and/or other devices (over BLE, BLE Long Range, LTE, GPRS, 2G/3G/4G/5G, NB-IoT, LoRa, Sigfox and so on). In some instances, beacons may not be directly connected to the internet. In some instances, a beacon may include a cellular interface). To this end, “global position” may refer to the position of a device with respect to a global frame of reference (e.g., a latitudinal and longitudinal location) while a “relative position” as used herein may refer to a location with respect to two or more construction resources, with respect to gridlines, and/or the like. The present disclosure contemplates that the delineation between construction resources, construction assets, and/or construction objects may vary based on the intended application of the systems described herein. In some embodiments, two or more construction resources may interact.

As used herein, a “user interface” may be a point of human-computer interaction and communication in a device that allows a user to input information, such as commands or data, into a device, or that allows the device to output information to the user. For example, the user interface includes a graphical user interface (GUI) or an interface to input computer-executable instructions that direct a processor to carry out specific functions. The user interface typically employs certain input and output devices such as a display, mouse, keyboard, button, touchpad, touch screen, microphone, speaker, LED, light, joystick, switch, buzzer, bell, and/or other user input/output device for communicating with one or more users.

As used herein, a “user device” may be a device capable of receiving an interaction from a human, a system (e.g., the system 100), a server (e.g., the server 130), another device, or the like. The user device (e.g., the user device 140) may include components to allow a user to interact with the user device. In this regard, the user device may include a user interface as described above. The user device may be equipped with components including, but not limited to, a processor, a memory, a storage device, an input/output device (such as a display), a communication interface, a transceiver, and the like. The components may be connected, interconnected, operatively coupled, or the like via various buses, cables, boards (e.g., motherboards), or in other manners as appropriate. In specific examples, the user device may include a mobile phone, a laptop, a computer, a tablet, a kiosk, a terminal, a scanner, a wearable, a GPS, a three dimensional printer, a smart sensor, or the like.

As used herein, an “interaction” may refer to any communication between one or more users, one or more companies or institutions, one or more devices, nodes, clusters, or systems within a distributed computing environment, as described herein. For example, an interaction may refer to a transfer of data between devices, an accessing of stored data by one or more nodes of a computing cluster, a transmission of a requested task, a transmission of a dataset, a transmission of a representation, or the like. Further, an interaction may refer to a discrete instance of an event occurring within a continuous time interval that may evolve the state or attribute of a construction project, building material, building material data entity, or the like. Examples of an interaction may include, but are not limited to, an operative or user driving a nail with a hammer, a tower crane liftin precast concrete, an excavator lifting a bucket of soil, a robot painting a wall, etc.

As used herein, the terms “data,” “content,” “information,” and similar terms may be used interchangeably to refer to data capable of being transmitted, received, and/or stored in accordance with embodiments of the present disclosure. Thus, use of any such terms should not be taken to limit the spirit and scope of embodiments of the present disclosure. Further, where a computing device is described herein as receiving data from another computing device, it will be appreciated that the data may be received directly from another computing device or may be received indirectly via one or more intermediary computing devices, such as, for example, one or more servers, relays, routers, network access points, base stations, hosts, and/or the like, sometimes referred to herein as a “network.” Similarly, where a computing device is described herein as sending data to another computing device, it will be appreciated that the data may be sent directly to another computing device or may be sent indirectly via one or more intermediary computing devices, such as, for example, one or more servers, relays, routers, network access points, base stations, hosts, and/or the like.

It should be understood that the word “exemplary” is used herein to mean “serving as an example, instance, or illustration.” Any implementation described herein as “exemplary” is not necessarily to be construed as advantageous over other implementations.

As used herein, “determining” may encompass a variety of actions. For example, “determining” may include calculating, computing, processing, deriving, investigating, ascertaining, and/or the like. Furthermore, “determining” may also include receiving (e.g., receiving information), accessing (e.g., accessing data in a memory), and/or the like. Also, “determining” may include resolving, selecting, choosing, calculating, establishing, and/or the like. Determining may also include ascertaining that a parameter matches a predetermined criterion, including that a threshold has been met, passed, exceeded, and so on.

As used herein, “wave-based sensor” may be used to refer to any device which may generate, adjust, or control a time-varying excitation (based on an input signal) and/or sense a response to an excitation including, but not limited to, of a target material, or another material coupled (directly or indirectly) to the target material. Such a wave-based sensor may be, used to generate or otherwise make use of and sense waves, excitations, and/or oscillations (such as electromagnetic waves, electric currents and/or mechanical stresses) as described herein. Furthermore, “wave-based” may refer to any device, technique, sensor, etc. that employs one or more actuators to excite a host material, or a second material that is coupled to the host material. The excitation may be a time varying signal (e.g., an oscillatory signal, a wave, etc.). Wave-based devices, techniques, and sensing may also employ sensors to measure the response of the host material (directly, or indirectly through the response of the second material, or another material coupled to the host material). For the avoidance of doubt, the “wave-based” techniques described herein may encompass, without limitation, excitations, oscillations, and waves, and may further encompass any device configured to take input signals and generate, adjust, control an excitation of a field, force, or form of energy, such as via an actuator defined herein, as well as a response (e.g., material response, coupled medium response, etc.) to such excitation, oscillation, or wave.

As used herein, an “entity,” “data entity,” or “building material data entity” may be a specific piece of information from the data source. The data source, for example, may be a building material data source. The building material data source may include a variety of data sources, including, but not limited to construction documentation, user input, sensor data, and the like. In this regard, and in some embodiments, the building material data source may be primarily from construction-based data sources. Further, the building materials may include concrete, raw materials for creating concrete (e.g., cementitious materials such as Portland cement and any green alternatives, aggregates, admixtures, etc.), steel, glass, and the like. In this regard, the building materials may include raw building materials used in a construction project. The building materials may be coupled together to create a semi-finished or finished project. Further, the building materials may be physically located at the construction project site, at a staging area (e.g., a warehouse), at a supplier of the building material, or at a manufacturer of the building material.

### Building Material Data Management Systems and Methods

As now will be described more fully herein, the disclosure presents systems and methods for building material data management. Conventional systems and methods of building material data management face several issues surrounding the disparate and fragmented nature of data sources, which may result in inefficiencies, data silos, and lack of real-time insights. Traditional systems often struggle to integrate data from various stages of a project's lifecycle, such as production, transportation, and installation of building materials, which may lead to issues surrounding material quality, compliance, and environmental impact monitoring. For instance, the lack of real-time updates in traditional systems may compound problems associated with embodied carbon data tracking, which may lead to compliance issues throughout the lifecycle of the completed project. As a result, stakeholders associated with the project often lack comprehensive and unified views of material performance, which may impede decision making and lead to delays and material quality shortfalls.

In order to solve these problems and others, the building material data management systems of the present disclosure provide for data ingestion, aggregation, analysis, and the like, in real time that ensures project updates are communicated in a timely manner. The solution as described herein may ingest data from a plurality of data sources (e.g., user input(s), records, building material data sources, and the like) that may provide insight related to the underlying building material. The data ingested may include, but is not limited to, data relating to the production of the building material, the transportation of the building material, the testing of the building material, the installation of the building material, or the like. The present disclosure also provides solutions for extracting relevant data from these data sources (e.g., the building material data sources) and configuring the data to be further processed. The processing of the data may relate, link, associate, analyze, or the like, the data ingested and configured within the system. Further, the processed data may be output in a way that is understandable to a user interacting with the system. In this way, the output may include a representation of the data that may include configuring a user device in such a way as to display the representation. Further, the data ingestion, processing, and output may happen in real-time which may allow for a user, such as a stakeholder in the construction project, to determine next steps regarding the project. Further still, in some embodiments, the disclosure herein provides solutions for incorporating artificial intelligence (AI) engines that may perform any of the steps as described herein.

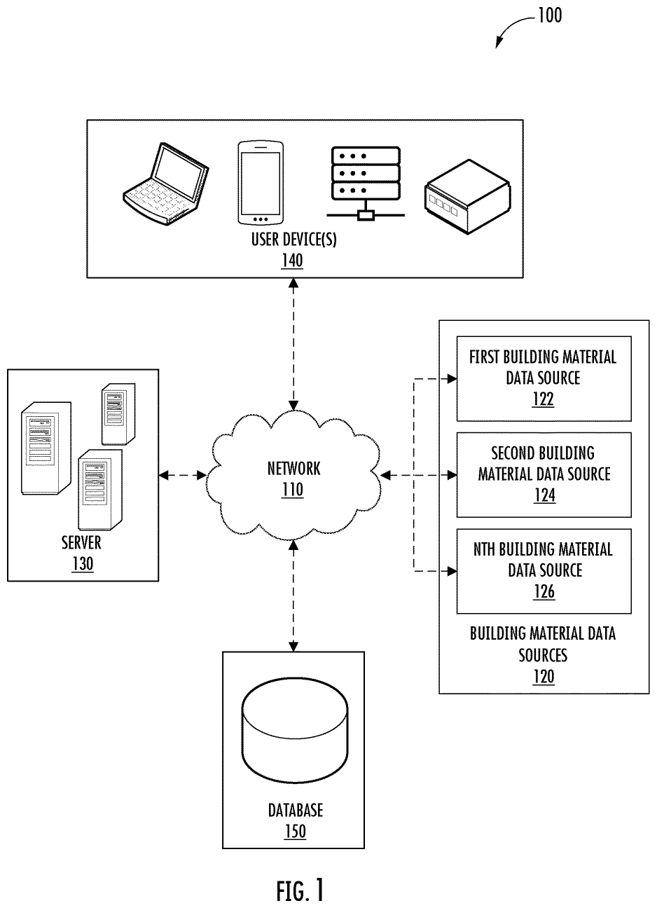

FIG. 1 illustrates an example system for building material data management (e.g., system 100). It will be appreciated that the system 100 is provided as an example of an embodiment(s) and should not be construed to narrow the scope or spirit of the disclosure. The depicted system 100 of FIG. 1 may include building material data sources 120, a server 130, user device(s) 140, and a database 150 communicatively coupled via a network 110. The server 130 and/or user device(s) 140 may be configured to control or otherwise influence operations of the one or more building material data sources 120. Further, the server 130 may be communicatively coupled to the database 150. In some embodiments, the system 100 may include the user device(s) 140 by which a user associated with the system 100 may interact with the system 100, such as via a user interface of the user device 140.

In some embodiments, the server 130 and the user device(s) 140 may have a client-server relationship in which the user device(s) 140 are remote devices that request and receive service from a centralized server, i.e., the server 130. In some other embodiments, the server 130 and the user device(s) 140 may have a peer-to-peer relationship in which the server 130 and the user device(s) 140 are considered equal and all have the same abilities to use the resources available on the network 110. Instead of having a central server (e.g., server 130) which would act as the shared drive, each device that is connect to the network 110 would act as the server for the files stored on it.

The server 130 may represent various forms of servers, such as web servers, database servers, file server, or the like, various forms of digital computing devices, such as laptops, desktops, video recorders, audio/video players, radios, workstations, or the like, or any other auxiliary network devices, such as wearable devices, Internet-of-things devices, mainframes, or the like, or any combination of the aforementioned.

The user device(s) 140 may represent various forms of electronic devices, including user input devices such as personal digital assistants, cellular telephones, smartphones, laptops, tablets desktops, and/or the like, and/or edge devices such as routers, routing switches, integrated access devices (IAD), and/or the like. In some embodiments, a user may use the user device(s) 140 to transmit and/or receive information or commands to and from the system 100 via the network 110. Any communication between the system 100 and the user device(s) 140 may be subject to an authentication protocol allowing the system 100 to maintain security by permitting only authenticated users (or processes) to access the protected areas of the system 100, which may include servers, databases, applications, and/or any of the components described herein.

The network 110 may be a distributed network that is spread over different networks. This provides a single data communication network, which can be managed jointly or separately by each network. Besides shared communication within the network, the distributed network often also supports distributed processing. The network 110 may be a form of digital communication network such as a telecommunication network, a local area network (“LAN”), a wide area network (“WAN”), a global area network (“GAN”), the Internet, or any combination of the foregoing. The network 110 may be secure and/or unsecure and may also include wireless and/or wired and/or optical interconnection technology.

It is to be understood that the structure of the distributed computing environment and its components, connections and relationships, and their functions, are meant to be exemplary only, and are not meant to limit implementations of the disclosures described and/or claimed in this document. In one example, the system 100 may include more, fewer, or different components. In another example, some or all of the portions of the system 100 may be combined into a single portion or all of the portions of the system 100 may be separated into two or more distinct portions. Various implementations of the system 100, including the server 130 and user device(s) 140, and techniques described here can be realized in digital electronic circuitry, integrated circuitry, specially designed ASICs (application specific integrated circuits), computer hardware, firmware, software, and/or combinations thereof.

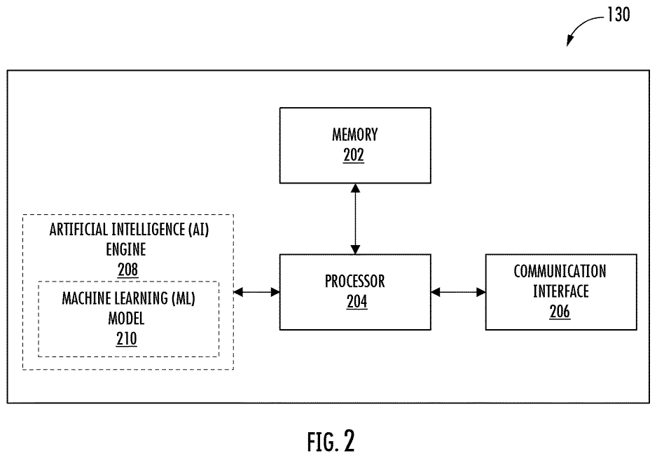

FIG. 2 illustrates an exemplary component-level structure of the server 130, in accordance with an embodiment of the disclosure. As shown in FIG. 2, the server 130 may include a memory 202, a processor 204, and a communication interface 206. In some embodiments, the server 130 may include an artificial intelligence (AI) engine 208 and/or a machine learning (ML) model 210. Each of the components 202, 204, 206, 208, and 210 may be operatively coupled to one another using various buses and may be mounted on a common motherboard or in other manners as appropriate. As described herein, the processor 204 may include a number of subsystems to execute the portions of processes described herein. Each subsystem may be a self-contained component of a larger system (e.g., server 130) and capable of being configured to execute specialized processes as part of the larger system.

The processor 204 can process instructions, such as instructions of an application that may perform the functions disclosed herein. These instructions may be stored in the memory 202 (e.g., non-transitory storage device), or on the database 150, for execution within the server 130 using any subsystems described herein. It is to be understood that the server 130 may use, as appropriate, multiple processors, along with multiple memories, and/or I/O devices, to execute the processes described herein.

The memory 202 stores information within the system 130. In one implementation, the memory 202 is a volatile memory unit or units, such as volatile random access memory (RAM) having a cache area for the temporary storage of information, such as a command, a current operating state of the system 100, an intended operating state of the system 100, instructions related to various methods and/or functionalities described herein, and/or the like. The memory 202 may store, recall, receive, transmit, and/or access various files and/or information used by the system 100 during operation.

The communication interface 206 may be any means such as a device or circuitry embodied in either hardware or a combination of hardware and software that is configured to receive and/or transmit data, including media content in the form of video or image files, one or more audio tracks or the like. In this regard, the communication interface 206 may include, for example, an antenna (or multiple antennas) and supporting hardware and/or software for enabling communications with a wireless communication network. Additionally or alternatively, the communication interface may include the circuitry for interacting with the antenna(s) to cause transmission of signals via the antenna(s) or to handle receipt of signals received via the antenna(s). In some environments, the communication interface may alternatively or also support wired communication. As such, for example, the communication interface may include a communication modem and/or other hardware/software for supporting communication via cable, digital subscriber line (DSL), universal serial bus (USB) or other mechanisms.

The communication interface 206 may provide for communications under various modes or protocols, such as the Internet Protocol (IP) suite (commonly known as TCP/IP). Protocols in the IP suite define end-to-end data handling methods for everything from packetizing, addressing and routing, to receiving. Broken down into layers, the IP suite includes the link layer, containing communication methods for data that remains within a single network segment (link); the Internet layer, providing internetworking between independent networks; the transport layer, handling host-to-host communication; and the application layer, providing process-to-process data exchange for applications. Each layer contains a stack of protocols used for communications. In addition, the communication interface 206 may provide for communications under various telecommunications standards (e.g., 2G, 3G, 4G, 5G, and/or the like) using their respective layered protocol stacks. These communications may occur through a transceiver, such as radio-frequency transceiver. In addition, short-range communication may occur, such as using a Bluetooth, Wi-Fi, or other such transceiver (not shown).

In some embodiments, the server 130 may deploy one or more machine learning (ML) models to perform the operations described herein. To this end, the server 130 may include a machine learning (ML) module 210 comprising circuitry configured to ingest data, such as a multivariate N-dimensional space of time-series data where N is the number of different measurement types (e.g., data of different types) and, via a various ML and/or artificial intelligence techniques described hereafter, and output location determinations, interaction determination, state determination, and/or the like. The ML module 210 may leverage the processor 204 to perform its associated operations and may, for example store any results in the memory 202 and/or databases 150.

The database 150 is capable of providing mass storage for the system 100. In one aspect, the database 150 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described herein. The information carrier may be a non-transitory computer- or machine-readable storage medium, such as the memory 202, the database 150, or memory on the processor 204.

Of course, while the term “circuitry” should be understood broadly to include hardware, in some embodiments, the term “circuitry” may also include software for configuring the hardware. For example, although “circuitry” may include processing circuitry, storage media, network interfaces, input/output devices, and the like, other elements of the server 130 may provide or supplement the functionality of particular circuitry.

### Example Sensor Devices

As an initial matter, the present disclosure contemplates that any embodiment and/or any method described herein, in full or in part, of any device, sensor, actuator, transducer, accessory and/or any other component which may be described herein associated with any device herein may be used in combination to produce another embodiment of the present disclosure. Any embodiment and/or any method described herein may be used, in full or in part, for any part of any method described in any other section herein, in any of their embodiments, in full or in part.

As described above, a wave-based sensor may refer to any device which may generate, adjust, or control a time-varying excitation (based on an input signal) and/or sense a response to an excitation including, but not limited to, of a target material, or another material coupled (directly or indirectly) to the target material. Such a wave based sensor may be, used to generate or otherwise make use of and sense waves, excitations, and/or oscillations (such as electromagnetic waves, electric currents and/or mechanical stresses) as described herein. Furthermore, wave-based may refer to any device, technique, sensor, etc. that employs one or more actuators to excite a host material, or a second material that is coupled to the host material. The excitation may be a time varying signal (e.g., an oscillatory signal, a wave, etc.). Wave-based devices, techniques, and sensing may also employ sensors to measure the response of the host material (directly, or indirectly through the response of the second material, or another material coupled to the host material). For the avoidance of doubt, the “wave-based” techniques described herein may encompass, without limitation, excitations, oscillations, and waves, and may further encompass any device configured to take input signals and generate, adjust, control an excitation of a field, force, or form of energy, such as via an actuator defined herein, as well as a response (e.g., material response, coupled medium response, etc.) to such excitation, oscillation, or wave.

Further, in some embodiments, the sensors as provided herein may include several different forms, such as electrochemical impedance spectroscopy, electromechanical impedance spectroscopy, ultrasonic sensors, piezoelectric transducer based sensors, spectroscopy based sensors, and the like. For example, electrochemical impedance spectroscopy may include measuring the impedance of materials (e.g., building materials) over a range of frequencies which may provide data relating to their electrochemical properties. In this way, the data produced may include data relating to conductivity, surface characteristics, degradation, and the like. In specific embodiments, the electrochemical impedance spectroscopy may be useful in evaluating long-term behavior of building materials and the data may be integrated into the system for tracking material quality, embodied carbon, and the like.

Further, in some embodiments, electromechanical impedance spectroscopy may include measuring the mechanical impedance of building materials by analyzing their electrical response to applied mechanical stimulations. In this way, the building material may be assessed regarding its structural health and integrity via change in stiffness, mass, damping properties, and the like. For example, by applying stimulations such as mechanical stress or vibrations, the building material may be analyzed to determine damage, fatigue, degradation, and the like. In this way, data may be collected from all kinds of building materials, including homogenous building materials and composite building materials.

In some embodiments, data associated with the evolution of the properties associated with a building material may be ingested, processed, and monitored. For example, the building material's workability, compressive strength, and the like may be analyzed throughout the building material's lifecycle. Further, the building material and the associated data may be inferred as the building material is created. For example, data from concrete's creation cycle (e.g., as it is poured and to when it hardens) may be ingested by the system to determine chemical properties associated with the process.

Further still, in some embodiments, the ultrasonic and piezoelectric transducer based sensors may include using sound waves and mechanical vibrations (e.g., stimulations) to assess building material properties. In some embodiments, the sensors may be embedded into building materials to continuously assess the integrity of the building material throughout its lifecycle. In this way, the system may ingest the data produced by these sensors and determine, in real-time, the overall health of the project site, building material, or the like.

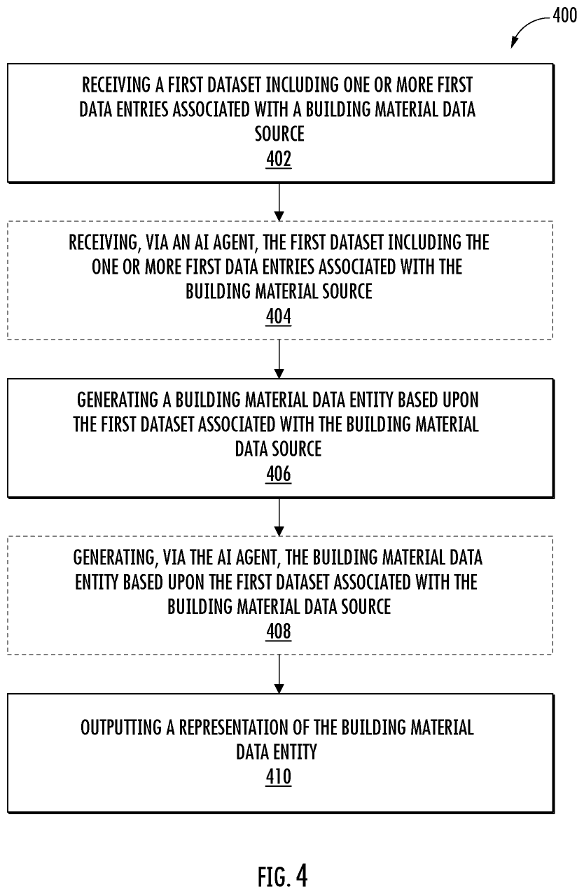

In some embodiments, and as shown in block 402 of FIG. 4, the disclosure as described herein may provide for receiving a first dataset 320 including one or more first data entries 322 associated with a building material data source. Additionally, or alternatively, in some embodiments, the first dataset may include data generated by, received from or associated with a wave-based sensor (e.g. a mechanical or electromagnetic wave-based sensor configured to excite and/or measure a cementitious mixture, or configured to measure electrochemical or electromechanical parameters of a building material).

### Example Sensor Hardware

As used herein, the terms “sensor,” “sensor device,” “transducer,” and “device” may be used interchangeably and/or collectively to refer to any hardware or circuitry component configured to generate data, such as first data entries, that is associated with a building material, construction resource, one or more elements, a building material data source, a building material data entity, and/or the like without limitation. As described herein, a sensor device may include any relevant circuitry, components, etc. configured to generate data that is indicative of or associated with, for example, the material properties (e.g., building material properties, crush test records, material test records, building material data sources, etc.) of a material. The present disclosure contemplates that each of the techniques, models, etc. of the present disclosure may be implemented with any number of the sensor and/or sensor devices and/or transducers and/or devices described herein, alone or in any combination. In some embodiments, the sensor devices described herein may be embedded in, mounted on, directed at, or otherwise coupled to a material. Further, in some embodiments, the sensor devices may include “smart aggregates” or “smart dust” (i.e., sensing dust and/or miniaturized self-contained wireless sensor devices) that are placed in the material, such as concrete, steel, etc. during production, batching, etc. Still further, the present disclosure contemplates that any of the sensor devices described herein may be “smart sensors” that, for example, include a MCU, a memory, battery management, battery power, and one or more sensors types configured to perform the techniques described herein. Each of the embodiments described herein may further be multivariate in which a plurality of sensors of the same or different type may be used.

The sensor devices of the present disclosure may be designed to be integrated throughout the lifecycle of a material, such as into concrete pours or elements (installed prior to pouring, (e.g., on rebar), and covered with concrete). Various attachment methods are designed to ensure optimal functionality (e.g. wireless communication) and secure placement throughout the material lifecycle. As such, the present disclosure contemplates that the attachment designs consider factors such as sensor shape, resonance influence, and aggregate interference, in attachment selection and may make use of various materials and coatings. These attachments are resilient to diverse material environmental conditions and do not compromise the host material's structural integrity. These attachments ensure secure attachment to different components of the material (e.g., elements of the pour structure such as reinforcement bars, otherwise referred to as ‘rebar’ or formwork, concrete drums in trucks etc.). Attachment methods may include one or more of (1) straps, bands or ties; (2) clamps, clips and fasteners; (3) adhesive and welding techniques; (3) magnetic attachments (that snap on to rebar); (4) innovative materials; (5) other; and (6) floating or sinking configurations (no attachment). The present disclosure contemplates that any attachment mechanism may be used based on the intended application of the sensor device.

In this regard, the sensors and/or sensor devices and/or transducers and/or devices as described herein may be operatively coupled to or in communication with the system 100 or any components of the system 100 as described in FIG. 1. For instance, a sensor device may be in communication with the server 130, the user device 140, the building material data source(s) 120, the database 150, the network 110, or the like. Further, in another instance, a sensor device may be operatively coupled to or included in the server 130, the user device 140, the building material data source(s) 120, the database 150, the network 110, or the like. In this way, the sensor device may generate data indicative of a particular component of the system 100 (e.g., the server 130, the user device 140, the building material data source 120, the database 150, etc.) or transmit the generated data to those components. In some embodiments, the sensor device may use the network 110 to communicate and/or transmit data to the components as shown in FIG. 1. In other embodiments, the sensor device may directly communicate with or transmit data to the components as shown in FIG. 1. In this way, the sensor device and the component the sensor device is communicating with (e.g., the server 130, the user device 140, the building material data source 120, the database 150, etc.) may be in communication via an additional network, which may include a wired or wireless connection.

Sensor devices may be used in association with “actuators” that may be used to refer to any element or circuitry component that is able to cause, generate, adjust and/or generally control any force, field or energy excitation, or disturbance (including for example mechanical excitations, or electromagnetic excitations, such as wave-based excitations, through force or field couplings). Said differently, the present disclosure contemplates that any element configured to or is otherwise capable of creating any form of excitation (not just movement based excitations) may be considered an “actuator.” In some embodiments, sensor, sensor device, transducer, actuator, and device may be used interchangeably to refer to any of their respective meanings, in a context dependent way. In some embodiments, an example “transducer” may be intrinsically resonating in that the configuration of the transducer (e.g., by geometry or the like) produces or is otherwise associated with resonant behaviors (e.g., oscillatory resonance, wave-based resonance modes, etc.).

As used herein, “wave-based sensor” may be used to refer to any device that may generate, adjust, or control a time-varying excitation (based on an input signal) and/or sense a response to an excitation including, but not limited to, of a target material, or another material coupled (directly or indirectly) to the target material. Such a wave-based sensor may be used to generate or otherwise make use of and sense waves, excitations, and/or oscillations (such as electromagnetic waves, electric currents and/or mechanical stresses) as described herein. Furthermore, “wave-based” may refer to any device, technique, sensory, etc. that employs one or more actuators to excite a host material, or a second material that is coupled to the host material. The excitation may be a time varying signal (e.g., an oscillatory signal, a wave, etc.). Wave-based devices, techniques, and sensing may also employ sensors to measure the response of the host material (directly, or indirectly through the response of the second material, or another material coupled to the host material). For the avoidance of doubt, the “wave-based” techniques described herein may encompass, without limitation, excitations, oscillations, and waves, and may further encompass any device configured to take input signals and generate, adjust, control an excitation of a field, force, or form of energy, such as via an actuator defined herein, as well as a response (e.g., material response, coupled medium response, etc.) to such excitation, oscillation, or wave.

As used herein in respect of wave-based sensors (or other, related devices), a “frame” may be used to refer to refer to fixtures, surfaces, volumes, membranes, and/or shapes of any kind which may be disposed as part of, in, around or in proximity of wave-based sensors, actuators or device housings as described herein. In some embodiments, devices, including their sensors and/or actuators may be at least partially embedded within frames, disposed within their inner volumes, in proximity to them and/or the like. In some embodiments, the devices described herein, or their component parts (e.g., sensors or actuators) may be physically bonded to frames (e.g., to produce a sensor/actuator-frame composite) or otherwise coupled (e.g., through a field, at a distance). As such, a frame may span any geometry that may or may not be contiguous. In some embodiments, frames may be made of materials or configured in geometries to manipulate waves (including their waveforms and direction of travel), oscillations, and/or excitations (for example, through wave reflections, absorption or diffraction, polarization, or oscillatory dampening, inertial, inductive, capacitive or elastic effects, and the like).

### Example Sensor Device Hardware

As an initial matter, the present disclosure contemplates that any embodiment and/or any method described herein, in full or in part, of any device, sensor, actuator, transducer, accessory and/or any other component that may be described herein associated with any device herein may be used in combination to produce another embodiment of the present disclosure. Any embodiment and/or any method described herein may be used, in full or in part, for any part of any method described in any other section herein, in any of their embodiments, in full or in part.

Sensor devices and/or node devices are devices that may typically be used to sample, monitor, store and/or transmit data sampled from sensor elements, and to excite actuator elements. They may include a Microcontroller Unit (MCU), battery, electronic circuitry, communication interface and a sensor and/or actuator and/or transducer. They may be independent or coupled. In one embodiment, the sensor device may be a passive cable assembly requiring a node device for active operation. In another embodiment, the sensor device may operate on a standalone basis. Any number of configurations of one or more of these components may be applicable. Sensor and node devices may communicate via any number of communications interfaces that may be wired or wireless. They may communicate to other sensor devices, node devices, and hub devices and/or without loss of generality any other device type configured to receive communications. In certain cases, the sensor or node devices will not have a direct connection to the internet and will therefore require a hub (or gateway) device, or a personal device (such as a smartphone) to relay the data to other parts of the system.

The hub (or gateway) may be a device that may be used to transmit data collected from node devices and/or sensor devices (or data about itself) to the internet/the cloud/a server/any external store of data. In some embodiments, the hub may also be a central control point, in charge of communicating directly to sensor devices and/or nodes. Those gateways or hubs may include any of the communication protocols listed in the communications section below and/or anywhere herein (to communicate with nodes and/or sensor devices, e.g., LoRa), and also any communication protocol that allows it to connect to the internet and cloud (e.g., cellular, including 3G/4G/5G, NB-IoT, ethernet or satellite connectivity). Hubs may be mains powered (typically using an industrial plug), or battery powered. Hubs may be rechargeable and may employ energy harvesting techniques.

### Advanced RF Techniques

Advanced RF techniques may also be leveraged by the embodiments described herein. For example, the advanced RF communication techniques may be engineered to optimize data transmission between sensors embedded in/surface mounted on/directed at or in proximity of the material and other devices or the internet (i.e. a server), and optimizing for reliability, efficiency, and power management in challenging construction environments. The system may use broadband radio frequency sensors and antennas, optimized for minimal signal attenuation and maximal reflection analysis, to enable real-time monitoring and reporting even in dense construction materials. The use of RF communications, including Bluetooth, LoRa, NB-IoT, LTE and other RF technologies, provides significant advantages in signal coupling and energy transmission. It ensures non-invasive material characterization and offers a high spatial resolution and sensing range for comprehensive material analysis.

Antenna tuning, and in particular, impedance matching for the material (to reduce power loss) are implemented. For example, adaptive tuning elements may be implemented, to modify the impedance of the antenna as, for example concrete (e.g., the example material) is curing and hydration reaction changes the medium's electromagnetic wave impedance (e.g. electrically-tunable impedance matching). Impedance matching may be implemented using quarter wavelength plates. Adaptive Impedance Tuning may be done by using variable resistors, varactors and variable inductors or other variable property components (optionally electrically actuated) on the RF front-end. RF Amplifiers may be used to amplify the signal. Optionally, the settings on those RF amplifiers may be modified adaptively, based on whether or not the device is embedded in concrete (increasing output power based on the medium surrounding the RF elements).

Antenna diversity may also be employed. Multiple antennas may be spatially distributed. They may be oriented differently to ensure different polarization of electromagnetic waves and are used for signal generations and detection. This maximizes signal transmission and reduces the impact of multipath interference fading, increasing resilience. These implementations demonstrate a significant improvement in performance of communication when in proximity of or embedded in fresh or cured concrete.

Antenna arrays may be installed on the device, such as to control direction and polarization of wave propagation. Phased array antennas may be employed, including for beamforming to direct RF communication towards specific locations (e.g. out of the concrete, or away from rebar). Adaptive beamforming is also implemented in some embodiments (based on feedback about success of communication, or other sensors (such as S parameter sensing). MIMO techniques are also implemented in some embodiments. Other beamforming mechanisms may be employed (switched beam systems, adaptive array systems, digital beamforming, analog beamforming, time delay beamforming, lens based beamforming or butler matrix beamforming).

### Advanced Power Management

The devices of the present disclosure may be powered using batteries of different types (including rechargeable batteries such as lithium ion based chemistries, or single use battery chemistries such as lithium thionyl chloride), or single-use coin cell batteries. They may also employ duty cycling and smart power management, and/or energy harvesting techniques to extend their battery life. Specific power management circuitry and/or battery types may be employed to manage larger spikes in energy consumption (e.g. for wave-based sensing excitation). Energy requirements for actuation elements will depend on sampling frequency, desired probing distances, and on the number of sensor transducers.

The power and energy requirements of the devices depend on the range and the number of excitation transducers, sensors, processing units as well as required battery life. Particular embodiments (e.g., electronic-based) will be ultra-low-power, whereas others (e.g. LIBS) will require large peaks of power (for short periods of time). To ensure multi-year battery life in a small low-cost form-factor, various energy conservation methods are used (including smart duty cycling so that excitation measurements, and wireless communication, which are the highest power functions, are only carried out at required intervals).

The sensor devices may feature an adaptive approach to power consumption, with sensors entering a low-power sleep mode during inactivity (e.g., where continuous monitoring is not required). Power settings can either be automatically or remotely adjusted based on real-time data needs and battery status, or based on context awareness outputs, optimizing the balance between operational readiness and energy conservation. A reversion to and out of sleep mode may be triggered automatically after a predefined operational period or manually through a deactivation command, or automatically based on a wake-up signal (e.g. from a sensor, or through different duty cycling modes). The devices may operate indefinitely through the combination of adaptive power usage, and energy conservation, and energy harvesting techniques. Furthermore, wave-based sensor devices generally use elements that may generate or receive waves and/or oscillations. These elements may be reused as energy harvesters during off-time (i.e. when they are not sampling).

Devices may include one or more sensor elements and/or one or more actuator elements of different types. Some techniques will be passive (only requiring sensor elements), and others will be active, requiring actuator elements (that takes an input signal and generates an output excitation). In active systems, the sensor element typically measures the material response for analysis (the response of the element itself, or of the material of interest, or any other related element). Active techniques may require at least one actuator and one sensor. Devices may also employ transducers (which convert one form of energy into another), and vice versa (e.g. mechanical energy to electrical energy). All actuators (in the general sense of the term) are transducers, but not all sensors are transducers (some sensors, such as the photoelastic elements described later, exploit changes in their properties caused by their environment, which need independent excitation to be measured).

Sensors, actuators and/or transducers may exploit various physical couplings—e.g. electro-mechanical, electro-chemical, electro-magnetic, electro-thermal, magneto-mechanical, magneto-chemical, magneto-thermal, photo-mechanical, photo-electric, photo-chemical, photo-thermal, as well as third order couplings. This includes any possible combinations of couplings between electric fields, magnetic fields, electromagnetic fields/waves ((including optical waves and photonics, but also RF waves), mechanical displacements & waves). The devices that exploit these couplings may be reciprocal (acting as both actuators and sensors), or non-reciprocal (only acting as a sensor or actuator). Different combinations of reciprocal or non-reciprocal coupling based devices may be constructed or used to sense different phenomena in materials such as concrete.

In some device embodiments, input or excitation signals may be generated (for example to stimulate a transducer, in contact with a material in the context of wave-based sensing). Traditionally, such signals are excited and measured using bulky, expensive, and power hungry lab signal generators, oscilloscopes, impedance analyzers, vector network analyzers, etc. The devices of the present disclosure, however, utilize ultra-low power and low cost electronics to achieve this, offering a step-change for the industry which will enable wide applicability. Excitation signals may be generated using analogue and digital techniques. Virtually any material or device that has the capability to detect and/or respond to an abstract, non-tangible or physical property, may be a sensor. Virtually any material or device that has the capability to transfer energy (of any form) into another system, may be an actuator (in the broad sense of the term). Actuators are always transducers (they transduce energy). Sensors are, most of the time, but not always, transducers.

The wave-based sensing aspect of the present disclosure pertains to the generation, use of and sensing of waves, excitations or oscillations (such as electromagnetic waves and/or mechanical stresses) for the purposes of measuring and characterizing material properties. The material properties in question constitute any of a material's static, contextual, and/or compositional properties, and also encompass inferences on the contextual conditions of the material or the device in question (where those conditions may relate to the environment in which the material or sensor device is placed, for example) and in general may be used to measure, characterize, and/or otherwise generate any property and/or data type listed in any section herein.

The present disclosure describes the use of mechanical stresses, electromagnetic waves, excitations and/or oscillations, generated and measured by various configurations of devices embodiments, wherein those devices may generally be distributed throughout, attached to the surface of, or externally placed with respect to a given material element.

By modifying various aspects of those generated waves, excitations and/or oscillations (either in part or in conjunction) devices, computational models, computer-implemented methods, and systems are able to infer the properties of a material in real-time; even for the case in which a material (such as a volume of curing concrete) has its properties change continuously during the measurement process. To this end, devices and systems generate or modify transmitted, resonant or passively received excitations, oscillations or waves by modulating: Wave amplitude or power; Wave frequency; the temporal phase of a wave; The polarization of a wave (wherein the wave is polarizable); The position from which the wave is emitted, or at which the wave is measured.

In general, these modulations may be varied actively over the course of the measurement process and can involve operational modes that include (but are not limited to) the following: Amplitude/Power Modes: Continuous amplitude/power; Periodic amplitude/power; Pulsed amplitude/power (wherein the wave is generated over a discrete time window); Random adjustments to amplitude/power (relating to all of the above modes). Frequency Modes: Single frequency emission; Harmonic frequency emissions (i.e. multiple, simultaneous single-frequency emissions); Frequency sweeps (i.e., time-varying frequency change of single-frequency emission); Broadband emission (i.e. wave emission over a range of simultaneous frequencies); Random frequency emission (relating to all of the above modes). Temporal-Phase Modes: Pulsed timing; Fixed time-delays; Sweeped time-delays; Random time-delays (relating to all of the above modes). Polarization Modes: Circular polarization; Uni-axial polarization; Random polarization. Position Modes: Fixed wave sources/wave receivers; Moving wave sources/wave receivers; Mixed combinations of moving and fixed wave sources/wave receivers; Wave sources/wave receivers internal to a material; Wave sources/wave receivers external to a material; Mixed combinations of internal and external wave sources/wave receivers; Any of the above in any combination.

Wave-based material characterization techniques cover both electromagnetic and mechanical waves as a mechanism to probe underlying material properties. In each of these embodiments, systems operate over a broad range of amplitudes and frequencies and utilize all of the above-mentioned modal modulation methods. An example of a device innovation discussed in the present disclosure is the use of an on-chip, Vector Network Analyzer (VNA) device that is able to characterize material properties using either mechanical waves (e.g. via piezo-electric or CMUT transducers) or electromagnetic waves (via on-chip antennas or photonic devices), and which is embeddable within the material at small scales. Another example of an innovative device configuration is the use of high-power, high-frequency electromagnetic radiation in order to vaporize a localized volume of concrete, so as to measure its chemical composition directly via the use of a light-based spectroscopy technique on the resulting plasma, and to therefore provide a mix fingerprinting or mix optimization insight with respect to that building material.

Another example of an innovative modal operation of the present disclosure is one in which the motion of wave sources and/or wave receivers from within, or external, to a given material are utilized, in order to create a 3D representation of its internal physico-chemical constituents or mechanical properties, or of a 3D distribution of some set of contextual conditions (such as the spatial distribution of temperature, force-loading, mechanical expansions or shrinkage). This technique is described as a form of material tomography, which is used in the broadest sense to measure a measurable material property as a function of spatial position within a material element.

### Mechanical Waveguides And Resonators

Mathematically the concepts developed around waveguides, frames and resonators of the present disclosure for electromagnetic waves translate naturally to the other realms include mechanical waves. This may be understood from the consideration of the wave equation, allowing for the differences in physical contributions and the boundary conditions. The phase velocity of the lowest propagating mode in an acoustic waveguide is generally close to the free-space sound velocity so sound velocity can conveniently be measured in a waveguide as a function of gas composition, temperature, and pressure, in the presence of a flow field, and even in turbulent flows. Similarly, damping of waves may be a measure of the shear viscosity of the medium.

These ideas may be extended to a solid medium, specifically in the context of wave-based sensors. From a waveguide perspective, typically surface acoustic waves such as Lamb waves are excited. These travel along the direction of the boundary of the medium, are typically S-waves and may be directed by the excitation unit in a manner that triggers wave reflection back to a collocated sensor or transmission to a distinct sensing element. The critical propagation occurs through the medium and the properties of the medium may be measured, wave speed directly relating to the bulk modulus, the attenuation of waves relate to the shear modulus. The system employ such waveguides in some embodiments. Their excitation modes can be characterized as a measure of the material of interest. An equivalent electrical circuit can be constructed for mechanical systems, formed of wave-based sensors and frames (e.g., acoustic waveguides). This is used to understand and/or tune complex mechanical systems. One embodiment uses such equivalent circuits to model and measure wave propagation scattering through the circuit by converting it into an N-port system and measuring its S or T parameters.

### MAIS: Multi-Coupling Advanced Impedance Spectroscopy Techniques

The wave-based sensors described herein may further be configured to measure the spectra of a new class of impedances, through a plurality of innovative couplings (so called multi-coupling advanced impedance spectroscopy' techniques' or ‘MAIS’). This goes beyond the more traditional technique of electrochemical impedance spectroscopy (EIS, where an electrical potential applied across an analyte is used to determine the electrochemical impedance at a plurality of frequencies).

In MAIS, the response of a sample to one or more perturbation time-varying excitations (e.g. electric, mechanical, optical and so on) may be monitored, and the fraction of energy that is stored (including stored potential energy—i.e. capacitive, dielectric or stiffness components, and also kinetic/magnetic energy—i.e. inductive or inertial components) versus the fraction of energy dissipated (resistive, damping component of impedance or other) by the sample, as well as the relaxation time scale (the time that it takes the sample to return to equilibrium after excitation by the input), is measured as a function of frequency.

The input to generate the excitation may take any of the forms described herein (e.g., sinusoidal, multi-sine, step functions, delta functions, and/or the like), and the measured output impedances may take any of the forms described herein, or any other impedance-like, or impedance analogous measure that may involve other fields, flows or forces. These generalized impedance measurements are typically complex, may be measured by detecting one or more amplitudes and phase shifts, or by measuring an input and an output voltage or current (when electrically coupled), or by measuring an inductance, capacitance and resistance of a circuit (or any of their analogues in non-electric domains).

Wave-based sensors are able to carry out MAIS techniques by exploiting couplings between different domains (e.g. electric, magnetic, electromagnetic, optical or photonic, chemical, mechanical, radiative or biological domains). For example, to characterize the mechanical impedance of a system, an electromechanically coupled sensor and/or actuator may be used to drive the excitation or sense the system. The measured output of the coupled system is the electromechanical impedance (wherein the electrical impedance of the electromechanically coupled sensor is measured). It follows that other couplings may be employed—e.g. optomechanical, magnetomechanical, magnetochemical, optochemical, optoelectric and any other two coupling permutation. Higher order couplings (3 couplings, 4 couplings and so on, such as electro-magneto-mechanical, electro-opto-mechanical) may also be employed in certain embodiments, for example when a second order coupling that is not electronic in nature is measured by an electronic system. The fundamental types of impedances (in respect of the physical phenomenon they are related to) are described hereinafter. When they are measured through a coupling, the coupling is typically prefixed to them and the measured impedance quantity is labeled after the “coupling type” and “phenomenon domain” (e.g. “electromechanical impedance” or “optomechanical impedance” and so on).

Three types of impedances are described above (electromagnetic wave impedance, acoustic impedance, and mechanical impedance), which can be measured by wave-based sensors, across a variety of frequencies. These impedances are associated, but physically distinct concepts. Broadly they may represent how a particular force, flux, or flow is impeded by a system (or in the case of admittance, which is the inverse of impedance, how a particular force or flow is admitted by a system). These are more formally defined below (without loss of generality for another related or similar form).

Electromagnetic Wave Impedance is Z_{w}=Eₓ/H_{y}, where Eₓ and H_{y} are the transverse components of the electric and magnetic field. For a wave travelling in a dielectric with dispersion and losses, this becomes: Z_{w}(ω)=\sqrt{iμω/(σ+iω∈)} where μ, ∈ and σ are the permeability, permittivity and conductivity of the medium in which the electromagnetic wave is travelling.

Acoustic Impedance is (for P waves at normal incidence) Zₐ(ω)=ρc, where ρ is the density of the medium, and c the speed of sound in the medium. The speed of sound in the medium may depend on frequency (in particular in resonators) and can be expressed in terms of the frequency ω and wavenumber k. In the frequency domain this becomes: Zₐ(ω)=ρω/k. This is the opposition to the flow of sound energy through a medium, measured in Rayls (acoustic ohms, of unit (kg/(s·m²))).

Mechanical Impedance is Zₘ=F/ν, where F and v are the driving force and velocity at a point. More generally, for an n dimensional linear system, mechanical impedance is defined in the frequency domain, as the ratio of the fourier transforms of the force excitation and the velocity response, which can be expressed as follows in summation notation: ZᵢⱼVᵢ=Fᵢ.

The technique is extended further to other forms of impedance (for different forces, waves, fluxes or flows), which may all be measured by wave-based sensing systems (optionally at a plurality of frequencies). Below some additional examples of the different types of impedances the system is able to characterize through MAIS are shown.

Electric Impedance is Zₘ(t)=V (t)/I(t), where Vis the voltage across, and I is the current passing through the component of interest. This is typically further broken down into its real and imaginary components, Z=R+iX, where R is the resistance, and X is the reactance (itself made up of the capacitive and inductive reactances).

Elastic Impedance, which is an extension of Acoustic Impedance, to oblique incidences, that combines the density and velocities of both P-waves and S-waves in materials to provide an intrinsic property of the elastic medium. This can take various forms (including, e.g. an impedance matrix), or for example, Ver West's the Ray-Path Acoustic Impedance Z_{RI}(ρ, V_{P}, V_{S}|p)=ρV_{P}/[\sqrt{1−V_{P}²p²}]exp[−4V_{S}²p²ρ/ρ₀].

Magnetic Impedance, which refers to the opposition to the flow of an alternating magnetic field in a material. In the gyrator-capacitor model, this is Z_{B}(ω)=F(ω)/\dot{Φ}(ω), Alternatively, in the reactance-reluctance model the analogue is the magnetic reluctance, R_{B}=F/Φ (analogous to an electric resistance).

Thermal Impedance, which measures the resistance to heat flow through a material (in degrees kelvin per watt (K/W)) and is the generalization of thermal resistance to time-varying thermal excitations. This can be defined as the ratio between the temperature of the sample, and the thermal wave flux. In one embodiment this is expressed as

$${Z}_{θ} = [ {T}_{ac} ( x , t ) ] / [ - k ( \frac{{dT}_{ac}}{dx} ( x , t ) ] .$$

For a semi-infinite medium,

$${Z}_{θ} = \frac{1 - i}{ϵ \sqrt{2 ω}} ,$$

where ω is the frequency of thermal oscillation, and ∈, the thermal effusivity.

The goal of the mechanical wave-based devices is the determination of compositional properties, contextual material properties, and static material properties, device and material contextual conditions or related characteristics of the host material (e.g., the time evolution of concrete strength or workability of a cementitious mixture as it cures). The measured output may include mechanical displacements and deformations, mechanical wave characteristics in the host material (e.g. mechanical impedance frequency response, acoustic or elastic impedance frequency response or for an N-port system, the S-parameters/S-Matrix & T-Matrix).

The embodiments of the present disclosure considers mechanical wave-based elements that leverage a number of different physical force couplings (as further described herein). In some cases these are built from smart materials. These couplings enable sensing, actuation, or both (in some cases, but not always, through a reciprocal phenomenon). In the case where the coupling is a reciprocal phenomenon (e.g. piezoelectric materials, CMUT transducers), then a single element may be used for the characterization of materials. The behavior of a single element is akin to a 1-port system, which means that its impedance can be measured (e.g. if an electro-mechanical coupling is employed, the electric impedance of an electromechanically coupled system will be indicative of the mechanical impedance). In the case where the coupling is not reciprocal and there are multiple elements that carry out actuation and sensing, the system may be analyzed as an N-port system. In some embodiments, an element can both actuate and sense. In other embodiments, different elements are used for actuation and for sensing, which may or may not be spatially collocated, or on the same or distributed across different devices. When sensing and actuation are spatially separated, typically the system involves traveling waves, rather than just oscillations. The signal analysis can then be thought of as the determination of the transfer function for the system.

A mechanical excitation may be driven through a host material through one or more actuator elements. The response of the material to those mechanical oscillations is then measured using a sensor element. This may take the form of a frequency response analysis (e.g. impedance spectroscopy), intensity response, time response, and/or the like. The input signal that excites the actuation element (which may be electrical, photonic etc.) may take a variety of forms, including waveforms such as delta functions, square waves, step functions, sinusoids, or a sequence of custom pulses (constructed from one or multiple oscillatory frequencies). Alternatively, the input may be a frequency sweep (e.g. a chirp, which may include up-chirping or down-chirping). The input signals are applied to the actuator, which then produces mechanical displacements or deformations in the actuating element (through the applicable coupling). This in turn, creates a displacement and deformations of the host material.

Material properties may then be determined through various techniques, including through the use of a machine learning model trained on a database of mechanical impedance signals obtained from known material samples and associated compressive strength measurements (e.g., from CMUT transducers embedded in concrete cylinders or cubes, and associated cylinder or cube crushes). Alternatively, physico-chemical models can be used to relate the impedance spectrum to known physical quantities (e.g. stiffness and/or dynamic modulus of the material) and so on. Hybrid methods may be employed (which combine physico-chemical models and machine learning models trained on pre-existing data). Training dataset for machine learning models may be based on physical simulations (e.g. finite element models).

### Piezoelectric Sensing & Actuation

One implementation of electromechanical sensing and actuation makes use of piezoelectric elements. The piezoelectric transducer may excite a volume surrounding it (where the size of the volume of influence is related to the size of the piezo element, and the power/energy input and the material properties). Piezoelectric elements may also be stacked for increased effectiveness, and importantly, enabling custom piezo active shapes which can enable various resonance modes (through irregular piezo active elements). They are low-cost, low power, and may also be micromachined and deposited or constructed using thin-films, enabling miniaturization into a low-cost, mobile, long-lasting embedded or surface mounted device (or a hybrid of the two).

### CMUT Devices

CMUT are a type of transducers that generate mechanical deformations and oscillations (typically in the ultrasonic frequency domain) through changes in capacitance (a mechano-capacitance based coupling). They may also act as sensors of mechanical displacement and oscillations (which means this is an example of direct energy conversion reciprocity). They are constructed using silicon micromachining techniques. Given the prevalence of silicon micromachining in chip design and MEMS, this means it is possible to construct various CMUT-active transducers (e.g., including of various transduction arrays and resonant geometries) at a relatively low cost using existing equipment.

The CMUT element may be formed of a silicon substrate (which can easily be micromachined based on microfabrication techniques). Thin film layers are deposited on the substrate, including conductive layers for electrodes, a sacrificial layer (typically an insulator), and a membrane layer. The sacrificial layer is etched away to form a cavity. The membrane is made of a conductive or semiconductor (e.g., silicon) and is mounted above the sacrificial layer (forming a cavity between the substrate and the membrane). The substrate and the membrane may be connected to electrodes (through conductive layers). When a potential is applied across the electrodes, charge build-up leads to an electric field across the electrodes. This field leads to forces which the membrane towards the substrate, decreasing the size of the cavity. The potential across the electrodes can be modulated to generate a mechanical oscillation. Potential frequency sweeps and various pulses can be used to mechanically excite the transducer.

Conversely, when mechanical displacements are applied onto the membrane (e.g., from incident mechanical waves), they change the distance between the membrane and the substrate, which alters the capacitance of the system. These capacitance changes cause a change in charge accumulation in the substrate and membrane. When the membrane moves closer to the substrate, the capacitance increases and more charge is stored. When it moves away from the substrate, the capacitance decreases and less charge is stored. This change in charge leads to a displacement current, that is proportional to the rate of change of the voltage and the rate of change of the capacitance. This displacement current is small but can be measured through signal processing techniques (including amplification, and conversion into a voltage, e.g. using a transimpedance amplifier). The resulting voltage is processed (optionally using filtering and digitization techniques). Further analysis is then carried out on the processed signal to determine characteristics of the mechanical deformations (e.g. ultrasonic wave intensity, frequency etc.). Generally, this is all based on measurement of changes in capacitance to derive mechanical behavior.

### E&M Wave-Based Sensing Devices

Materials properties may also be characterized based on the impact of time-varying electromagnetic fields on material properties (actuation), and the impact of the material on those electromagnetic fields (sensing). Electromagnetic wave-based sensors are in essence probing a coupling between the material, and the time varying electric or magnetic field. Materials may be excited using a variety of electromagnetic input signals, such as time varying electric fields (e.g. alternating currents or voltages), time varying magnetic fields, or of electromagnetic wave propagation. They may also be sensed using similar signals. Some devices are able to act as both excitation sources/actuators, and sensors.

Time-varying magnetic fields induce electric fields. Time-varying electric fields induce magnetic fields. But these oscillations do not always lead to significant wave propagation in a medium (waves may decay), due to the permittivity (ε), permeability (μ) and conductivity (σ) of the medium. In materials with high conductivity, σ, electromagnetic waves are heavily attenuated. The electrical field induces current into the material, which dissipates energy as heat due to resistance. In dielectric materials (low conductivity), E&M waves can propagate with less dissipation at higher frequencies. However, at lower frequencies, even these dielectrics will absorb energy (dielectric losses), for example due to polar molecules which align with the electric field. This means that excitation at different electromagnetic oscillation frequencies leads to different phenomena in the material.

The present disclosure categorizes E&M wave-based sensing techniques along the frequency domain as follows. Low Frequency Excitation & Sensing include from zero up to the frequencies where time-varying electric and magnetic fields begin to exhibit wave propagation in the medium. The frequency at which this occurs will depend on the material under consideration (including its permittivity, permeabilities and conductivities). For practical purposes, these are defined dynamically, as the frequency where electromagnetic waves begin to propagate within the medium with an attenuation of less than 1/e. At these low frequencies, wave propagation is not dominant (due to their interaction with dipole moments etc.). When exciting dielectric materials like concrete, this band can be split into Electrochemical and Magnetochemical depending on whether electrical or magnetic fields are predominantly driven by the actuator or drive the sensor's response. Electro-Magneto-Chemical couplings may also be employed.

Mid Frequency Excitation and Sensing includes where electric and magnetic fields begin to exhibit a tightly coupling interaction, allowing electromagnetic waves to propagate effectively in the medium. It encompasses frequencies where E&M waves can travel more than a few wavelengths before attenuating by 1/e and extends up to the beginning of the infrared spectrum. As such this band contains what is commonly referred to as Radio Frequency, Microwaves and Terahertz frequencies.

High Frequency Excitation & Sensing includes where electric and magnetic fields begin to interact with molecules and atoms in the media, which begins to impede wave propagation. Frequency band starts somewhere in the Infrared Spectrum and includes any frequency beyond it (so infrared, visible, ultraviolet, x-rays and gamma rays). At these frequencies, due to the lower wavelength and higher energy, interaction with the material happens at the atomic or particle level, which leads to different techniques.

### Electromagnetic Wave Impedance

In electromagnetic wave impedance sensing mode, the methods described herein may make use of one or more broad spectrum radio frequency sensors/detectors, and one or more antennas. In active monitoring configurations, one or more antennae are used to generate signals at different frequencies and locations within a host material so as to be able to monitor signal attenuation, reflections, electromagnetic wave impedance and general frequency response. These parameters may be monitored over time as the material evolves, but also over space to determine their spatial distribution. The one or more receiving antenna may be the same as the one or more transmitting antenna (e.g. for one antenna, acting as a one port system), or the system may employ distinct receiving and exciting antennas (or a hybrid approach may be employed). Some embodiments employ one single antenna, others employ a plurality of antennas. Spatial separation of antennas, polarization and gain distribution are all key considerations for designing the system.

The devices of the present disclosure may be placed in a multi transducer and multi-sensor configuration (as described previously for other techniques) in order to do spatial tomography and/or time domain reflectometry. Likewise, device output electromagnetic signals can be driven onto waveguides, or from within or into containers that isolate a volume of concrete in the element for analysis or be placed in proximity of such containers. Optionally, these containers may act as cavities (e.g. made of electromagnetically reflective material), so as to generate particular excitation modes of the electromagnetic signal. They may also act as reflectors or concentrators. Generally, any frame and/or fixtures, which may be made of conductive materials (including waveguides) to direct the propagation of electromagnetic waves, and also generate electromagnetic resonances are considered. These may also take the form of dielectric resonators.

### Refractive Index & Polarization Sensing

Using specialized optics and/or antennas, reflective real and imaginary components of the refractive index (attenuation and speed of light change and in parallel light polarization) and polarization of electromagnetic waves (e.g. described in the form of Jones Matrices or Mueller matrices) can be determined, from both within as well as from the surface of host materials (including the boundary effects of the surface, as well as the impact of the medium itself on wave propagation). Physically, refractive index sensing can be related back to electromagnetic wave impedance.

In one embodiment, E&M waves are directed onto or into a material at one or more angles, and the transmitted wave's intensity and beam deviation is measured to calculate the refractive index. In embedded scenarios, RF or optical waveguides may be used with a direct, angled boundary into the medium, to aid in refractive index characterization. Generally, refractive index sensing involves measuring the intensity and angular deviation of E&M waves as they interact with the material. By analyzing these changes, the system can detect variations in the material's refractive index. Determination of the refractive index would in turn allow for monitoring of the material's relative permittivity and permeability in the chosen frequency range. This can then be related to other material characteristics, such as the water to cement ratio and ultimately its compressive strength or workability.

In another embodiment, multiple polarized antenna, or optical analyzers are used to sense the polarization (or change in polarization) of electromagnetic waves within a medium. In one embodiment, a uniformly polarized excitation signal is generated (e.g. the excitation signal may be circularly, linearly polarized, or elliptically polarized for example). At least two (and optionally three, for three dimensional sensing), perpendicular polarized antennas are disposed in the path of the electromagnetic wave propagation. The two perpendicular antennas are used as an analyzer, to fully characterize the x and y components of the wave's polarization. With three antennas, the direction of propagation, and polarization can all be determined. It is worth noting, that in the mechanical world, an analogue exists for the detection of the mode of the wave (transverse waves, longitudinal waves, surface waves etc.), and in the case where the waves are transverse or surface-based, their polarization can be characterized similarly.

The technology is applicable across various frequency ranges, including mid and high frequencies (such as the visible light spectrum). The mid-frequency electromagnetic regime (RF, Microwave) allows for good wave propagation through the medium, making refractive index and polarization sensing particularly advantageous in this part of the spectrum. In the infrared, optical domain waves will attenuate too fast in the medium. However, waves can propagate in other materials which may be coupled to the host material (e.g. a photonic waveguide, which are discussed in the high frequency section, or photoelastic materials which are discussed in the optomechanical section).

### NMR, EPR and/or Microwave Spectroscopy

Nuclear Magnetic Resonances, Electron Paramagnetic Resonances, and Microwave spectroscopy techniques can be used in the radio and microwave part of the spectrum to produce a response spectra (in the case of NMR and EPR, related to the spin of their nuclei and electrons respectively). Spectroscopic analysis can then be carried out to determine compositional properties of the sample over time e.g. signals that demonstrate absorption due to water and its decaying influence as the concrete cures and dries. In this section, ultra-low-power, low-cost wireless, miniaturized devices (e.g. designed for embeddability or surface mounting on concrete) are designed with NMR, EPR and Microwave Spectroscopy capability for field material characterization and identification.

When placing nuclei that carry spin in a strong magnetic field, the magnetic moments of those particles align with the applied field, but they also process around the field direction, at a frequency known as the Larmor frequency. This frequency is different for each type of nucleus, and also depends on the applied magnetic field strength. In NMR, samples are placed in a magnetic field, and radiofrequency pulses are used to perturb the magnetic moment alignment and precession frequency. The nuclei absorb energy from these pulses and move into a higher energy state. After the pulse, they return to their initial state and release energy as a result. This energy release is detected and recorded, producing an NMR signal. In NMR the pulse is typically in the radio frequency domain.

When placing unpaired electrons (e.g. in paramagnetic materials) in strong magnetic fields, their magnetic moments also align with the applied fields (due to the electron spin). When placed in a magnetic field, the spin states of the electron split into different levels (governed by Zeeman effect). In EPR spectroscopy, the sample is placed in a magnetic field and subjected to a microwave frequency sweep. Resonance absorption occurs when the microwave energy matches the energy delta between the split levels. This leads to a change in magnetic field at the detector, which can be measured to determine the EPR Spectrum and the g-factor. Species of interest include Fe(III), Fe(II) and Mn(II), and other paramagnetic species.

NMR, EPR and more broadly, Microwave Spectroscopy are highly effective in monitoring the curing (in particular water changes). As concrete cures, changes in the concrete properties are tracked over time to assess the curing stage and overall quality of the concrete and make determination about the water to cement ratio and the compressive strength of the concrete, as well as its setting time.

In some embodiments, the system houses specialized dual-mode generators capable of emitting both NMR (radio) and EPR/microwave frequencies. Precision control mechanisms are integrated to ensure the stability and accuracy of the frequencies generated. This is crucial for consistent and reliable material analysis. The system includes an array of directional antennas for the emission and reception of NMR and microwave signals. Optionally, the antennas are designed to adaptively focus and steer the emitted signals, enhancing the depth and resolution of material penetration.

The system may employs high-sensitivity magnetic field detectors to measure the energy absorption or emission at specific frequencies. In the case of NMR, as the nuclei or electrons relax to their ground state, they realign with the permanent magnetic field, which generates an electromagnetic wave (RF or Microwave respectively), which is detected in a nearby receiver coil. The chemical shift is also measured in association with the NMR spectrum. In the case of EPR, as electrons are excited by incident microwave energy. Parts of the microwave spectrum are absorbed, which leads to a change in the intensity of the wave, which is measured at multiple frequencies to construct a spectra. The g-factor is also measured in association.

In the NMR and EPR module, uniform magnetic field coils generate a consistent magnetic field. Control systems are integrated to adjust the magnetic field strength, allowing for customization based on different material characteristics.

### High-Frequency (Near-IR, Visible, UV, X-Ray+)

High frequency wave-based sensing techniques involve E&M waves (also sometimes colloquially referred to as “light”) with frequencies at the near-IR band and upwards. At these frequencies, E&M waves carry enough energy to begin exciting atoms and particles. These excitations and interactions are used to characterize the medium under consideration, from its fundamental constituents upwards.

Intensity Spectroscopy & Imaging Sensing may refer to a class of sensing technique which comprises analyzing the E&M intensity-frequency spectra of E&M waves emitted, absorbed, reflected, transmitted and/or otherwise interacted with or radiated by a medium. Typically this will involve the actuation of a medium using a high-frequency E&M wave, which will interact with the medium in one of the aforementioned ways and be sensed using a spectrum analyzer to monitor intensity spectra.

Photonic Sensing may refer to a class of sensing techniques which use materials with photonic properties that may control and/or influence E&M waves in or around the IR/Visible/UV spectrum to engineer conditions that are particularly advantageous for sensing the interaction of these E&M waves with the material under consideration (e.g. host medium or material).

As for other types of wave-based sensing devices, the sensor devices disclosed herein may principally be used to measure compositional, contextual and/or static material properties of the host material, as well as material and/or device contextual conditions, and/or any other data type listed in any part of this document. Any part or sub-part of any embodiments, disclosures and/or further descriptions in this section, may be used to enable, in full or in part, any method described herein. Any part or sub-part of any embodiments, disclosures and/or further descriptions in this section may also without loss of generality be used for any other embodiment of any sensor device described herein. Any of the methods described in this section may be used on any hardware embodiment disclosed (for example, low-cost mobile battery powered field devices designed to be embedded and/or attached within concrete, able to communicate wirelessly using any of the communication methods already described, coupled with smartphones and cloud-based machine learning models for analysis). These low cost devices of the present disclosure present a step-change away from bulky lab-based spectroscopy that are incapable of performance in the field as described herein.

### Intensity Spectroscopy & Imaging Sensing (ISI)

Intensity Spectroscopy & Imaging Techniques may present a way of measuring the data type (e.g. any material property) listed in any section of the present disclosure, and in particular for the determination of compositional material properties (atomic elements, compounds, formulations etc.), as well as any contextual and/or static material properties associated with the chemistry, atomic structure, and/or other atomic level properties of the material. Without loss of generality, these sensor devices may also present methods of measuring other types of properties of matter. In this way, the device embodiment listed herein may be particularly useful for intrinsic material identification purposes. Such devices therefore present a highly accurate material monitoring tool based on fundamental, atomic-level chemical and physical material properties, which may self-identify materials. In addition, imaging techniques allow for spectral E&M Wave tomography, as E&M spectra are spatially mapped to different areas of material, which allows for comprehensive characterization of the material. These techniques may be applied to cementitious mixes and/or concrete mixes or any of their raw materials, but also other materials used in construction such as steel beams and/or rebar, timber, coatings such as intumescent paint, and without loss of generality any building materials, composite material, raw material, mined or extracted material and/or other materials.

### LIBS Spectroscopy Sensing Device

The LIBS Spectroscopy embodiment of the E&M High-Frequency Wave-based sensing device makes use of LIBS spectroscopy for building material property determination. LIBS Spectroscopy comprises a method using high intensity lasers to transfer energy into and excite a microscopic volume of material into a state of plasma for a very short time interval. Once this ‘micro-plasma’ de-excites, it emits radiation corresponding to the spectral energy levels of its component molecules. This is detected by a spectrometer or other E&M wave detection device. The process, from E&M wave emission to detection may last a few hundred nanoseconds and may be considered a non-destructive or quasi-non-destructive technique in building materials applications, since negligible samples of material are converted into plasma and as such, the structural integrity of the building material is not compromised.

The spectrometer reconstructs the material's intensity-frequency spectrum based on the received E&M waves. Using this spectral data, attributes and/or properties of the material under consideration may be determined. For cementitious mixes, properties of interest for determination may include building material compositional properties, including material formulation and/or raw material concentration within the building material, as well as contextual material properties including compressive strength, and other properties associated with the rate of hydration in early-age cementitious mixes. In one embodiment, the LIBS device may be configured to do spectral analysis for material compressive strength determination in cementitious mixes. One analysis method for execution of this determination includes detecting the intensities of the dominant Calcium I & Calcium II spectral lines, known to exist at 422.6 nm for Ca I, and at 393.3 nm & 396.8 nm for Ca II. Once these are detected, the ratio between the intensity of the Ca I & Ca II (either Ca II lines) may be correlated to the compressive strength of concrete. Calcium compounds comprise many of the reagent compounds in the hydration reaction of cementitious mixes, and may therefore be used for compressive strength determination, which strongly correlates with the hydration reaction. In some embodiments, the relationship between the intensity ratio and the compressive strength of the cementitious mix may be linear. In some embodiments, spectral analysis includes a calibration step. Enhanced LIBS methods may employ double pulse excitation, spatial configuration, magnetic confinement, spark discharge confinement, or DFLS to improve measurement accuracy.

### FTIR Spectroscopy Sensing Device

FTIR measures absorption of infrared light, providing an absorption spectrum displaying the frequencies at which a sample absorbs incident photons. A sample is illuminated with IR light, and absorbed light energy is converted into defined molecular vibrations. FTIR covers a wider spectral range, typically from the near-infrared to the far-infrared region. The technique may be particularly advantageous for material identification, in that it can provide information about molecular vibrations, including functional groups and chemical bonding. This means it can be used to complement other methods such as LIBS that provide elemental data.

Each functional group in a molecule has characteristic unique vibrations that are reflected at different bands in the infrared spectrum. Individual bands in an infrared spectrum can be used to determine what functional groups are present in a sample. The bands of all these different functional groups together result in a Fourier transform infrared (FTIR) spectrum that can be considered a fingerprint of the sample. This technique may be particularly useful for mix fingerprinting applications. The region in which most of the characteristic vibrations are present is called the fingerprint region. The fingerprint region is located at the lower end of the so-called mid-IR region. Infrared spectroscopy requires light from the mid-IR region, which spans from about 4000 to 400 cm⁻¹.

### Hyperspectral Imaging Sensing Device

Another significant element considered in one embodiment includes the use of hyperspectral imaging to characterize the fresh, hardened and/or other properties of construction materials such as concrete, in both 2D and/or 3D. Material property determinations may include for example compressive strength, or water to cement ratio. Through the various device features (MCU, smart power management etc.) already described, ultra-low cost hyperspectral devices are built, enabling much wider adoption of embedded, surface mounted or near-pour devices.

By directing a hyperspectral camera at a concrete element (for example, by mounting it near the surface), the full spatially distributed electromagnetic spectrum for each pixel (which represents an area of material dA) may be mapped, providing invaluable information on its chemical composition. Higher resolution hyperspectral imaging is also able to build up a distribution of material within the concrete (aggregate, cement matrix etc.). This allows for clustering of spectra for the different subcomponents of a concrete mix, enabling the characterization of the cement matrix and the aggregate type. This may include the use of magnifying optics for hyperspectral microscopy of concrete.

In some embodiments, an illumination source may be used to illuminate the concrete (or the generalized material). Additionally or alternatively, the illumination source may be a broadband light source, or narrowband light source. Additionally or alternatively, there may be one single light source or a plurality of light sources. Additionally or alternatively, the light source may be LED based. Additionally or alternatively, the hyperspectral imager may employ a tunable filter to compose a hyperspectral cube (e.g., a MOEMS-based tunable Fabry Perot filter). Additionally or alternatively, a plurality of narrowband illumination sources may be turned on and off in succession at a predefined pattern, and the output recorded by the camera, and processed to create a hyperspectral cube.

Additionally or alternatively, the subcomponents of the concrete (e.g., aggregate vs cement matrix) may be identified in the hyperspectral image. This may be done using a machine learning model. Additionally or alternatively, this output may then be used to construct one or more distinct frequency spectra for the whole or parts of the cement matrix, and/or the aggregate, and/or any other parts of the material. In the case where another amorphous material is considered, similar substructure may be identified, separated, and characterized. Additionally or alternatively, averages, means, modes, or other mathematical operations may be applied to the spectral data from each sub material type and used in characterizing the material.

### Raman Spectroscopy Sensing Device

Raman Spectroscopy involves the use of laser light to interact with molecular vibrations, phonons, or other excitations in a material. The technique provides detailed information on molecular composition, crystal structure, and other physical properties. It can be used to study concrete's crystalline and amorphous form.

Raman spectroscopy may be employed to characterize concrete or cement in lab environments, but it requires specialist, costly equipment, and importantly, requires samples to be sent from the field to the lab. In this embodiment, an ultra-low-power, battery powered or energy harvesting device, designed to either be surface mounted, or embedded into concrete, and wirelessly communicate with other devices or the internet/the cloud, is able to carry out Raman Spectroscopy in the field, a feature not found in conventional Rama based systems. Generally, all of the features described in the general hardware section may be incorporated into this device, and spectroscopy techniques described for other embodiments herein may be transferred to this embodiment (including adaptive optics, movement and guiding of beams etc.).

At the core of the device is a monochromatic laser (e.g. a diode laser) which provides a narrow-band light as a specific wavelength. Optical fibers and/or lenses (or other photonic waveguides) guide the laser beam to a surface area of concrete. A trapezoid prism-shaped housing, and/or a semi-parabolic convex dome design may be employed to support precise directing and focusing of the laser beam onto the surface of the material of interest. The device detects Raleigh scattering, Stokes-Raman scattering and anti-stokes Rama scattering to determine vibrational modes of molecules in the material of interest (e.g. concrete), to identify them. The source light would be produced by a single or multiple lasers across one or a wide variety of wavelengths. A high-resolution spectrometer is used to analyze the scattered light, and separate the Raman scattered light into its constituent wavelengths. This may take the form of a CCD or CMOS sensor alongside a Fabry-Perot Tunable Filter (or any other spectroscopy technique described herein).

### XRD Spectroscopy Sensing Device

The X-ray part of the spectrum can be treated as an extension of the visual spectrum and as such X-rays can be used to both excite the unit or material under test as well as monitor its absorption and reflection of said source X-rays. This enables the determination of material composition and other material properties, including their changes over time and space. XRD spectroscopy is employed to characterize concrete or cement in the lab, but it requires specialist, costly equipment, and importantly, requires samples to be sent from the field to the lab.

In this embodiment, an ultra-low-power, battery powered or energy harvesting device, designed to either be surface mounted, or embedded into concrete, and wirelessly communicate with other devices or the internet/the cloud, is able to sample XRD spectra. Generally, all of the features described in the general hardware section may be incorporated into this device, and spectroscopy techniques described for other embodiments herein may be transferred to this embodiment.

### DRS Spectroscopy

In one embodiment, the device may be configured to execute differential reflectance spectroscopy. DRS spectroscopy may involve characterization of the difference in intensity as well reflectance spectra of the surface of the material under consideration with respect to different parameters, for example changing wavelengths. Light may probe the surface of the material and be reflected back towards a photodetector. The reflectance spectrum may comprise values for the surface differential reflectivity for a plurality of frequencies, optionally a continuum of frequencies (frequency band). The surface differential reflectivity may be defined according to a 3-surface model.

In one embodiment, this may be used to characterize the dielectric properties of the surface of the material. This device and technique embodiment may use a near-IR, visible and/or UV light source to excite the surface of a material (e.g. concrete). The reflectance of the E&M waves as they bounce off the surface of the material is detected by a spectrometer and used to reconstruct a reflectance and/or intensity spectrum for the material. In some embodiments, this procedure may be carried out multiple times whilst varying a given parameter. For example, this procedure may be carried out whilst varying the wavelength/frequency of the generated E&M wave. In this way a reflectance spectrum showing the reflectance of the material at different wavelengths may be obtained. In addition, intensity spectra may be obtained for each wavelength of input light. This may enable comprehensive characterization of the material, including characterization of the molecular, atomic, and electronic structures including electronic transitions characterization. In one embodiment, the light source may comprise a tunable laser, connected with a MOEMS control system as described above, which can tune the light source's emitted wavelength. In further embodiments, this may be done at multiple discrete locations on the surface of the material, or over larger areas to enable surface tomography of the material. Other variable parameters for differential reflectance spectroscopy may include adjusting the angle of incidence, or temperature (e.g. oven actuation). Although described herein with reference to particular sensor devices, such as wave-based sensors, the present disclosure contemplates that any sensor device of any type may be used with the building material data management techniques of the present disclosure.

The spectroscopy techniques describe herein may each be configured to detect different parts of an amorphous material through spectroscopy (e.g., aggregate vs cement matrix). The individuals characterizing each part (e.g., one or multiple times) may be used to build a spectra. These techniques may, as would be evident to one of ordinary skill in the art, be used to determined (1) the presence of particular spectral lines, the ratio of spectral lines (e.g., ratio of the intensities), the width of spectral lines (e.g., FWHM), and/or the change over time in the presence of spectral lines, their ratios, their width and the like. Although described herein with reference to the spectroscopy techniques of the present disclosure, each of these techniques, outcomes, characteristics, etc. may be equally applicable to MAIS as described above (e.g., non-photonic spectroscopy types) and any frequency dependent determination.

### Maturity Thermal Monitoring

In some embodiments, non-wave-based sensors, such as point temperature sensors may be used in some embodiments. The temperature sensors may enable temperature correction for the other sensors/transducers and/or actuators in the sensing device. The temperature sensors may further be configured to enable maturity sensing in cementitious mix related applications. Thermal Tails (including MPTTs) may be used for spatial temperature characterization of the material. In this combination, it may be possible to map out the temperatures in the regions wherein the waves sent through wave-based sensing may travel, and account for these temperatures/normalize using context awareness methods for example. Point sensors such as temperature sensors (e.g., maturity sensors) may be used in combination with any other sensor type described herein. In particular, the combination of a temperature sensor and at least one other sensing or actuation method is considered to form the basis for some embodiments of enhanced maturity methods. Enhanced maturity may further include instances in which a sensor device is self-calibrating, such as using electrochemical impedance or electromechanical impedance to calibrate the mix under consideration and then make use of the maturity method. Furthermore, temperature monitoring may occur over time. The embodiments described herein may relate the temperature to rate of reaction, and from that computing change in properties with a calibration and a normalization. Still further, thermal profiles (spatial and temporal) and thermal control (e.g. to avoid cracking) may be determined. These profiles may be beneficial for quality assurance and quality control for materials. By way of example, a string of temperature (e.g., maturity) sensors connected to an embedded device, or matrices of sensors may be used to rebuild thermal profiles and detect thresholds. These may be linked to quality records and/or AI models as described herein. In some embodiments, “smart microscopes” may be sued to collect cuts of materials at different scales to inform multi-scale models. Additionally or alternatively, in any embodiment, cameras and/or LIDAR may be used to track quantity and volumes of input raw materials (e.g., rebar) going into a concrete pour (e.g., for embodied carbon tracking).

### Data Sources and Inputs

With reference to FIG. 1, the building material data sources 120 may include one or more individual building material data sources (e.g., 122, 124, and/or 126). In this way, the system 100 may receive any number of building material data sources 120. In some embodiments, receiving the first dataset may include ingesting a plurality of data records. Further, in some embodiments, the plurality of data records may include at least one of a construction document, a user input, sensor data, or machine data.

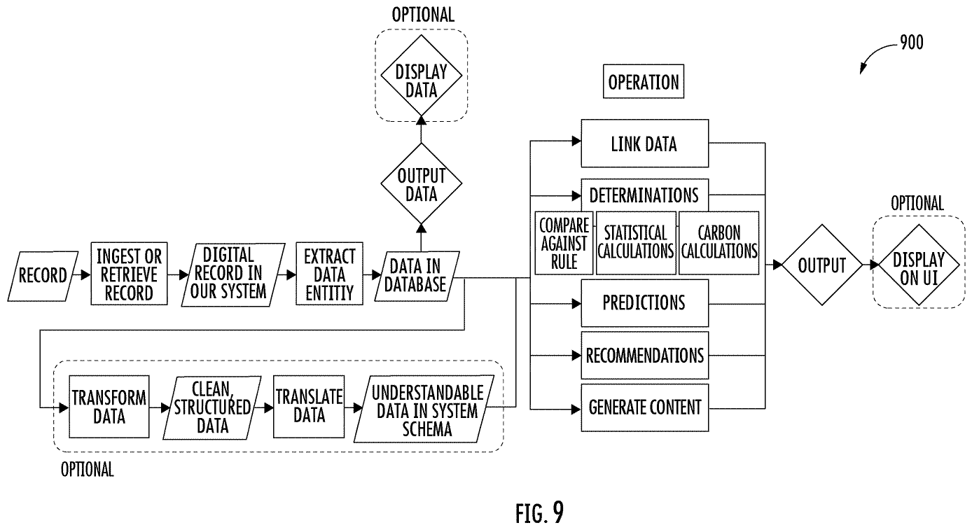

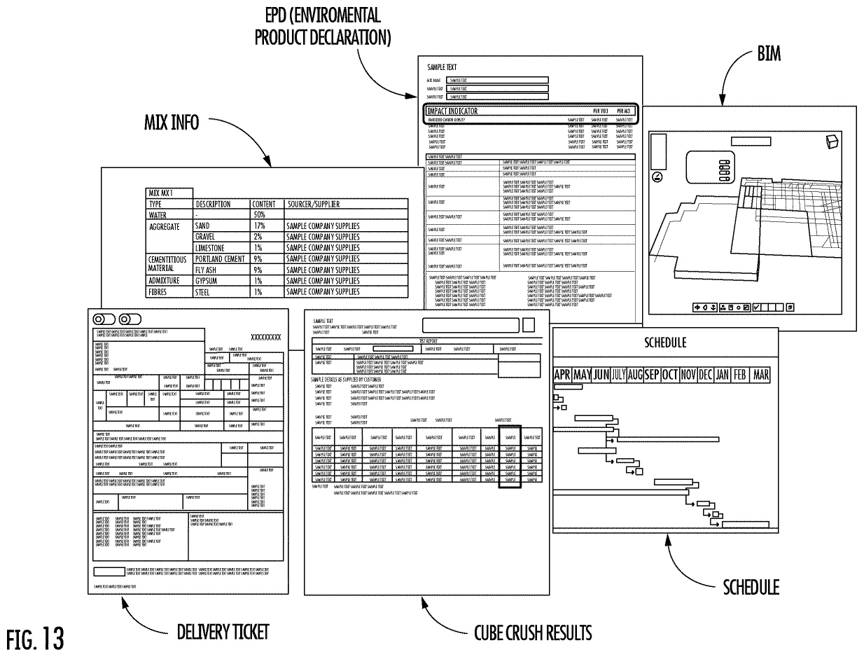

For example, as shown in FIG. 9, a record may be ingested or retrieved via the system 100. In some embodiments, the plurality of data records may include digital records, such as those shown in FIG. 13. In some embodiments, the records may include mix information (e.g., concrete mix information, concrete mix designs, material specifications), an Environmental Product Declaration (EPD), floorplans, building information modeling (BIM), a delivery ticket, crush results, material testing records (e.g., compressive, flexural or tensile strength results) a schedule of the project, or the like. In some embodiments, the crush results may include crush results for various geometric shapes, including but not limited to cubes, cylinders, prisms, and the like.

In this regard, the system 100 may ingest or retrieve the record via the server 130 (e.g., as shown in FIG. 1). The record may be retrieved from a variety of sources, including a user device 140, a building material data source 120, a database 150, and/or a sensor device. The record may flow through the network 110 to reach the server 130 by communicating with the network 110 via the communication interface 206, as shown in FIG. 2.

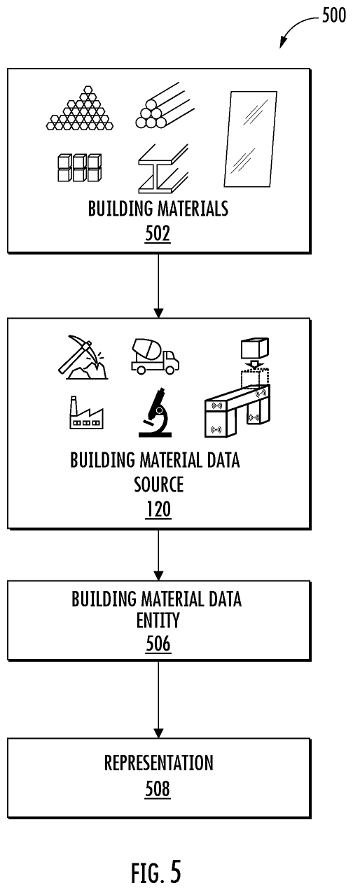

For example, and process flow 500 of FIG. 5 provides an overview of the building material data management process. The building material data source 120 may include building materials 502 (which also may include building materials 301) to create a building material data entity 506 (which also may be building material data entity 330). Further, a representation 508 may be produced that includes data from the building materials 301, the building material data source 120, and/or the building material data entity 330. In some embodiments, the plurality of data records may include real-time data, or near real-time data, collected from multiple stages of the building material's lifecycle. In this way, near real-time may include microseconds, seconds, minutes, hours, days, weeks, months, years, decades, or centuries, or any appropriate timeframe. For example, this may allow for end-to-end tracking of the embodied carbon, quality control metrics, or volumetric information passed along to various project stakeholders. The system 100 may facilitate automating the collection, linkage, processing, analysis, and the like of the data at every stage, and may incorporate real-time sensor data to further process and enhance the data analysis.

The real-time aspect of the system 100 may enhance the overall efficiency and accuracy of building material data management, as described herein. By integrating real-time data, which may originate from a variety of sources as described herein, the system 100 may provide instantaneous (or near-instantaneous at any order of magnitude of time delay) updates on material conditions, performance, environmental factors, and the like. For example, as shown in block 802 of process flow 800, the system may receive a first data set (e.g., in real-time) which may data form a construction document. As discussed herein, the construction document may include data relating to compliance reporting of a building material which may be used later to determine the performance of the building material during production, installation, or the like.

Further, as shown in block 804, the process flow 800 may receive a second dataset which may include data from a building material data source. For instance, and by way of non-limiting example, data ingested from sensors embedded in a particular concrete mix may monitor temperature, humidity, or curing time of the concrete on-site that will provide data used in determining whether adjustments to the process are needed. In this way, the real-time data may also feed directly into the system to provide continuous tracking of the building material as it moves throughout the construction project.

Further still, and as shown in block 806 of process flow 800, the first dataset and the second dataset may be compared. Additionally, or alternatively, the system may process and analyze the ingested data in real-time simultaneously along with historical records, which may offer up-to-date insights on quality and status metrics related to the building material. For example, real-time quality analysis may ensure the building materials meet required compliance specifications prior to installation, which reduces delays associated with faulty material installations. Further, and as shown in block 808 of process flow 800, the building material data entity may be generated. In this way, the building material data entity may be generated based on the comparison of the datasets, which may include differences from an actual and expected performance of the building material data entity.

Similarly, in some embodiments, AI models may perform the steps as shown in process flow 800. In this way, one or more AI models may communicate with one another in real-time to make predictive decisions, such as forecasting models or risk identification in the construction process. In some embodiments, the real-time analysis may include analyzing data up to a first time, which may include data ingested and process up until an initial point, which may also serve as baseline data. Further, in some embodiments, data may be collected up until a second time, which may be a point in time after the first time. In this way, the data associated with the first time and the data associated with the second time may be compared, analyzed, processed, and the like. It is to be understood that the real-time analysis may also include numerous points in time and should not be limited to the first time and the second time. Said differently, the operations described herein may be performed iteratively such that the first and/or second time may refer to any time at which the operations of the systems described herein occur.

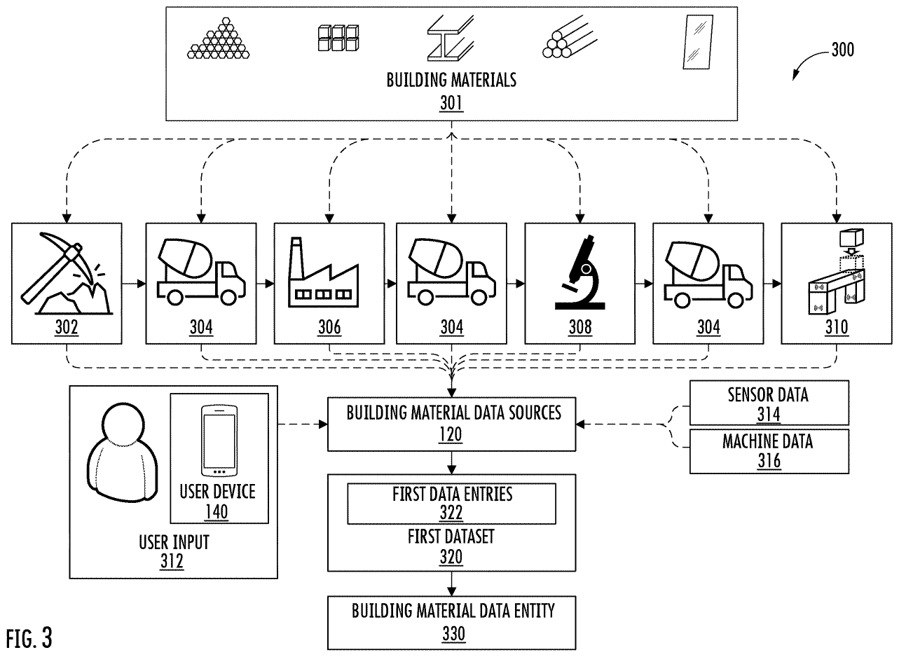

Further, with respect to FIG. 9, the record (e.g., digital record) may be stored in the system 100. In this way, the record may be stored in a variety of places, including the memory 202 of the server 130, a memory on the user device 140, or the database 150. Further still, and in some embodiments, a building material data entity (e.g., the building material data entity 330 in FIG. 3) may be extracted from the record. The extraction of the building material data entity from the record may be caused by the server 130 (e.g., in the processor 204, the AI engine 208, or the ML model 210), or another associated device (e.g., the user device 140). The extracted building material data entity may also be stored in a similar fashion, such as in the database 150 or on the server's 130 memory 202.

In some embodiments, a report may be generated that includes information and data relating to the building material data entity. In this way, the report may be a communication or file (e.g., an email communication, a PDF report, or the like). The report may incorporate the one or more computed values, anomalies (if any), status alerts (e.g., pass, fail, warning, etc.) associated with the building material data entity. Further, the report may be generated for a single pour or a multiple pour in embodiments where concrete is the building material. In some embodiments, the report may include an operation and maintenance manual that may be generated automatically upon the system receiving data associated with the building material data entity. Further, the report may include a project handover report which may summarize all compliance and quality status associated with the project.

Additionally, or alternatively, the building material data entity may, in some embodiments, be outputted onto a display. The display may include the display of the user device 140. In this regard, the user device 140 may include a graphical user interface that may be configured by the system 100, the server 130, or the like, to display the extracted building material data entity.

Further, in some embodiments, the system 100 may transform the data and/or building material data entity by cleaning and structuring the data. In some embodiments, the system 100 may translate the data to make the data understandable in regard to the schema of the system 100. For example, the building material data entity may be processed via the server 130 in order to transform and translate the data prior to further processing.

In some embodiments, the operation of the system 100 may include data linkages, determinations, predictions, recommendations, or generating content. In this regard, the building material data entity may be further processed by the system 100 to analyze the building material data entity further. For example, the determinations generated based on the building material data entity may include comparing it against a rule (e.g., a crush rule), performing statistical calculations, performing carbon calculations, or the like.

Further, the system 100 may determine which operational step is appropriate to provide a deep analysis on the building material data entity. In this regard, a request for a particular output may be received that may indicate that a particular operation should be performed. For example, if a request is received to determine an embodied carbon calculation, the operations performed on the building material data entity may provide the appropriate analysis to provide the calculation relating to the embodied carbon.

Further, in some embodiments, the operations performed by the system 100 on the building material data entity may then be outputted as a representation on the user device, for example. Similar to above, the representation may be displayed on the display and/or user interface associated with the user device 140. Further still, in some embodiments, the construction document may include at least one of material data (e.g., which may include cube data, cylinder data, crush test results, or the like), delivery data, or regulation data.

Further, the present disclosure may include a variety of building material data sources 120. In some embodiments, a building material data source 120 may include data relating to a building material (e.g., the building material 301 as shown in 300 with respect to FIG. 3). In this way, the building material data source 120 may relate to the process, creation, excavation, transportation, usage, or the like of the building material 301. Further, data may be generated such as geographical data, climate data, volumetric data, qualitative data, quantitative data, and the like that relate to the building material data source 120 and/or the building material 301. Additionally, or alternatively, the building material data source 120 may include one or more building material data sources, such as a first building material data source 122, a second building material data source 124, or an Nth building material data source 126, as shown in FIG. 1. The additional building material data sources (e.g., 122, 124, 126) may include any and all of the features associated with the building material data source 120 as described herein. Further, the additional building material data sources may communicate with or be integrated into each other or a building material data source 120. In this way, and in some embodiments, the building material data sources (e.g., 120, 122, 124, 126, etc.) may generate, communicate, or transmit data among each other.

In some embodiments, a building material 301 may include any material used in a construction or building process to construct or create an element, building, structure, or the like. For example, a building material may include concrete, concrete ingredients/aggregates, a cementitious mix, admixtures, wood, steel, glass, MEP (mechanical, electrical, plumbing) assemblies, rebar, etc. In some embodiments, a building material may be a homogenous material that includes the same uniform material throughout. In other embodiments, a building material may include composite materials that include one or more materials. For example, a building material may include reinforced concrete, wherein the reinforced concrete includes concrete and rebar.

Further, the building material may be mined, extracted, or the like from an excavation site 302. In this regard, a building material data source 120 (e.g., one of the building material data sources 120) may include the excavation site 302. In this regard, the building material data source 120 may include data from the excavation site 302 such as quality or quantity of the building material 301 excavated.

Further, in some embodiments, the transportation 304 of the building material 301 may be included in the building material data source 120. In this way, the building material data source 120 may include source information, destination information, transportation equipment information (e.g., a vehicle used to load, transport, or unload the building material). The transportation 304 may further include distances from each of the steps and/or processes shown in FIG. 3. In this regard, the transportation 304 may include the transportation of the building material 301 from the excavation site 302 to a manufacturing site 306 to a building material test site 308 to a project site 310, or any combination of the foregoing.

Further, in some embodiments, the building material data source 120 associated with the transportation 304 may include construction documentation that includes delivery tickets. The delivery tickets may include information associated with the delivery of a given building material 301 (e.g., concrete) to a project site (e.g., the project site 310). The delivery tickets may take a variety of forms, including a physical paper document, an electronic document, text file, datasheet, spreadsheet, picture file (e.g., JPEG, PNG), digital object file (e.g., JSON) and any other digital format used to represent textual information as would be clear to one skilled in the art. Further, the delivery ticket may include specific information relating to the delivery of the building material. For example, the delivery ticket may include, but is not limited to: Project/Site name or ID; Delivery Ticket ID; Delivery Date; Delivery Time which may further include (Time Batched, Time Arrived, Time Discharged); Mix Design name or Mix ID; Batching Plant Name; Customer Name; Order ID; Quote ID; Delivery address (site address); Delivery quantity; Concrete Mix Design description and/or composition (including but not limited to its description, density class, chloride class, exposure class, etc.); Haulier Name and ID; Vehicle registration number; Delivery number (specifying its position within an order of several deliveries); Site Contact Name and Number; Order quantity (total and cumulative); Order status (e.g. Scheduled, Delivered, Cancelled, Returned, etc.); Delivery cost/price and currency; Concrete mix design unit price and currency; Supplier system concrete mix design reference; Custom recorded comments; Concrete volume returned; Water added to the concrete on site; Quality Technician load observations and tests (including but not limited to temperature, slump observations, etc.); (E) Signature details; and Concrete mix design data.

Further still, in some embodiments, the manufacturing 306 of the building material 301 may also be a building material data source 120. The manufacturing 306 may include data associated with a quality and quantity of the building material 301 that was manufactured. For example, the data included may include which raw materials were used in the manufacturing process such as the building material's 301 origin, composition, and quality, which may indicate the final building material's 301 characteristics. Further, the building material data source 120 may include data on the manufacturing site's 306 processes themselves, including specific methods, machinery, technology used to create and/or process the building materials 301. For example, the manufacturing 306 may include kiln usage to manufacture building materials. Further, the manufacturing 306 may also include the manufacture of the raw materials (e.g., building materials) that are used in creating or constructing the building material.

Further still, in some embodiments, some building materials may be combined to create other buildings materials, which may happen during manufacturing 306. For example, concrete and rebar may be combined to create reinforced concrete (e.g., a building material 301) that may be used further in the steps as described herein. In this example, the reinforced concrete may have several building material data sources originating from the concrete and the rebar. The data ingested by the system 100 regarding the concrete and the rebar may include the building material data sources 120 from the sites where the concrete and rebar originated, were manufactured, and the like.

In some embodiments, a building material test 308 may be included in the steps shown in FIG. 3. The building material test 308 may include quality tests of the building material and/or the raw materials that compose or create the building material. In some embodiments, the building material test 308 may include using samples of the building material 301 to determine the quality of the building material as compared with compliance requirements. Further, the data included in the building material data source 120 may include data such as the mechanical, thermal, and chemical properties that may indicate strength (e.g., compressive, tensile, or flexural), durability, flexibility, workability, and the like.

For example, the building material test 308 may include crush test results. The crust test results may include construction documentation that contains information associated with compliance sample crush tests. In this way, crushes may use some sample from a particular material (e.g., building material) to determine performance of the material. For example, concrete crush test results may include concrete compliance sample crush tests. The crush test results may include a variety of forms, including a physical paper document, an electronic document, text file, datasheet, spreadsheet, picture file (e.g., JPEG, PNG), digital object file (e.g., JSON), and any other digital format used to represent textual information as would be clear to one skilled in the art. Data contained in a record may include (but is not limited to): Project/Site name or ID; Mix Design name or Mix ID; Material IDs (including both site/contractor id and lab id) for every material in the material group; Crush test records i.e. the compressive strength of a given material, alongside the age of the cube as recorded by physically crushing it using a concrete crusher, hydraulic press and/or any other equipment which may be used for crushing as clear to one skilled in the art; the compressive strength is often denoted in megapascals (MPa) or pound per square inch (PSI). In some embodiments, the age of the material is often denoted in hours or days and may be recorded as the duration of time between the concrete is poured into its mold and the moment it is crushed. Crush records may often include the above data for many materials in a material group. Material groups are collections of materials prepared from the same batch, to be used as compliance materials against this same batch as delivered to site. Further, a concrete record may include crush tests grouping reference (to identify which samples were created from the same delivery/load); Date the sample was made; Date the sample was received by the laboratory; Date the sample was tested; Dimensions of the sample; Density of the sample; Possible slump/flow/slump flow data; Specified strength of the sample's concrete mix design at a specific age; Possible location data (identifying the element and/or pour where the concrete mix design load was used); Lab comments/remarks; Customer comments/remarks.

Further, in some embodiments, other types of mechanical tests may produce records that are relevant to the material data. For example, a material may be tested for its flexural strength or its tensile strength. Similar to the crush tests (producing the compressive strength of the material), the flexural strength may indicate the ability of the material to flex under a load or force while the tensile strength may indicate the ability of the material to respond to a specified tension. These tests may provide records, data, and the like on building materials used throughout the process as described herein. Further, the tests may be building material data entities 330 that may be extracted from a building material data source 120 configured to perform, record, and produce the test and/or test results.

In some embodiments, the construction documentation may also include Slump Test Records (including one off measurements of slump, or photos/videos of slump tests being carried out, but also continuous measurements of slump through any of the sensor embodiments already described herein); Concrete mix design supplier/customer qualitative data (e.g. comments and/or remarks) on a specific delivery; Customer/laboratory qualitative data (e.g. comments and/or remarks) on a specific sample/strength observation; BIM Models; Mix Information; Concrete mix design EPDs (and any EPDs for the constituent raw materials themselves); reinforcement bars EPDs (e.g., for steel and/or rebar reinforcement); Construction site concrete mix design specification documentation; pre and post-pour inspection sheets; photos and videos of the construction site; quality and compliance records; forms and checklists; permits to strike; permits to tension; permits to load; other types of permits; specifications; drawings; floorplans; any other type of record mentioned elsewhere in this disclosure.

Further, in some embodiments, a project site 310 may be included as a building material data source 120. In some embodiments, the project site 310 may include, but is not limited to, a construction project site wherein the building material is used to construct a structure. The project site 310 may provide data on how the building materials 301 are used before, during, and after construction. For example, data generated from the project site 310 may include data on the receiving process, on-site storage, material handling, installation process, compatibility with other building materials 301, performance after installation, and the like of the building materials 301. Further, in a specific example, the project site 310 may produce data relating to how well the building material 301 performs under environmental conditions after the building material 301 has been installed in the construction project.

### User Input

In some embodiments, another building material data source 120 may include user input 312. In some embodiments, information may be requested from a user through a notification or prompt on the platform (e.g., the system 100), as part of the data ingestion process (e.g., an online form to be completed as part of data ingestion), or via a user device 140. Some relevant data which may be ingested by the platform through user input includes (but is not limited to) the following end location/destination identifier—for a given pour associated with a given batch/delivery, or for a given delivery in its entirety. For example, relevant user input may be represented as a text string and/or any other format understood to be used as an identifier. In some embodiments, the user input may also be selected by the user from a list of pre-existing locations on the site. In other embodiments, a destination of the list of pre-existing locations may be created and inputted by the user as a text string into the software platform. In further embodiments, this text string may be saved into the pre-existing list of locations such that a future user may be able to select this location from the list going forward. Further, the list (e.g., the pre-existing list of locations) may be visualised on the platform as a drop-down menu a user would be able to select from.

Further, in some embodiments, the user input 312 may include an end element type identifier associated with a given pour of a given batch or delivery, or for a given delivery in its entirety. For example, this may be represented as a text string and/or any other format understood to be used as an identifier. Some examples of end element type identifiers include: column, slab, wall, beam, and other element types understood to be such to one skilled in the art.

Further, in some embodiments, the user input 312 may include slump and flow information as a measure of the concrete's consistency (e.g., provided in associated with every delivery). For example, this may include slump value (e.g., in millimeters, flow, slump flow, slump grading, and the like).

In some embodiments, other user input 312 data may also include pre- and post-pour inspection forms and the information associated with those activities (e.g. pour ID, inspection results, additional comments). In other embodiments, any of the data types previously listed as ingested from documentation may also be manually inputted by users, for example delivery data and cube strength data, and any other user observation.

In some embodiments, domain translation methods may be used to ingest data from any of these above systems or data sources, including data from different stakeholders (e.g. from concrete suppliers or test labs) and translate them into a unified domain usable by the methods/platform described in the present disclosure. This unified domain may be applicable to any other methods in any other section herein, such that data from these other systems may be integrated into this platform. In further embodiments, both original data and the translated data may be stored in the platform records.

### Sensor and Machine Data

Additionally, or alternatively, and as shown in FIG. 3, sensor data 314 and machine data 316 may be another building material data source 120. In some embodiments, the building material data source 120 may include a sensor device configured to generate data associated with the building material data source 120. This includes all of the sensor device types and data types described elsewhere herein (including sensors embedded in pours, directed at pours, mounted on pours, sensors on trucks, sensors at the batching plant). Further, the same applies to machine data 316 from any hardware used throughout the value chain (including the crane, the concrete pump and the like on the jobsite, and also the batching machinery, mixer, drum, silo's and mixing equipment at the batching plant, as well as the kiln during cement production and so on). Further, the sensor data 314 and machine data 316 may be collected from any of the building material 301 process steps as shown in FIG. 3 (e.g., 302, 304, 306, 308, 310, and so on). This sensor data 314 and machine data 316 may be ingested in real-time or collected asynchronously.

In some embodiments, the sensor data 314 and machine data 316 may include a timestamp of when the building material 301 is installed at the project site 310. The timestamp may include a date and time that the building material 301 is installed. In this way, the sensor data 314, for example, may be embedded in a building material produce a signal that the building material is installed. The sensor that produces the sensor data 314 may have preset or predetermined coordinates (e.g., geographical coordinates) based on one of the data records (e.g., the BIM) and may produce and transmit the signal once the embedded sensor is in the correct location. Further, the sensor data 314 may be collected for all building materials used on the project site 310 to determine the overall status of the build.

Further, in some embodiments, and as shown in block 406 of FIG. 4, the disclosure may provide for generating a building material data entity based upon the first dataset associated with the building material data source. For example, as shown in FIG. 3, the building material data entity 330 may be based upon the building material data source 120. In this regard, and in some embodiments, the building material data entity 330 may include a first dataset 320 which may include data, a data element, information, or the like that is derived and extracted from the data associated with the building material data source 120. Further, the first dataset 320 may include one or more first data entries 322, which may include specific data as it relates to a building material 301. For example, the building material data entity 330 may include specific values and/or data (e.g., the first data entries 322) extracted from a particular building material data source 120. In a specific example, the building material data entity 330 may include mix ratios of the building materials 301 used to create a particular concrete mix (e.g., the building material data source 120). Further, in another example, the building material data entity 330 may include crush test results associated with the particular concrete mix.

Further still, the sensor data 314 and/or machine data 316 and/or digitized records data may determine a surplus of building material 301 associated with the build. In this way, the sensor data 314 associated with excess building materials 301 may be gathered and analyzed by the system 100 to determine that the excess building materials 301 were not used during construction. For example, the sensor data 314 may report unused building materials 301 after the project has been completed. The system 100 may be able to determine that a surplus of building materials 301 exist. Further, in some embodiments, it may be determined that the surplus of building materials 301 constitute a waste of building materials 301. In this way, the building materials 301 (and associated sensor data 314) may be determined to have been wasted via damage, redundancy, project change orders, or the like.

Further still, the sensor data 314 and/or machine data 316 and/or records data and/or any measure extracted and computed based on any of the above (e.g., total cumulative volume poured to date) associated with building materials 301 may be compared against one of the records (e.g., the BIM) to determine an expected use of building materials 301. The expected value may be compared against an actual usage of the building materials 301 to determine a surplus or a waste. In this way, the comparisons may include comparing against several iterations of the project stage. For example, the project may have an as designed usage of building materials, an as delivered usage of building materials, and an as installed usage of building materials. Each of these iterations may be compared against one another to determine a waste of the building materials along the several project stages.

Additionally, or alternatively, the building material data entity 330 may include data from the building material data source 120 that may be used for further analysis by the system 100, the server 130, the processor 204, the AI engine 208, or the ML model 210. In this regard, the building material data entity 330 may be able to provide, either on its own or through further processing, information about a corresponding building material data source 120.

### Crush Rules

In some embodiments, the building material data entity 330 may be associated with material data extracted from the first dataset 320. The crush rules may include compliance rules or the like associated with the building material. For example, the crush rules may include rules associated with the different crush samples (e.g., cube crush samples, cylinder crush samples, prism crush samples, etc.). Further, in some embodiments, the crush rules may be specific to the particular shape of the crush sample. For instance, and by way of non-limiting example, a crush rule may include a cube rule that is associated with a cube crush test result. Further, as described herein, any explanations or descriptions relating to a particular cube rule shape (e.g., a cube rule) may apply to any other crush rule (e.g., a cylinder rule, a prism rule, or the like). In specific embodiments, the type of crush rule (e.g., cube rule, cylinder rule, prism rule, or the like) may be dependent upon geographical locations of the crush test. In this way, and in some embodiments, the system may determine, based on the geographical location of the project site, the appropriate crush test to apply. For clarification, if a description herein provides that a process or step uses a specific rule (e.g., a cube rule), it is to be understood that the process or step may also include any other crush rule (e.g., a cylinder rule, a prism rule, or the like).

In some embodiments, this may include comparing cube data of the building material data entity 330 with one or more cube rules. For example, a building material data entity 330 may relate to cube rules associated with a concrete cube (e.g., building material 301). In some embodiments, the crush rules may denote a set of conditions placed upon the result of one or a plurality of crush tests. The disclosure herein may apply crush rules onto ingested data to check for compliance, and display a cube status, for example, which is indicative of the relationship between the result and the rule. Example Cube Rules may include ranges of values a crush test result must fall within, which may be described as hard coded values, or as functional forms, which may in some embodiments, be any functional form dependent on the design strength of the mix associated with the given cube.

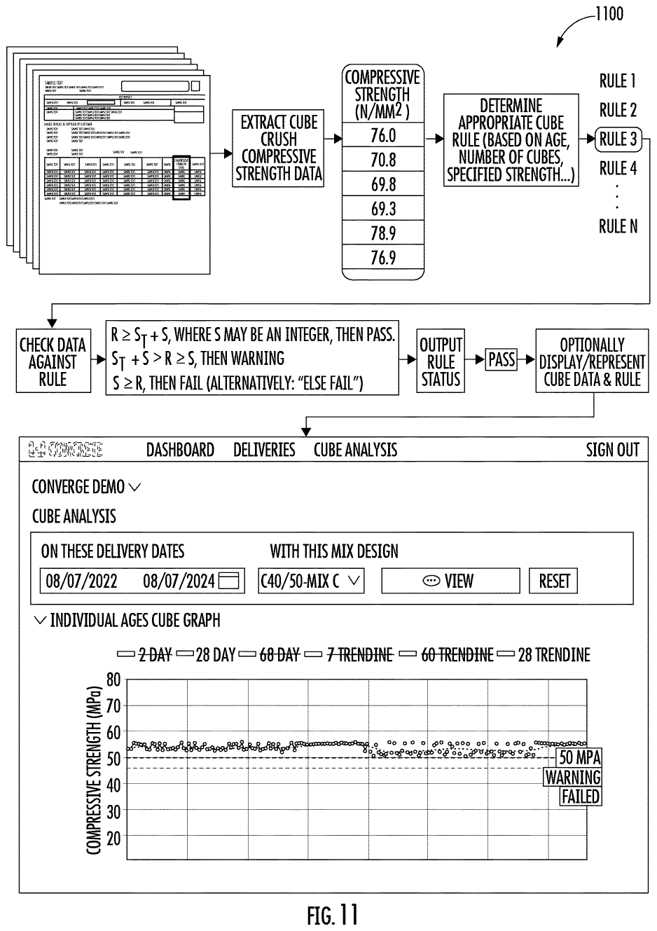

In some embodiments, crush rules may have associated types, which are categorisations used to group rules together according to some grouping definition. For example, as shown in FIG. 11, the cube rules may be extracted from a cube crush result document. In some embodiments, extracting the cube rules from the cube crush result document may include an automated extraction via the server 130, the AI engine 208, or the like, or by a user input 312. The information extracted from the cube crush result document may include the compressive strength data associated with the cube. Further, in some embodiments, an appropriate cube rule may be determined to be used. In this regard, the determination of which cube rule to use may be based on age, the number of cubes, the specified strength, or the like. Additionally, or alternatively, once a cube rule is chosen, the data associated with the rule may be used for further analysis, as will be discussed in greater detail below. Further, in some embodiments, the status associated with the cube rule may be outputted. In this regard, the representation may include the rule status (e.g., pass, fail, warning), which may be displayed on the user device 140. For clarification, the process as shown in FIG. 11 may be applied to any crush rules as compared with any crush result and is not limited to cube rules and cube crush test results.

In one embodiment, these types may be categorised as one of the following: individual, pair, or aggregate crush rules. The individual crush rules may denote rules associated with the result of a singular crush. The pair crush rules may denote rules associated with the results of a pair of crushes, considered together. In some embodiments, the pair may designate materials (e.g., building materials) of the same mix, crushed at the same age. Further, the aggregate crush rules may denote rules associated with the results of more than two crushes, considered together in aggregate. Typically, aggregate rules are designed for building materials of a given mix, crushed at the same age. In some embodiments, these rules consider the results from a set of pairs (e.g. 2 to 6 pairs).

In some embodiments, the method may include comparing material data of the building material data entity with one or more crush rules, as shown in block 602 of process flow 600. The comparison may include using material data, such as crush results of the building material, to determine if the building material meets certain crush rules. The determination of whether the crush results meets a crush rule may include generating a rule status. In some embodiments, rule statuses may include: a pass, a warning, or a fail. In some embodiments, and as shown in block 604 of process flow 600, in an instance in which the material data fails to satisfy the one or more crush rules, a failure alert may be generated. Further, in some embodiments, and as shown in block 606 of process flow 600, in an instance in which the material data satisfies the one or more crush rules, a passage alert may be generated. In some embodiments, and as shown in block 608 of process flow 600, in an instance in which the material data is within a warning threshold associated with the one or more crush rules, a warning alert may be generated. In some embodiments, the material data may include data associated with the building material. In this way, the material data may include crush results, crush tests, material test records, material crush results, or the like associated with the building material. Further, in some embodiments, the material data may be associated with the building material data source or the building material data entity.

For example, the pass (e.g., the passage alert) may denote the condition has been satisfied, the warning (e.g., the warning alert) may denote that the material test result is within a predefined range close to the failure threshold, but that it still passes, and the fail (e.g., the failure alert) may denote the condition has not been satisfied. In some embodiments, rule statuses may be created and defined, in some cases by users (e.g., as a user input 312). This may in some embodiments involve defining an identifier for a status (e.g. string text; sequence of integers), as well as a value range for the test which is associated with the status. In some embodiments, the value range may be defined as a functional form. Further, as will be described below, the rule statuses may be outputted as a representation.

In some embodiments, crush rules may form part of the platform/system/method logic. In this regard, the crush rules may form part of the system 100. They may be hard coded, such that they apply to any material and/or building material. In some embodiments, crush rules may be hard coded for building materials of a particular group e.g. any building material of mix A, or any building material from provider B, or any building material on site C, or any building material on project D, and any other grouping as may be clear to one skilled in the art.

In some embodiments, crush rules may be created by users and inputted to the system 100 as user input 312. In some embodiments, users define one or a combination of the following when creating a rule: Mix Design, Rule Type, Crush Age, Rule Identifier/Name. In some embodiments, the users define a set of specified range of values (or singular values) the building material result (e.g., a crush result) must fall within, alongside associated rule statuses. One example may be defining a status identifier “Double Strength!”, and defining this status be associated for “Crush_Test_Result>2×(specified design strength)”. In some embodiments, once a crush rule is defined, the range of pass, warning, fail, and other statuses may be displayed (e.g., as a representation) visually for users to see. Users are able to name their rules—in some cases users may be able to choose from pre-existing rules or create their own. For aggregate crush rules, one part of the rule to be defined may include the number of material pairs that constitute a discrete bin for the moving average to roll over.

In some embodiments, template rules may be available on the platform (e.g., the system 100) for users to choose from. Template rules are likely to be common rules many users may require. In some embodiments, template rules may be automatically recommended to users based on some information. For example, template rules may be recommended to users based on location/geography. This may include the geography/country they are accessing the platform from, or the geography the site (e.g., the project site 310) associated with the user is located in.

In further embodiments, these values (e.g., crush rules) are hard coded as ranges of real numbers and using equalities of inequalities. In other further embodiments, users may define a rule using functional forms. Users may define these rules using a GUI specifically designed for rule creation, which may comprise the ability to select variables (e.g. design strength), input values, select binary or non-binary operators e.g. addition, subtraction, division, multiplication, exponents, logarithms, modulus, absolute value, integrals, derivatives, and other operators as would be clear to one skilled in the art. In some embodiments, for example for aggregate rules, confidence interval tolerances may be defined, wherein if a group of building materials may pass the rule within that confidence interval tolerance, the aggregate rule is still complied with e.g. for a 95% confidence interval, if less than 5% of building materials fail the compliance test, the aggregate compliance is still adhered to. Further, in some embodiments, the users may use the user device 140 to create the rules.

In some embodiments, crush rules may be extracted from documentation in an automated method. This may include extraction from physical documentation, for example through image or video data. Machine Vision and/or multimodal machine learning based models may be used to convert a rule written down on a physical document, into a rule integrated into the platform. This may include taking a picture of a mathematical equation, inequality, and/or generalised functional form written down on paper and using machine learning to interpret the equation as a rule and integrate it into the platform. In one embodiment, when users create new rules, the platform may allow for the option to “upload photo” or “upload video”, which the platform may use to extract. Further, the user device 140 may be equipped with a camera that the user may use to scan the physical document to capture the crush rules. In some embodiments, the user device 140 may then upload the documentation to the system 100 via the network 110. In some embodiments, the server 130 may use the AI engine 208 or ML model 210 to integrate the rule into the system 100.

This may also include extraction from digital documentation. Digital documents such as specification, codes and/or other regulatory documents as clear to one skilled in the art may be parsed for crush rules using machine learning methods (e.g., using the AI engine 208 or the ML model 210), as well as non-AI text or image parsing methods.

In one embodiment, the crush rule creation GUI (e.g., associated with the user device 140) includes the option for users to upload documentation to be parsed and incorporated as rules (e.g., via image, video, document, spreadsheets etc.) in a plurality of formats (e.g., PDF, PNG, MP4, JSON, and the like).

In an embodiment, once the platform (e.g., the system 100) has successfully extracted the rule, it is displayed on the GUI associated with the user device 140 for the user to see. The user may then edit and/or confirm/validate the rule, such that it then may be applied as part of the platform logic. In another embodiment, the relevant documentation may be sought online or within a particular database, and retrieved by the system, before being automatically parsed and rules. In some embodiments, the database 150 may have the relevant documentation and the system 100 may access and retrieve the rules from the database 150. Further, in some embodiments, the system 100 may access an additional database via wireless or wired connections (such as via the Internet) to determine which rules may be needed. Further, the rules may be updated and edited by authorized users at any time. The method described herein may be used to extract construction rules of any kind, from any type of documentation, and may not only be restricted to crush rules. For example, rules associated with best practices during building may be extracted from building codes.

Example crush rules include but are not limited to the following (e.g., a material test result is denoted R, and specified design strength at age T is denoted ST, for convenience).

Individual rule examples are as follows. Rule A may include R≥S_{T}+S, where S may be an integer, then PASS; S_{T}+S>R≥S, then WARNING; and S≥R, then FAIL (alternatively: “else FAIL”). Rule B may include R≥S_{T}+x, where x may be an integer, then PASS; and Else, FAIL. The following may be a generalised for of an individual rule in some embodiments: g(S_{T})≥R≥f(S_{T}), then [STATUS].

Pair rule examples (e.g., for two test results R₁ & R₂): percentage diff(R₁, R₂)≤x, then PASS. Else FAIL. Wherein percentage diff denotes the percentage difference function applied onto R₁ & R₂, and x is a percentage value. |R₁−R₂|≤ΔS, then PASS. Else FAIL. Wherein AS may denote a prespecified difference in compressive strength. f(|R₁−R₂|)≤X, then PASS wherein X may be a value of compressive strength, or a percentage. g(X_{b})≤f(R₁, R₂)≤h(Xₐ), then [STATUS], this may be a generalised form of a pair rule in some embodiments.

Aggregate Rule Examples—for a set of N test results of the same mix, and age. The test results may be denoted Rᵢ, wherein i is any number in the range {1,N}. In some embodiments, aggregate rules are determined based on considering sets of cube pairs. Results for such pairs may be denoted {Rᵢ, Rᵢ₊₁} moving average (R₁, R₂, . . . , R_{N})≥S_{T}+x, then PASS. Else, FAIL. Wherein, moving average may denote the moving average function as would be clearly understood by one skilled in the art. In some embodiments, this may include any type of moving average (e.g. simple, cumulative, weighted). For a subset of consecutive crush results of cardinality n, wherein the subset comprises crush test results from the last M pair averages (where M may often be a number between 2 and 6), which may correspond to pairs crushed within a period in time Tₛ to T_{f}. One datapoint in the moving average, comprises the mean of all Rᵢ within that subset. Further moving average data points comprise calculating the average for every subset of consecutive Rᵢ. This happens continuously as cubes are tested, producing a crush result Trendline, when depicted graphically. More formally, considering data-set of crush results comprising initially N data points: {RN}={R₁, R₂, . . . , R_{N}}, the simple moving average is the mean over the last k datapoints. This may defined as

$${SMA}_{k} = \frac{1}{k} {\sum }_{i = n - k + 1}^{N} {R}_{i} .$$

The moving average considers the mean over every bin of data, so the next moving average may be defined as

$${SMA}_{k , next} = \frac{1}{k} {\sum }_{i = n - k + 2}^{N + 1} {R}_{i} ,$$

and so on and so forth. When the dataset is smaller than k, then the mean of the size of the dataset is considered ∀(moving averages) in set {R_{N}}, if Rᵢ==PASS for p %*
|{R_{N}}|, then PASS. Else FAIL Oftentimes p=95% confidence interval. For all values of the moving average computed, if as a whole, the values PASS the aggregate test described above at least p % of the time, then the test is PASSED. Otherwise, the test is FAILED.

Specific examples of rules may include the following. For example, for a building material (e.g., a concrete mix design) with a specified strength of 40 MPa at 28 days, the following rules could apply: Individual Rules: 7 day, 0<=R<20 WARNING, 20<=R PASSED; 28 day, 0<=R<36 FAILED, 36<=R<40 WARNING, 40<=R PASSED; 56 day, 0<=R<40 FAILED, 40<=R PASSED. Pair Rule: for a pair of 28 day building materials in the same group ABS(R1−R2)<=0.15*AVG(R1, R2)->PASSED (i.e. 15% difference, varies by geography). Else FAILED.

Aggregate Rules: For a moving average with a sliding window size of at least 2 and maximum 6 pairs; For each pair calculate the average, so there is a list of pair averages of at least 2 to 6; If the window sliding size is [2,4] (Inclusive), then the average of the pair averages has to be equal to specified strength+1; If the window sliding size is [5,6] (inclusive), then the average of the pair averages has to be equal to specified strength+2.

It is to be understood that rules may comprise any general functional form associated with an equality or inequality. In some embodiments, rules may be applicable to any type compliance sample. It is often the case that rules may vary by geography, and it is to be understood that the system of rules designed herein may be implemented with respect to any compliance rule from any geography. In some embodiments, rules may be automatically extracted from compliance documentation in any geography e.g., through AI language parsing methods. In some embodiments, the method may comprise a database of rules, which may be pulled into the platform. The rules may be grouped by geographies, project type, or the like. It will be clear to one skilled in the art that the rules system disclosed herein may apply beyond concrete samples and may be applied to any quantitative condition placed upon any building material and/or process associated with construction or building materials. It may also be applied to qualitative conditions wherein numerical conditions may be replaced by qualitative characteristics (e.g. colour, system may be able to automatically access camera feed data to make sure colour of a building material complies with condition or requirements).

Further, in some embodiments, rules may be determined by an AI model based on similar sites (e.g., project site(s) 310), or based on the incoming data. Rules may be static, or dynamic (change over the lifetime of a jobsite). In particular, the AI models may determine a better set of rules which are more adequate for quality tracking and compliance.

In some embodiments, rules may also include and aggregate other measures (not just crush results), such as slump data or any output of any sensor data 314, machine data 316, or building material data source 120. Generally, these rules can be applied at any stage of the concreting process (from the production of the raw materials such as cement, to the batching of concrete, to the pouring of concrete on a site). For example, in the case of cement, the equivalent compliance sample may be a mortar produced based on the cement output from a kiln, which is then also crushed. For rebar, it may be a pull test. In this regard, these rules can be seen to apply to any material test result, which may be inputted or extracted from a record.

### Data Outputs and Visualization

In some embodiments, the disclosure may provide for outputting a representation of the building material data entity 330. In some embodiments, the representation may include the building material data entity 330. Further, in some embodiments, the disclosure as provided herein may output the building material data source 120 or any associated information as a visualization or a representation on a graphical user interface (GUI). In some embodiments, the representation may be outputted on a GUI of the user device 140. Further, the representation may be outputted in many different visual formats. Further still, as shown in block 410 of process flow 400, the method may include outputting a representation of the building material data entity.

In one embodiment, a toolbar allows users to select the broad categories of data they would like to see, including Delivery Data, Building Material Data or Building Material Analysis Data, and a Dashboard with aggregated insights. Additionally, or alternatively, the data (e.g., the representation) may be outputted through IT systems (e.g. APIs) into other digital tools.

In some embodiments, delivery data may showcase data associated with the delivery of building material batches on the GUI. The user may be able to select the timeframe of interest, such that only delivery data within this timeframe may be shown to the user. The user may also be able to select a one or a plurality of mix designs of interest, in some embodiments from a pre-existing list of mix designs for which delivery data exists. Delivery data may be shown alongside other associated data including but not limited to building material crush data. In some embodiments, the data may be also filtered based on an element type, combination of mix design and element type, based on some specifications, or a combination of all of these filters.

In one embodiment, the GUI for delivery data may comprise aggregated data for deliveries and other associated data. This may be for the full history of deliveries, or may be grouped by mixes, or be shown for a specific timeframe. Alternatively, or additionally, this may be grouped by element type and/or use case. Specific embodiments of such aggregated data may include delivery summary data, which may include aggregated metrics associated with delivery. For example, this may include the total number of deliveries, average delivery time/duration, average discharge time/duration (e.g., discharge may refer to the process by which building materials 301 are moved from the truck to the project site 310).

Further, the aggregated data may include compliance data that is associated with whether the batches and/or loads that have been delivered are compliant with specifications and/or other regulatory requirements, or if they pass certain regulatory tests. For example, the compliance data may include a total number of compliance cube reports, a total number of individual cube test reports and breakdown of this number with associated test result (e.g. pass, warning, fail), a total number of pair cube test reports and breakdown of this number with associated test result (e.g. pass, warning, fail), a total number of aggregated cube test reports and breakdown of this number with associated test result (e.g. pass, warning, fail), or the like.

Further, the aggregated data may include delivery volumes data, which may include metrics associated with the volume of building materials delivered. For example, this may include the total volume of building materials delivered or the breakdown of volume by element type (e.g., the volume of concrete used as pours per type of building elements, which may include beams, columns, walls, blinding, stairs, core walls, waste, other, etc.).

In some embodiment, the GUI comprises data associated with deliveries, which may be individual deliveries, or groups of deliveries. In some embodiments, this data may be showed in a tabular form on the GUI, wherein each row denotes a separate delivery, and the columns may comprise any one or any combination of the following fields (non-exhaustive list): Delivery Ticket ID, Delivery Date, Batch/Load end Location, Mix Design ID/Reference, Mix Strength Class (e.g. C32/40, C40/50, C50/60), Slump (either recorded slump or slump grading), Delivery Volume, Breakdown of volume by end element type, Other comments.

For example, in one embodiment, cube data indicative of cubes created from concrete in a given delivery may be shown on the GUI as well, clearly in association with deliveries. This data may include the following: Number of cubes associated with the delivery, Cube rule types associated with the delivery, Cube Rule Type & Status for each cube associated with the delivery, Cube ID/Reference (e.g. string text, or sequence of integers), Delivery ID/Reference, Mix Name (e.g. C40/50 ABC 1), Request Sheet N°, Client Reference, Date Made (date cube was created), Date Tested (date cube was tested), Age (e.g. in 7, 28, 56 days), Sample location (e.g. location wherein the batch associated with the cube has been poured), Density (concrete cube density e.g. 2400 kg/m³), Cube Compressive Strength (i.e. crush test result e.g. 20 MPa or 20 N/mm²), Load (i.e. compressive strength divided by cross-sectional surface area of cube e.g. 200 kN), Specified Design Strength at 28 days, etc.

In some embodiments, the representation may include the data association of the building material data entity 330. For example, a user may expand each row to view this building material data on the GUI, for example through the use of a button on each row. In some embodiments, this may be viewed in a tabular form comprising a row for each building material. In one embodiment, for any data associated with a crush rule, rule type or rule status, for an individual building material, or a plurality of building materials, details associated with the calculations undertaken for determining whether the given building material(s) satisfy the rule may be included for the user to see, including a step-by-step breakdown of calculations. In some embodiments, this may be viewable on the GUI by hovering or clicking on a given rule status. In some embodiments, rule statuses may be colour coded (e.g. Fail statuses may be shown in red, and pass statuses may be shown in blue).

In another embodiment, any of the operations and outputs described above may be accessed through an API, or other command line based/non-GUI based approach. Additionally, or alternatively, interfacing with the inputs or outputs may be done through a conversational interface (e.g., AI-based GPTs and the likes), notifications (e.g. user device 140), augmented or virtual reality, mobile or tablet apps and the like.

### Building Material Analysis

In some embodiments, the data analysis may include building material analysis which may showcase data from cube results as well as analysis done on these building material results. Building material analysis may take the form of an interactive graph chart on the platform's GUI, or tabular data which may be grouped according to a grouping definition. The user may be able to select the timeframe of interest, such that only building material data within this timeframe may be shown to the user. The user may also be able to select a one or a plurality of mix designs of interest, in some embodiments from a pre-existing list of mix designs for which building material data exists. In some embodiments, building material analysis data may be shown alongside other kinds of data.

In one embodiment, building material analysis may be showcased through a visual, graphical representation of individual building material result history over time. This comprises a graph showing building material strength results against time. In one embodiment, this graph is a scatter plot. In one embodiment, this graph is a line graph. The datapoints along this line graph represent building material test result values for building materials of a given age. The datapoints may be connected by a straight line. In some embodiments, a trendline may be computed and viewable. In some embodiments, data for building materials of different ages, grouped by said age, and in some embodiments, colour coded by age group, may be viewable on the same plot. In some embodiments, error bars depicting the error or uncertainty associated with each datapoint may be viewable. In some embodiments, one or a plurality of datapoints, connected by straight lines, with associated trendlines, each representing building material data for building materials of respective ages may be viewable. In some embodiments, these ages may be 7 days, 28 days, and 56 days, or any other. In some embodiments, the graph may depict regions where a datapoint may pass, fail or be attributed another status with respect to a given rule. In some cases, these regions may be depicted by colour coded contoured areas on the graph.

In some embodiments, building material analysis may showcase aggregate building material analysis in a graphical format. This graph may depict a moving average of building material strength through time. Every moving average datapoint may represent the mean of between 2 to 6 consecutive crush pair results, which themselves are means of each individual crush result in the pair. In some embodiments, the aggregate building crush rule may be depicted as a line demarcating the region on the graph which may be a pass from a fail. In some embodiments, if an aggregate average/moving average datapoint falls below the line, it may be a fail, whereas if the datapoint is above the line, it may be a pass.

In some embodiments, building material analysis data may be shown in tabular format. This data representation may group building materials by associated delivery into an individual building material group, such that building materials associated with the same delivery may be part of the same group and that is captured visually. For example, the building material ID and/or reference may be captured. In this regard, and in some embodiments, the system may use an internal logic to create building material IDs where there are none. For example, one logic may comprise creating a building material ID that follows the following schema: dd_i_N, wherein “dd” represents the digits for the day (in the date format) that the building materials were created, “i” represents deliveries on a given day, ordered by first arrival and starting at 0, “N” represents a letter assigned to building materials associated with a delivery (e.g., the first building material assigned is A, the second is assigned B, and so on). Further data that may be captured is: Date Made (date building material has been created), Building material Group ID (groups are typically created according to deliveries, and multiple groups may be created on any given day since many deliveries may arrive to site on any given day), Building material age when crushed, Recorded building material strength when crushed, Independent Building material Rule Status, Pair Averages (typically for a pair of building materials in a given rule), Pair Status (status of the pair according to a given pair building material rule), Aggregated Average (moving average, typically for the last 6 consecutive building materials), Aggregated Status (status of the moving average/aggregate of building materials according to a given aggregate building material rule.

In some embodiments, the data analysis may include deploying an AI engine to perform the statistical analysis on the building material data entity. Further, in some embodiments, the representation may include the statistical analysis on the building material data entity 330 performed by the AI engine.

In some embodiments, the representation may include generating a visual presentation of the building material entity 330. For example, for any datapoint herein, it may be possible to hover over it on the GUI, and more information regarding the datapoint may be shown, including the y-value of the datapoint, as well as text describing what the data is e.g. “moving average of the last 2-6 data points”, delivery dates, delivery ID, group reference ID and any other information described herein or that may be clear as relevant data to one skilled in the art. It is to be understood that the visual representations and methods described herein, may be used to depict any other kind of data described herein. Further, any operation, input, output or method may be executed or accessed through non-GUI based approaches (e.g. APIs and the like).

### Dashboard and Data Insights

Further, a dashboard may capture aggregated insights from all the data collated into the platform. In this regard, the dashboard may include the representation outputted that contains the building material data entity 330 and/or any analysis (e.g., operations) performed on it. In one embodiment, the dashboard may comprise a Site View & a Mix Design View. The Site View comprises insights indicative of the site (e.g., the project site 310) as a whole (e.g., total concrete volumes delivered to site). The user may be able to select the timeframe of interest, such that only site insights within this timeframe may be shown to the user. The Mix Design View comprises insights associated with particular mixes. The user may be able to select the timeframe of interest, such that only mix design insights within this timeframe may be shown to the user. The user may also be able to select one or a plurality of mixes of interest.

In some embodiments, the Site View dashboard may comprise the following insights. Note, this list is non-exhaustive, and other insights associated with the site, as clear to one skilled in the art, may be displayed: Total number of concrete deliveries to site, Total volume of concrete to site, Breakdown of number of deliveries & volumes delivered by concrete mix, and/or Total volume of concrete wasted.

In some embodiments, the Mix Design View dashboard may including the following insights (non-exhaustive): total reports (may be broken down by mix design)—this may include the total number of reports existing for crush tests (This may oftentimes be equivalent to the total number of building materials crushed), total concrete volume by mix design, total individual mix report for building material crushes at every age tested (e.g. 7, 28, 56 days), which may be broken down by rule status (e.g. how many tests passed, failed, warning), total pair mix reports for building material crush pairs at every age tested, which may be broken down by rule status (e.g. how many tests passed, failed, warning), total aggregate mix reports for building material crush aggregations at every age tested (i.e. moving average rules), which may be broken down by rule status (e.g. how many tests passed, failed, warning), total volume of concrete broken down by mix, and broken down by ultimate element type.

It is to be understood that any of the data described herein may be outputted as grouped according to any other data field described herein. For example, this may include grouping delivery tickets by end locations, or grouping building material results by associated pour location.

### Carbon Tracking and Accounting

Carbon tracking may showcase carbon data associated with the project. In some embodiments, this may be data indicative of embodied carbon in concrete, in other embodiments, this may be data indicative of carbon from construction/building operations as well, in other embodiments, it may be data indicative of both. Further, the carbon tracking may include any portion of the project, which may include the project at any scale. For example, carbon of any stage of the project may be tracked from origination (e.g., excavation) of a building material to installation of the building material. Further, the smallest unit of a building material may be included in the carbon tracking process as well as the entire project. For example, embodied carbon tracking of the entire project may be produced by the carbon tracking and accounting process as described herein. In this way, the carbon may be tracked via analysing data associated with datasets of the building material.

Further still, it is to be understood that the carbon tracking and account steps as discussed herein may be applied to any building material type. In this way, the carbon (e.g., embodied carbon) that relates with building materials such as concrete, cementitious mixes, aggregates, wood, glass, steel, MEP assemblies, rebar, and the like may be tracked and accounted. For example, embodied carbon of a building material that is or includes rebar may be tracked and accounted using the steps as described herein. In this way, embodied carbon associated with a building material such as concrete reinforced with rebar may be analysed with the steps outlined here. Further, for clarification, any of the steps as described herein may relate to any building material. In this way, steps may reference a specific building material (e.g., concrete) but it is to be understood that tracking and accounting for embodied carbon of any building material may follow the same or a similar process.

As shown in block 702 of process flow 700, the method may include receiving carbon data via a sensor device associated with a building material data source. For example, an embedded sensor may generate and transmit carbon data associated a first dataset associated with the building material data source. In some embodiments, for example, the first dataset (e.g., the first dataset 320 as shown in FIG. 3) may include carbon data including an amount of carbon associated with a building material 301 associated with the building material data source 120. The user may be able to select the timeframe of interest, such that only carbon data within this timeframe may be shown to the user. The user may also be able to select a one or a plurality of mix designs of interest, in some embodiments from a pre-existing list of mix designs for which carbon data exists.

Further, as shown in block 704 of process flow 700, the amount of carbon associated with the building material data source may be determined. For example, the carbon data that may be calculated by on the platform may include the total cumulative embodied carbon in building materials 301 delivered to date (e.g., embodied carbon in concrete delivered in tons or kilograms). Further, the carbon data may include Embodied Carbon in delivered concrete broken down by any categorisation described herein. This may include tracking embodied carbon by (non-exhaustive): Element Type (e.g., walls; beams; columns; core walls; pile caps; slabs; stairs; retaining walls; core walls; plinths; pile caps; temporary works; waste; and the like), Mix Recipe, Day/Month (and/or other temporal delineation).

Further still, as shown in block 706, the carbon data may be outputted as a representation. In this way, the data showing the amount of carbon (e.g., embodied carbon) may be outputted as a representation on a user device 140, or the like. Further, the represented carbon data may include the data determined to be associated with the building material data source.

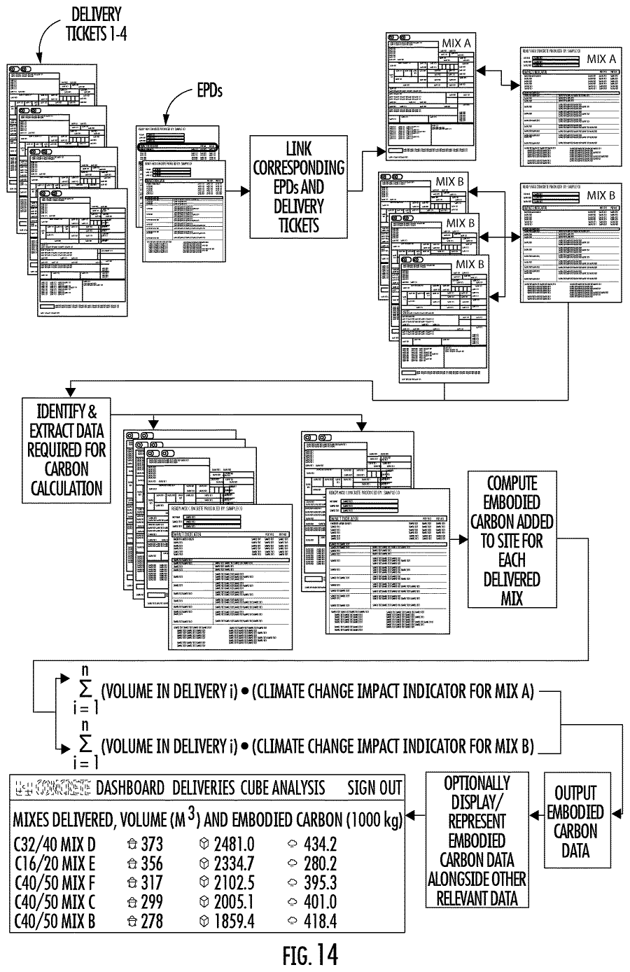

For example, as shown in FIG. 14, an example of an embodied carbon calculation process is shown. The plurality of records (e.g., delivery tickets, EPDs, or the like) may be ingested by the system 100. In some embodiments, data linkages and/or associations may be created between the plurality of records, for example, the delivery tickets and the EPDs. The linkage between the documents may include identification of the building material, analysis of a carbon impact of the building material 301, a quantity of the building material 301, and other associated information of the building material 301. In a specific example, when tracking embodied carbon of the entire project, all of the EPDs relating to the project may be aggregated, linked, and analyzed to determine the overall embodied carbon of the project site 310. Further, in some embodiments, the system 100 may extract the data associated with the data linkages for further computation of the embodied carbon. For example, the calculated embodied carbon may include the embodied carbon added to the project site 310 for each delivered concrete mix. In some embodiments, the embodied carbon may be calculated for any type of building material 301.

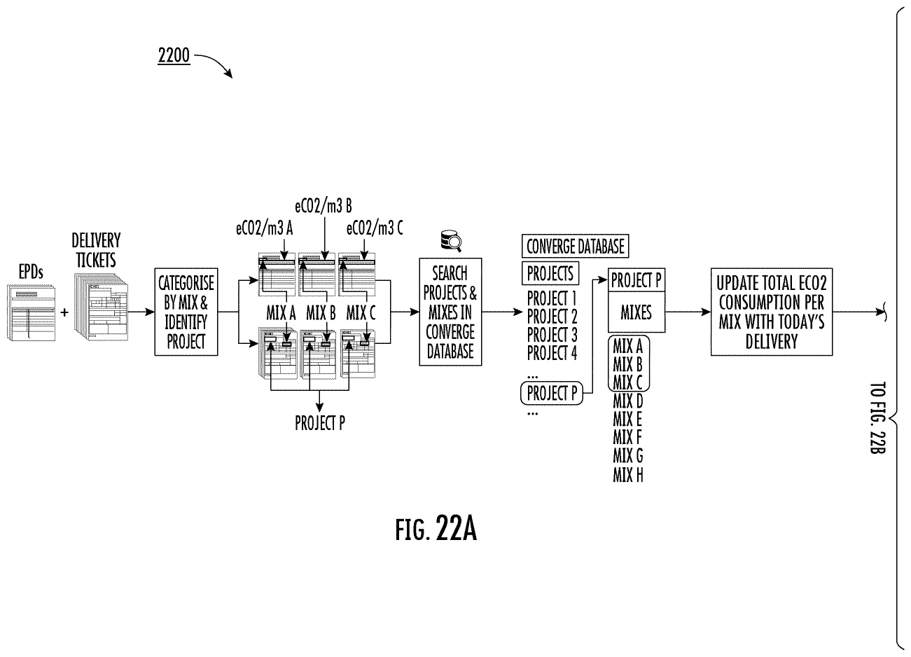

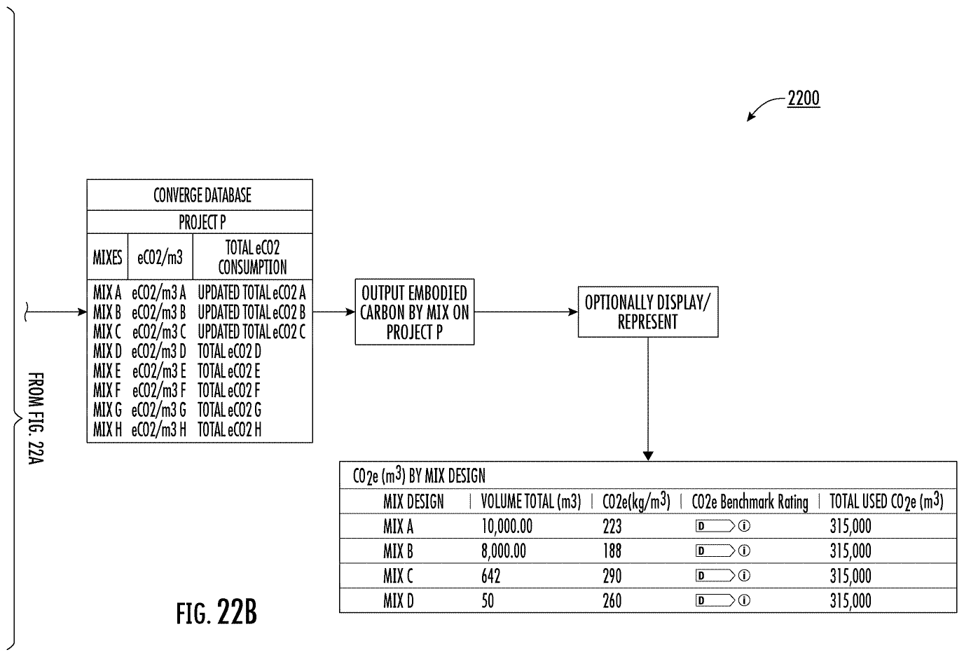

For example, as shown in FIGS. 22A and 22B, the total embodied carbon may be determined by mix in real-time. In some embodiments, as shown in FIG. 22A, the plurality of records (e.g., EPDs and delivery tickets) may be ingested by the system 100. The documents and associated data may be categorized by mix and project. Further, the projects identified in the documents may be queried in the database 150, for example. In some embodiments, the total project embodied carbon consumption may be updated based on a mix with a particular delivery. In some embodiments, the particular delivery may include a timeframe of deliveries (e.g., a particular day's delivery), or the like. In some embodiments, and as shown in FIG. 22B, the embodied carbon by mix of a certain project site (e.g., the project site 310) updated in a database (e.g., database 150), and may be outputted and optionally displayed as a representation on a user device 140, or the like. Further, in some embodiments, the carbon tracking may occur in real time (or in near real-time, e.g., at a predefined maximum lag or time interval such as 10 minutes, one hour, one day, one week, one month, etc.), which may comprise collecting embodied carbon data from the building materials 301 as the building materials 301 are used throughout the construction project. In this regard, the building materials may be manufactured, transported, tested, installed, or the like, which may affect the embodied carbon of the building material 301. In some embodiments, each step in the process may include a distinct amount of embodied carbon that may be compared with a later step in the process. For example, the manufacture of a building material may be compared with the transportation of the building material. Further, each of the steps may be summed together to produce a running total of the embodied carbon of the building material 301. Further, in some embodiments, the totals (e.g., running totals) for each building material 301 may be aggregated to determine a total amount of embodied carbon for the project. Further, in some embodiments, the running totals may be compared to cumulative carbon budget for the complete portion of the project.

In some embodiments, a carbon target, or associated carbon limit or budget may be ingested by the platform. This may be automatically scraped from documentation for example, or manually inputted by users (e.g., as user input 312). Data associated or compared with this carbon target may be determined and/or displayed as well. This may include the total embodied carbon consumed against the carbon target. In one GUI embodiment, this may be displayed as a bar of different colors. In another embodiment, the historical cumulative consumed embodied carbon over time may be displayed graphically, against the carbon limit.

In some embodiments, each concrete mix design may have a volumetric embodied carbon figure, which may normally be quoted in units such as kg/m³. In some embodiments, the volumetric carbon figure may include a constant carbon value associated with the mix design itself and may be provided by an entity using the system 100 (e.g., a customer), wherein the customer may receive the value from their concrete supplier. In other embodiments, the carbon value may be variable. In an example, a customer may report that from a first date to a second date the carbon value is X kg/m³. A small modification may be made to the mix such that the carbon value increases to a value of Y kg/m³. The system 100 may be able to record the initial date and an optional end date for the carbon value. Further, when delivery data is ingested, the volume and concrete mix design may be recorded. In some embodiments, the mix (e.g., concrete mix) may stay the same but carbon intensity of the cement may vary (e.g., by way of using a different fuel in the kiln), which may result in the embodied carbon changing.

Further, in some embodiments, when a customer requests information regarding the carbon performance of their specific mix and/or project site, the customer may select the date range they are interested in. Further, the customer may check the deliveries that were made in that date range and the mixes used. Further still, for each mix design, the following actions may be taken: check the total value of deliveries for that mix; if there is also a carbon value associated with the mix, multiply the carbon figure by the volume to get total carbon for the mix; and either present a per-mix carbon value or sum all the carbon information for all mixes used in that date range.

TABLE 1
Mix Reference with Constant Carbon Values.

| Mix Reference | Constant Carbon Values |
|---|---|
| Mix A | 124.56 |
| Mix B | 158.65 |

TABLE 2
Mix Reference including Delivery Volumes.

| Delivery Ref | Delivery Date | Mix Reference | Delivery Volume |
|---|---|---|---|
| 1 | 2024 Sep. 20 | Mix A | 7.7 |
| 2 | 2024 Sep. 20 | Mix B | 7.5 |
| 3 | 2024 Sep. 21 | Mix A | 6.4 |
| 4 | 2024 Sep. 21 | Mix A | 8.3 |
| 5 | 2024 Sep. 21 | Mix A | 6.2 |
| 6 | 2024 Sep. 22 | Mix A | 8.3 |
| 7 | 2024 Sep. 22 | Mix B | 7.1 |
| 8 | 2024 Sep. 23 | Mix B | 7.5 |
| 9 | 2024 Sep. 23 | Mix B | 7.8 |
| 10 | 2024 Sep. 24 | Mix A | 8.1 |

TABLE 3
Mix A Deliveries.

| Delivery Ref | Delivery Date | Mix Reference | Delivery Volume |
|---|---|---|---|
| 1 | 2024 Sep. 20 | Mix A | 7.7 |
| 3 | 2024 Sep. 21 | Mix A | 6.4 |
| 4 | 2024 Sep. 21 | Mix A | 8.3 |
| 5 | 2024 Sep. 21 | Mix A | 6.2 |
| 6 | 2024 Sep. 22 | Mix A | 8.3 |

TABLE 4
Mix B Deliveries.

| Delivery Ref | Delivery Date | Mix Reference | Delivery Volume |
|---|---|---|---|
| 2 | 2024 Sep. 20 | Mix B | 7.5 |
| 7 | 2024 Sep. 22 | Mix B | 7.1 |
| 8 | 2024 Sep. 23 | Mix B | 7.5 |
| 9 | 2024 Sep. 23 | Mix B | 7.8 |

For example, with reference to Tables 1 and 2 above, a customer is interested in the total carbon (e.g., per mix and aggregate) in the 2024 Sep. 20 to the 2024 Sep. 23 (inclusive) date range. The two mixes used in that date range are Mix A and Mix B. Mix A is included in the deliveries as noted in Table 3. For example, there are 5 deliveries for a total delivered volume of 36.9 m³. The carbon value for Mix A, which is constant in this case, is 124.56 kg/m³, as shown in Table 1. The total carbon for Mix A in the specified date range therefore is 36.9 m³×124.56 kg/m³=4596.26 kg.

Further, the total carbon for Mix B may be calculated in a similar way. With reference to Table 4, there are 4 deliveries of Mix B for a total of 29.9 m³. The constant carbon value of Mix B (referencing Table 1) is 158.65 kg/m³. Therefore, the total carbon for Mix B in the specified date range is 29.9 m³×158.65 kg/m³=4743.64 kg.

In some embodiments, the customer may view the following carbon information: the date range selected, the carbon, the total carbon for Mix A, the total carbon for Mix B, and the total carbon for both Mix A and Mix B. In other embodiments, a customer may request information about the carbon performance of their mix and/or project site. In this way, the customer may select the date range they are interested and take the following actions for each mix design: check if a carbon figure is available; if a carbon figure is available, check the date range it is applicable to; multiply the correct date range carbon figure by the total volume of deliveries for that mix in the date range; and sum up all date range carbon values.

In another example, the following tables represent a mix reference that includes a carbon value that varies with time.

TABLE 5
Mix A with varying Carbon Values.

| Mix Reference | Start Date | End Date | Carbon Value |
|---|---|---|---|
| Mix A | 2021 Dec. 1 | 2023 Feb. 28 | 124.56 |
| Mix A | 2023 Feb. 28 | | 130.24 |

TABLE 6
Mix A Deliveries.

| Delivery Ref | Delivery Date | Mix Reference | Delivery Volume |
|---|---|---|---|
| 1 | 2022 Dec. 3 | Mix A | 7.7 |
| 2 | 2022 Dec. 5 | Mix A | 7.7 |
| 3 | 2022 Dec. 13 | Mix A | 7.7 |
| 4 | 2022 Dec. 20 | Mix A | 7.7 |
| 5 | 2023 Jan. 15 | Mix A | 7.7 |
| 6 | 2022 Jan. 28 | Mix A | 7.7 |
| 7 | 2022 Feb. 25 | Mix A | 7.7 |
| 8 | 2022 Mar. 3 | Mix A | 7.7 |
| 9 | 2022 Mar. 10 | Mix A | 7.7 |
| 10 | 2022 Mar. 20 | Mix A | 7.7 |

For example, a customer may be interested in the total carbon (e.g., per mix and aggregate) in the 2022 Dec. 1 to 2023 Mar. 31 (inclusive) date range. In this example, only Mix A is used in that date range. Referencing Table 5, Mix A's carbon value changed on 2023 Feb. 28 from a value of 124.56 kg/m³ to 130.24 kg/m³. In the date range of 2022 Dec. 1 to 2023 Mar. 31, there are two carbon values for Mix A: 2022 Dec. 1<=Delivery Date<2023 Feb. 28, the carbon value is 124.56 while from 2023 Feb. 28<=Delivery Date, the carbon value is 130.24. In the first subrange, with reference to Table 6, there are 7 deliveries with a total volume of 53.9 m³ and in the second subrange, there are 3 deliveries with a total volume of 23.1 m³. Therefore, the total carbon of Mix A in the complete date range may include the following calculations: 53.9 m3*124.56 kg/m3=6713.78 kg; 23.1 m3*130.24 kg/m3=3008.54 kg; for a total carbon value calculation of: 6713.78 kg+3008.54 kg=9722.32 kg. In additional embodiments, the customer may be a readymix supplier, and the methods as described herein may apply to orders of cement, aggregates, admixtures, and other subcomponents of concrete.

In some embodiments, the system may output a prediction for expected total carbon consumed/emitted. If this is larger than the carbon target, the system may flag or notify the user with a warning. In some embodiments, the prediction may be generated using predictive AI methods. In some embodiments, this carbon target may be broken down into targets per mix, and the used embodied carbon for each mix may be determined and/or displayed as compared against the target for each mix.

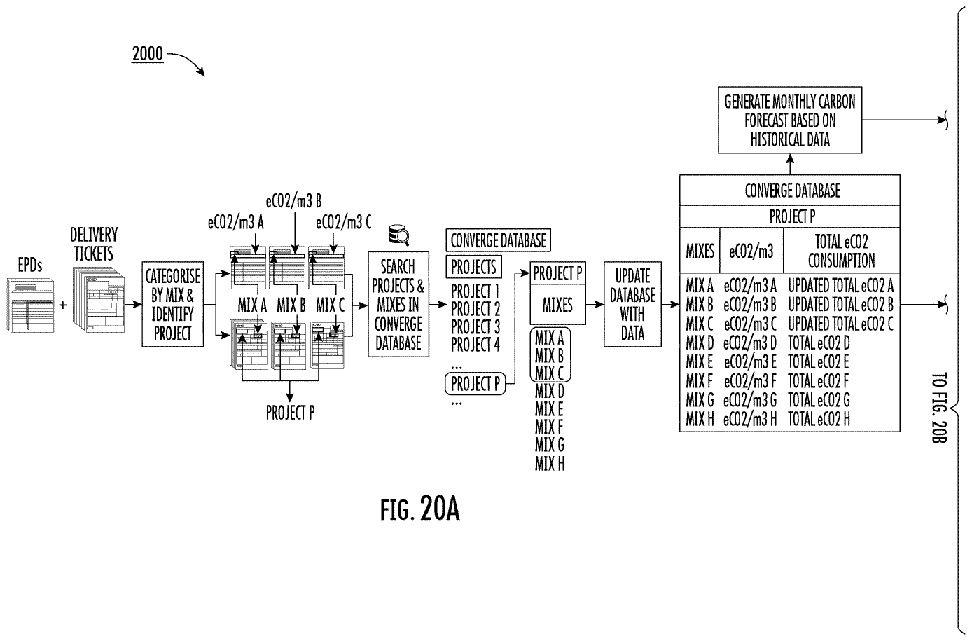

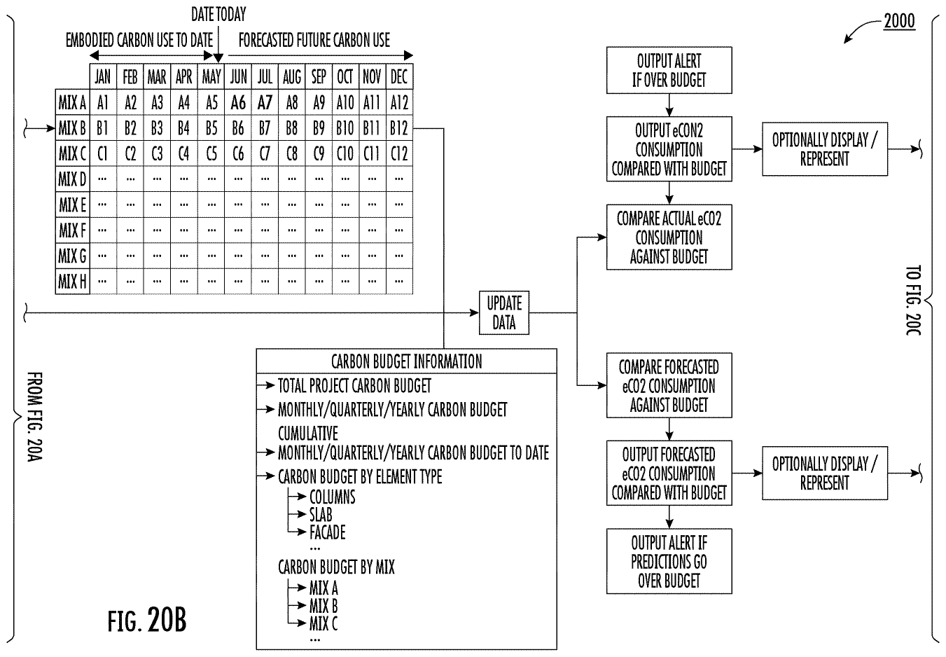

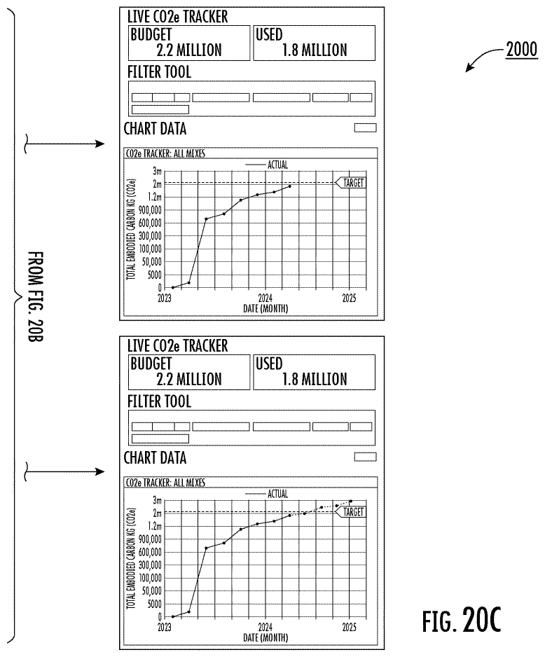

For example, as shown in FIGS. 20A, 20B, and 20C, the carbon limit and/or budget may be tracked in real time to determine an expected embodied carbon based on trends, remaining elements to be constructed, or the like. In this way, the plurality of records (e.g., EPDs and delivery tickets) may be ingested by the system 100, as shown in FIG. 20A. The documents and associated data may be categorized by mix and project. Further, the projects identified in the documents may be queried in the database 150. In some embodiments, as shown in FIG. 20B, a carbon forecast may be generated, which may take into account historical data and trends based on project usage of the specified mix. For example, data may show the embodied caron use to date and also the forecasted future carbon usage estimations. Further, in some embodiments, the carbon budget information may include a total project carbon budget, a time-based carbon budget (e.g., monthly, quarterly, yearly, etc.), the cumulative carbon budget to date, a carbon budget by element created with the building material (e.g., columns, slabs, facades, etc.), and a carbon budget by mix. In some embodiments, the prediction may be based on historical embodied carbon accumulated, a drawing, the BIM, the specification, the schedule, or the like associated with the project. In this way, mixes that may be used may be derived from the drawing, BIM, specification, or schedule, and multiplied by historical embodied carbon measures for such mixes. Such embodied carbon forecast may, in some embodiments, be dynamically updated as new data or records are ingested by the system.

In some embodiments, the carbon budget data may be ingested and compared with the actual embodied carbon density (e.g., eCO2) consumption compared with the carbon budget. In some embodiments, the output embodied carbon may be compared with the carbon budget. In some embodiments, if the actual embodied carbon is over the carbon budget, an alert may be generated. In further embodiments, the alert may be transmitted to a user device 140 wherein the alert configures the user interface and/or display to make the alert understandable to a user. Further, in some embodiments, and as shown in FIG. 20C, the data used to compare the embodied carbon and the carbon budget and the comparison itself may be outputted as a representation, which may be outputted on a user device 140.

Similarly, in some embodiments, the forecasted embodied carbon may be compared with the carbon budget. In some embodiments, an alert may be generated and outputted if the forecasted predictions go over the carbon budget. Further, the forecasts may be outputted as a representation to the user device 140. In some embodiments, carbon optioneering may be included, wherein mix to mix swaps may be applied to see impact on carbon forecast versus the carbon budget. In some embodiments, AI (e.g., the AI engine, AI agent, or the like) may swap mixes at different times and may apply the swaps to determine an impact on the carbon forecast as compared with the carbon budget. In this way, the mixes may be swapped at different times of the year and weather data may be integrated to determine the impacts.

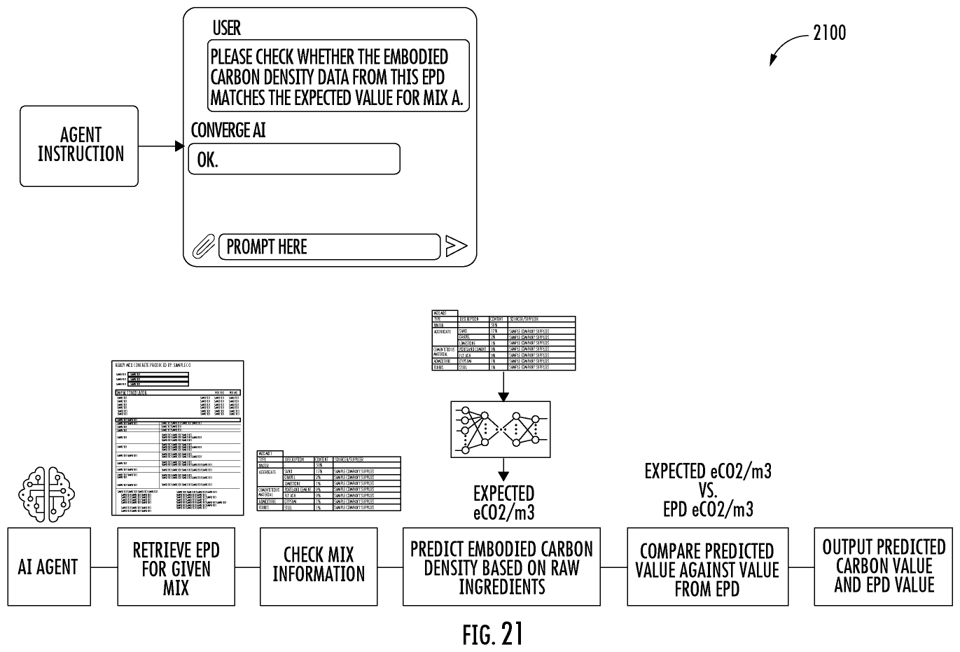

In some embodiments, and as shown in FIG. 21, the AI agent may analyze the plurality of records. For example, as shown in block 404 process flow 400 of FIG. 4, the method may include receiving, via the AI agent, the first dataset which may include the one or more first data entries associated with the building material data source. In this way, the AI agent may receive instructions (e.g., user input 312) from a user via a user device 140 to determine certain aspects of a given building material 301. For example, the AI agent may receive user input 312 to check if embodied carbon density data from a given EPD matches the expected value for a concrete mix. In this regard, the AI agent may ingest an EPD for the concrete mix. The AI agent may then check the mix information, which may available via upload from a user device 140, document retrieval from the database 150, or the like. Further, in some embodiments, the AI agent may predict the embodied carbon density based on raw ingredients associated with the mix. Further still, the AI agent may compare the predicted value against the value extracted from the EPD. In this way, the AI agent may generate the building material data entity 330, as shown in block 408 of FIG. 4. For example, the AI agent may generate the comparison between the predicted value against the value extracted from the EPD, which may include data from the first dataset. Further, the AI agent may cause an output of the predicted carbon value and EPD value. In this regard, the values may be outputted as a representation to the user device 140.

In some embodiments, carbon targets may be broken down into any relevant categorisation, including by element type for example (e.g. through user assignment). In some embodiments, the carbon data may be represented graphically. In some embodiments, this graph may be a bar chart, for example showing embodied carbon consumed per month. In further embodiments, the bar chart may showcase embodied carbon by mix or by element type, in some cases through colour coding. In some embodiments, carbon data may be displayed as a line graph or scatter plot, which includes datasets grouped by mix types, for example showcasing a line of different colours for each mix. On the same plot, the carbon target(s) may be displayed. In some embodiments, carbon data may be displayed as an area graph, comprising carbon targets and embodied carbon broken down by mix type. In some embodiments, carbon data may be displayed as a funnel graph, comprising carbon targets and embodied carbon broken down by mix type. Other embodiments may comprise any other graph type or graphical representation for carbon data as would be clear to one skilled in the art. These may be used for visualizing any other data types described herein as well, including delivery data and building material record data. In some embodiments, this data may be displayed in the aggregated dashboard described herein, as well as in combination with any other data type herein.

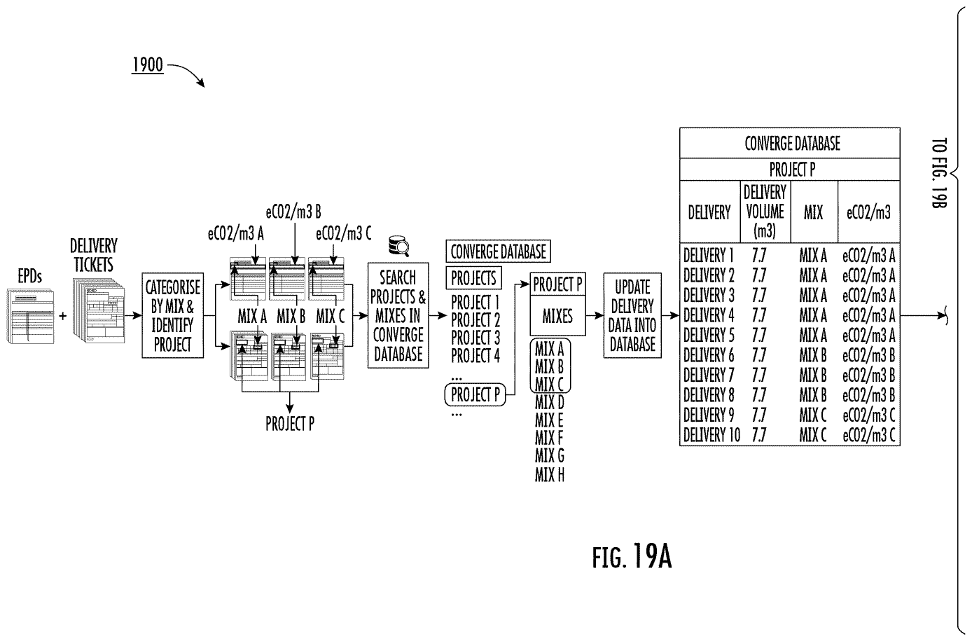

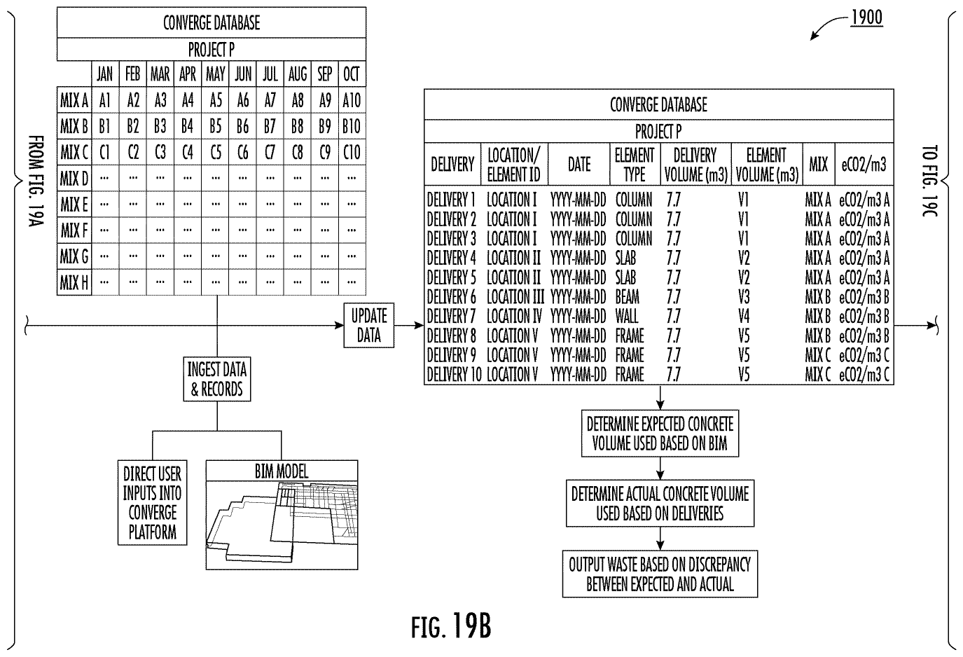

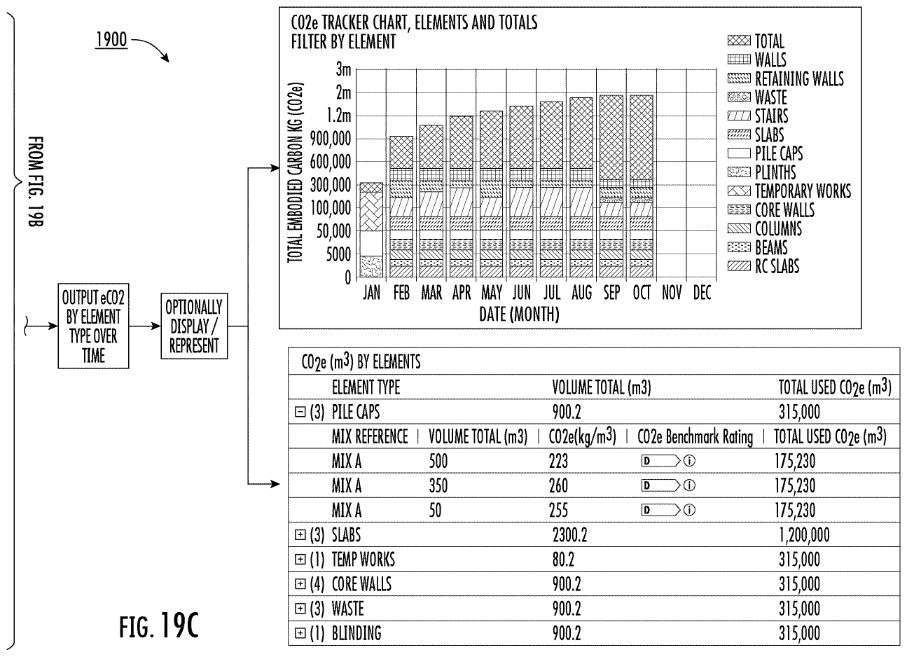

For example, as shown in FIGS. 19A, 19B, and 19C, the carbon by element (e.g., column, slab, façade, etc.) and/or by waste may be determined by the system 100. In some embodiments, as shown in FIG. 19A, the plurality of records may be ingested and analyzed by the system 100. Further, in some embodiments, after the database 150 is queried, the delivery data may be updated in the database 150. In this way, the delivery data may be updated to reflect the embodied carbon per delivery, for example. Further, as shown in FIG. 19B, in some embodiments, user input 312 and/or BIM models may be ingested by the system 100 to further update the data in the database 150. Based on the updated data, and in some embodiments, the determined expected concrete volume based on the BIM model may be produced. Further, in some embodiments, the determined actual concrete volume based on the deliveries may be produced. In some embodiments, both of these produced values may output a waste based on a discrepancy between the actual and expected values.

Further still, as shown in FIG. 19C, in some embodiments, the embodied carbon may be outputted by an element type, which may also include a timeframe over which the elements are created. For example, the embodied carbon associated with the columns of the project site 310 may be outputted against the timeframe in which they were created (e.g., days, weeks, months, years, etc.). Further, and in some embodiments, the output may include a representation of the carbon waste by element that may be displayed on a user device 140.

In some embodiments, the carbon data may be ingested from documentation or inputted by users for example by using the techniques described herein. This may include extracting data from EPDs for example. In some embodiments, an average carbon per unit volume for a given mix may be used to calculate embodied carbon, and total carbon may be calculated as the product of this average with the total volume of concrete consumed. In some embodiments, carbon associated or emitted from construction/building operations, for example from the transit/delivery of concrete, may also be taken as an input. In some embodiments, embodied carbon and delivery carbon may be displayed separately on the platform. In another embodiment, embodied carbon and delivery carbon or carbon from construction operations may be combined into an aggregated total carbon metric, which may be displayed as such on the platform. In some embodiments, carbon data may be computed from construction operation data. For example, this may comprise routing data e.g. map of route taken, total distance travelled in route, vehicle type, vehicle fuel type, vehicle fuel consumption data and more. This type of method may apply to any plant and machinery used as part of construction operations.

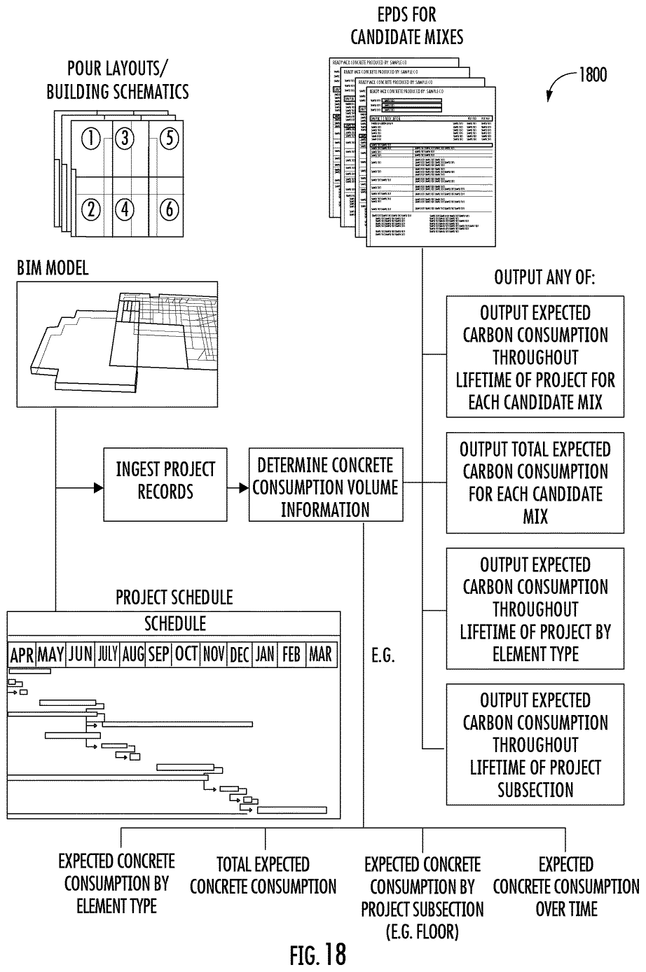

For example, and as shown in FIG. 18, carbon optioneering may be performed by the system 100. In some embodiments, carbon optioneering may include an in-depth analysis of the potential considerations and options for embodied carbon considerations. In this regard, the system 100 may ingest the appropriate plurality of records (e.g., pour layouts, building schematics, BIM models, project schedules, and the like) to determine which concrete mixes are most appropriate for a given project, element, subsection, or the like. In some embodiments, the concrete consumption volume information may be determined, which may include an expected concrete consumption by element type, a total expected concrete consumption, an expected concrete consumption by project subsection (e.g., the floor), or an expected concrete consumption over a given time period. Further, the system 100 may also ingest other records, such as the EPDs for candidate mixes. Further, in some embodiments, the output may include the expected carbon consumption throughout the lifetime of the project for each candidate mix; the total expected carbon consumption for each candidate mix; the expected carbon consumption throughout the lifetime of the project by element type; the expected carbon consumption throughout the lifetime of the project by subsection.

Carbon intensity of concrete raw materials may change based on the individual raw material (even for same or similar raw material types). For example for cement, this may vary depending on the plant the cement originates from (e.g. due to fuel consumption of plant, cement clinker manufacturing process). In some embodiments, embodied carbon data may be computed on the basis of these variations in raw materials.

In some embodiments the system may aggregate data from the underlying supply chain for the raw materials. This may include for example information associated with the kiln (e.g. kiln temperature, fuel type etc), as well as information associated with the transport of raw materials.

In one embodiment, AI models (such as LLMs, GPTs and the likes) may be used to extract embodied carbon data from records. In others, computer vision models, OCR models and the likes may also be used to transform records into structured data. AI models and/or deterministic models may also be used to estimate embodied carbon of raw materials and of concrete based on batching location, or other known properties about the material. Mix fingerprinting data may be used to characterize materials and determine their origin, to link them back to one or more EPDs.

In one embodiment, linkages between data (EPDs, delivery tickets, BIM elements, schedule items, and the like) may be inferred by statistical methods and AI models (such as LLMs, GPTs, and the like) as well as combinations thereof.

In some embodiments, cost data may be determined and/or displayed, tracking the cost of concrete deliveries and associated metrics, including breakdowns by mix type, and any other categorisation described herein.

### Data Extraction, Ingestion, and Operations

Data inputs into the system 100 comprise the data sources described above, in a standardised, semi-standardised or non-standardised (e.g. unstructured) format. In some embodiments, data ingestion and/or standardisation is either fully or partially automated.

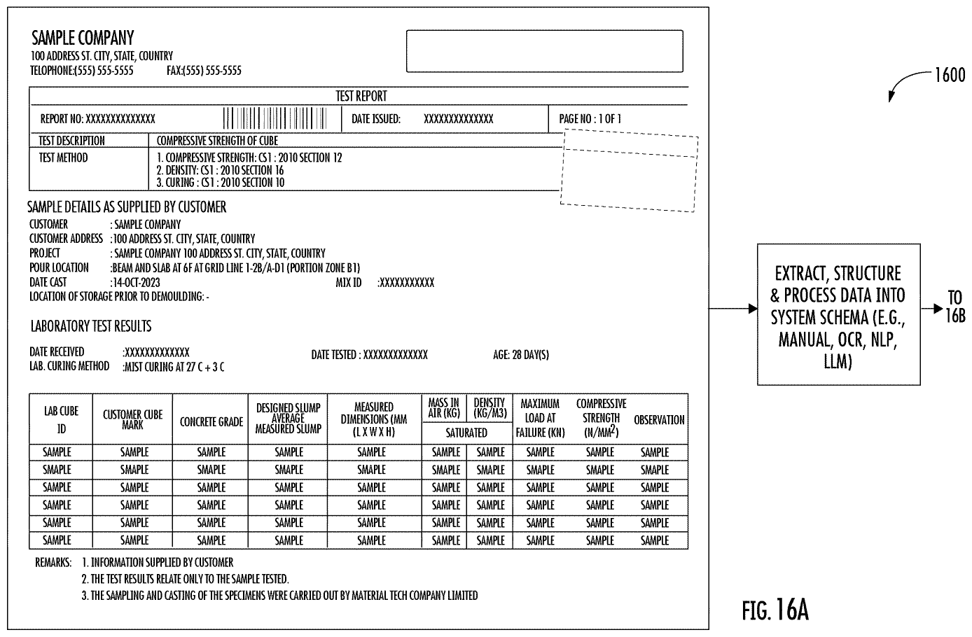

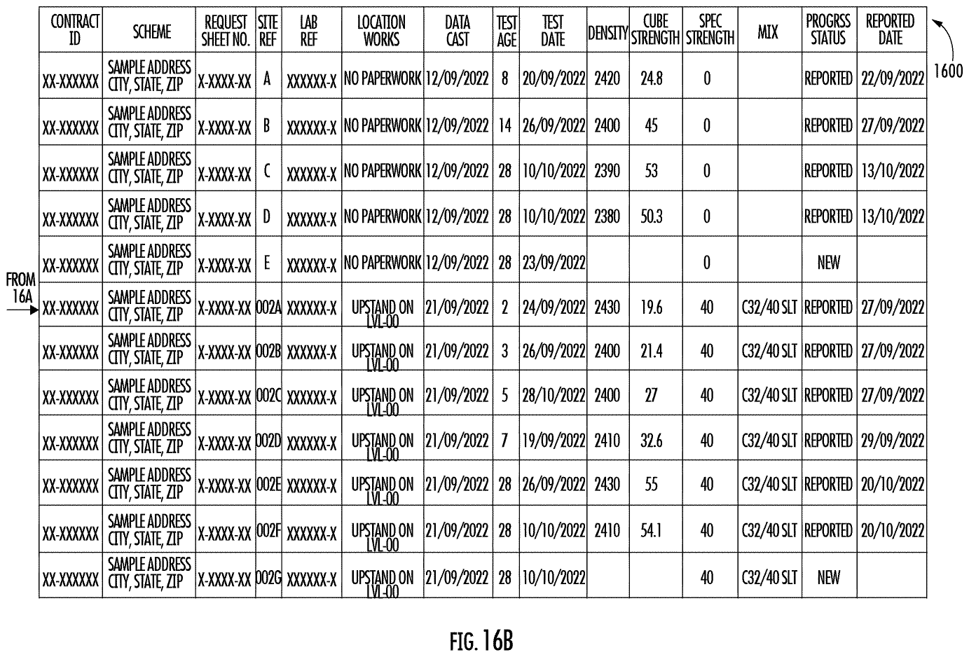

For example, FIGS. 16A and 16B illustrate an example embodiment of a high-level overview of the data extraction and structing process. In some embodiments, the system 100 may ingest a record, or the plurality of records. In some embodiments, the record(s) may include crush test results, as shown in FIG. 16A. In some embodiments, the system 100 may determine the appropriate information to extract from the record(s) by way of user input 312 (e.g., manually), the AI model 208 (e.g., using NLP), the ML model 210 (e.g., using a LLM), or the like. Further, as shown in FIG. 16B, the data may be extracted through the use of the user device 140, which may include the user device's 140 camera and processor using optical character recognition (OCR) to extract data from the record. Further, in some embodiments, the data may be structured and process into a system schema. In some embodiments, this may include structuring the data into a tabular format, as depicted in FIG. 16B.

In some embodiments, automated data ingestion does not require user or admin involvement. In some embodiments, data is accessed and ingested by the system herein through the use of an API (Application Programming Interface), typically programmed to access and retrieve data from a separate software platform comprising delivery records and concrete crush records and/or the data associated with those records, as well as other data of interest. In some embodiments, this data may be represented and stored in various formats including JSON, CSVs, Excels (e.g. xlm, xlsm, xlsb, xltx), and others.

In some embodiments, an AI agent may be configured to receive the first dataset (e.g., the first dataset 320) comprising the one or more first data entries associated with the building material data source. Further, in some embodiments, the AI agent may be configured to generate the building material data entity based upon the first dataset associated with the building material data source. In this regard, AI methods may be used to extract information automatically from records.

For example, the AI agent may gather information from multiple sources, such as the database 150, sensor data 314, machine data 316, the plurality of records, user input 312, and the like and integrate it into the system 100 or the server 130. The AI agent may, in this way, reduce the need for manual operations associated with gathering and ingesting the data for a particular construction project. The AI agent may, in performing these tasks, ensure the information is updated in real time (or in near real-time) across the construction project. Further, the AI agent may configured to handle administrative tasks such as scheduling tests for building materials, assigning resources such as building equipment and personnel, transmitting notifications, and the like.

Additionally, or alternatively, multiple AI agents may work together and interact to communicate to stakeholders and coordinate the construction project. The multiple AI agents may, in some embodiments, be specialized in different areas (e.g., data retrieval, monitoring compliance, scheduling, etc.). The communication between the AI agents may ensure that the relevant data are shared without delay. Further, the distribution system of AI agents may allow for efficient and effective coordination throughout various aspects of the construction project.

Further still, AI agent(s) handling the EPD creation may significantly reduce resources used in otherwise traditional methods of creating the EPD. The AI agent(s) may simplify the process by coordinating the data gathering across multiple teams assigned to handle EPD related tasks. For example, the AI agent may automate the communication process, send data requests to various stakeholders (e.g., manufacturers, transport companies, installation companies, etc.). Further, the AI agent may parse through communications, unstructured documentation (e.g., emails, reports, documents), and user input to extract key data used in EPD creation.

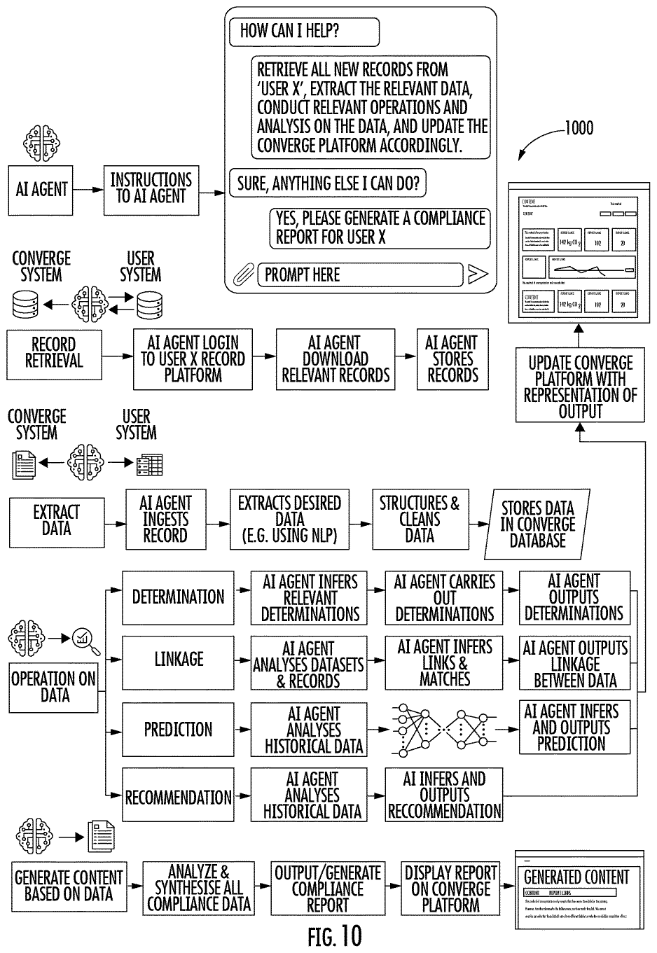

For example, FIG. 10 illustrates several embodiments of an AI agent configured to receive an input. In some embodiments, the AI agent may receive instructions from a user as the form of user input 312. In some embodiments, the user input 312 may be transmitted to the AI agent via a user device 140, which may use the user device's 140 communication device to communicate with the network 110 (as shown in FIG. 1). In some embodiments, the AI agent may receive, ingest, analyze, contextualize, or the like, the user input 312. In some embodiments, the AI agent may respond back to the user to gather more information, request the user send over more tasks for the AI agent to complete, respond with information, or the like.

In some embodiments, the AI agent may login to a user's record platform, which may include a database (e.g., the database 150), or the like. In this way, the AI agent may be authorized, via the user's authentication credentials, to access the database. In some embodiments, the AI agent may download the relevant records that may be used for record retrieval. Further, in some embodiments, the AI agent may store the records, which may include storing the records in a memory associated with the AI agent, the database 150, or any other storage device/memory of the system 100.

In some embodiments, the AI agent may be configured to extract data from the records it ingests. In this way, the AI agent may use an NLP engine to contextualize the ingested record and determine which data should be extracted. This may include using Large Language Models (LLMs), GPTs, transformers and/or other AI Model types that understand text, to parse documents such as delivery tickets and concrete records to extract the desired target data (e.g. mix ID). In some embodiments these AI Models may be trained on a dataset comprising construction documentation e.g. delivery tickets. In some embodiments these AI Models may be multi-modal, such that they also are able to ingest and interpret images, text, 3D models, graphs (e.g. compressive strength graphs of cube crush results). This may also include OCR models and computer vision models if the data is in an unstructured format (e.g. image of a delivery ticket) and may also include the combination of both types of records. Further, in some embodiments, the AI agent may structure and clean the data. Further, the AI agent may store the data in a database (e.g., the database 150, or the like).

Further, the AI agent may perform operations on the data (e.g., the building material data entity) extracted from the plurality of records. In some embodiments, a data operation may include a functional computation. In some embodiments, the functional computation may include data preparation, including transforming the building material data entity from a first format to a second format. In this way, the transformation of formats may include transforming the structure, file type, configuration, or the like associated with the building material data entity. For example, the first format of a building material data entity may be an unstructured format wherein the building material data entity is extracted from a written document. The transformation into a second format may include structuring the building material data entity into a format that may be used for further processing.

In some embodiments, the functional computation may include a data association, including generating linkages associated with the building material data entity. In some embodiments, the functional computation may include a data analysis, including performing a statistical analysis on the building material data entity. Further, in some embodiments, performing a data operation of the first dataset may include generating the building material data entity.

In this way, the operations may include a determination, a linkage, a prediction, or a recommendation based on the data. For example, with reference to the determination as shown in FIG. 10, the AI agent may infer relevant determinations, carry out those determinations, and output the determinations. Further, the AI agent may generate linkages between the data, which may include the AI agent analyzing the datasets and the records, inferring links and matches between the records, and outputting those linkages. Further still, the AI agent may make predictions by analyzing historical data (which may include using the ML model 210, a neural network, or the like) and outputting the inferences and/or predictions. Further still, the AI agent may analyze the historical data to output recommendations. In some embodiments, the outputs produced by the AI agent may include updating the system 100 and/or the database 150 with the representation of the output. In this way, the representation may be transmitted to a user device 140.

In some embodiments, the AI agent may generate content based on the data (e.g., the building material data source). For example, the AI agent may analyze and synthesize all of the relevant compliance data and create a compliance report based on that data. Further, in some embodiments, the AI agent may cause an output of the representation which includes the compliance report, for example.

In other embodiments, other software implemented text parsing algorithms or methods may be used to extract desired information from documents in any format listed herein, including pdfs, for example. In another embodiment, a method or algorithm replicating and automating user behaviour may be used to extract data from a digital location and ingest it into the system/platform described in the disclosure herein. In one embodiment, this digital location may be another separate software platform. In a further embodiment, the user behaviour automatically replicated by the algorithm may comprise one or any of the following steps, in any combination and/or order: login (the algorithm may be designed to login and access the software platform wherein the sought data is currently stored), download (the algorithm may be designed to download the sought data from the software platform), store (the algorithm may be designed to store the data in a given file format such as a JSON, XML, CSV, or other format as clear to one skilled in the art), structure (the algorithm may be designed to structure the data according to a predetermined schema), upload (the algorithm may be designed to upload the data onto the software platform), other (the algorithm may be designed to perform any other steps which may be required as part of a data acquisition process, as would be clear to one skilled in the art).

Further, partially automated data ingestion requires some level of user or admin involvement. In some embodiments, data is shared in a given file format (e.g. CSV, excel) through some data sharing mechanism (e.g. email). This is ingested either automatically through algorithms that parse the shared information, extracting the data file of interest, and feeding this into the system. The data sharing may be automated according to predetermined sharing rules (e.g. share this data daily at midnight, or share this data once this file becomes available and any other rule as would be evident to one skilled in the art), or may be done manually by an end user.

In some embodiments, the data file is automatically ingested by the platform. In some embodiments, the data file format is determined to be unsupported by the system, in which case the format is converted into another, supported format. This may be done automatically or manually or semi-manually. In some embodiments, the data schema is determined to be unsupported by the system, in which case the schema is converted into another, supported schema. In some embodiments, this determination and conversion procedure is automated. This may be automated using software implemented methods, wherein in some embodiments these methods comprise AI-based methods. In other embodiments, this may be manually or semi-manually converted to a supported data schema. In some embodiments, one or any of following steps, in any combinations may be done manually by an end user as part of the method herein: Login; Download; Store; Structure; Data Sharing; Upload; Other. For any data type, file type, schema type and/or other information associated with the data format and/or structure herein, in some embodiments, a mapping may be created between the data format/structure and the format compliant with the method disclosed herein.

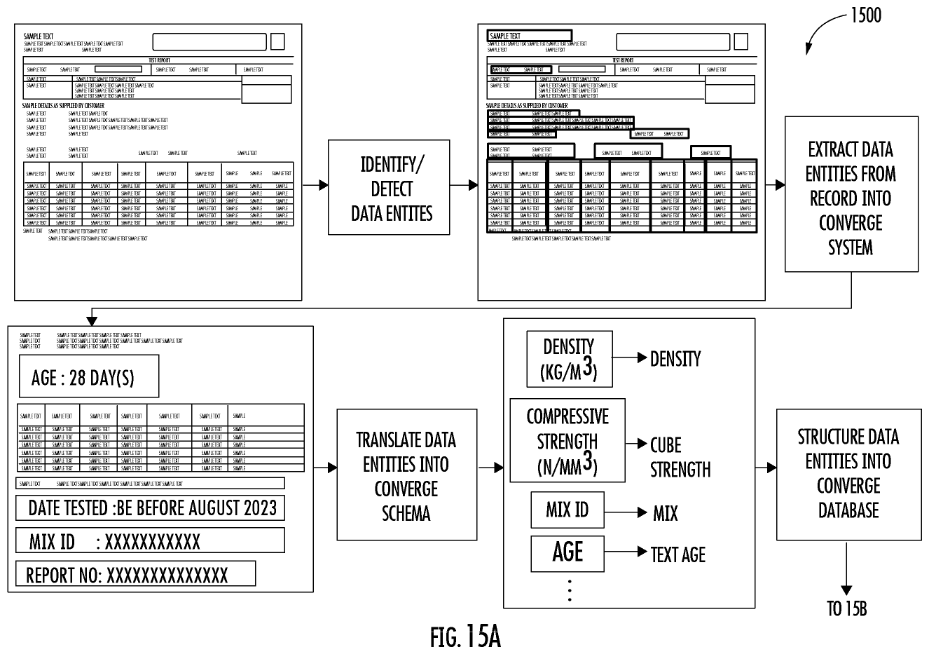

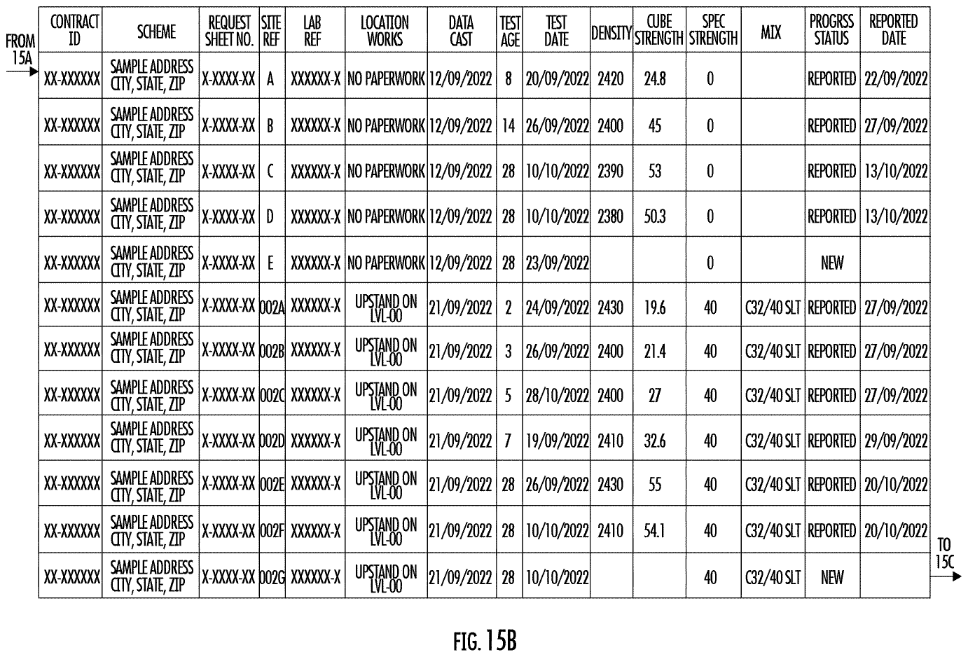

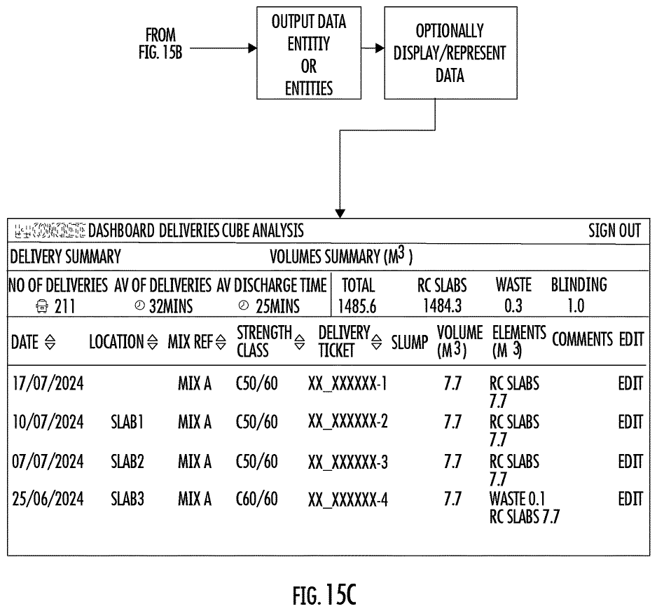

For example, FIGS. 15A, 15B, and 15C represents an example embodiment of extracting data from a record (e.g., a digital record, one of the plurality of records, a building material data source 120, or the like). In some embodiments, and as shown in FIG. 15A, the record may be used to identify and/or detect data entities (e.g., the building material data entity 330 as shown in FIG. 3). In this regard, the extracted data entities may be transferred to the database 150 by way of the network 110. In some embodiments, the building material data entity 330 may be translated into a schema of the system, which may include tagging, processing, structuring, or the like of the building material data entity. Further, the schema may allow other components (e.g., the server 130, the user device 140, the database 150) to use the data for further operations. In some embodiments, the data may be structured, which may include updating the data stored in the database 150, as shown in FIG. 15B. Further, as shown in FIG. 15C, in some embodiments, the system 100 may output the data entity, and may optionally represent the data. The representation may be transferred to a user device 140 for a user to interact with and/or view in an understandable way.

In some embodiments, users may be able to add allowable data formats into the platform. In further embodiments, this step may comprise users creating a mapping between data, for example by associating a given data schema to a list of predetermined fields provided by the system.

In some embodiments, the method comprises the ability for a user to set up the automated steps through which the system may access data (e.g. replicating user behaviour). This may comprise the user uploading a file in a given format (e.g. excel) which may in some embodiments comprise data associated with predefined mixes, which gets parsed. Users may also set up/select which systems they would like the present disclosure to integrate into, for example this may comprise platforms associated with concrete delivery suppliers and compliance test labs. For each the user may fill in the necessary information for integration e.g. usernames, email addresses, passwords, following which the system may be able to seek and ingest data automatically. In some embodiments, the method may comprise the system requesting permission to access data from another system, and/or requesting information from other platform/systems, for example supplier systems, or users, for example a particular supplier user. For example, this may comprise the system requesting or inviting that a supplier fill out and submit a digital form comprising required or desired information (e.g. mix data, raw materials data, supplier carbon assessment and/or other data). In other embodiments, the system may connect to supplier APIs or global EPD databases.

In some embodiments, the system may comprise data adherence determination and data cleaning methods. In some embodiments, the ingested data does not adhere to the supported format/schema/structure. In some embodiments, the methods herein may determine these formats are unsupported and label them as such internally, providing user readable labels for e.g. “incorrect”/“bad”/“needs attention”/any labelling which makes it clear the data is in an incorrect format, as opposed to “clean” data which may refer to data in a correct format. In some embodiments, the system comprises methods and mechanisms for automatically detecting, labelling and separating such data from supported data (e.g. store them in a different location). In further embodiments, the data may be manually reviewed and edited, following which the system may request approval from the user that the data is now correct.

For example, sometimes concrete mix design references may be incorrectly inputted/written/typed in. In one embodiment, the system may detect that it is ingesting the first instance of a potentially new concrete mix design. The affected data (whether it's a number of deliveries, or a number of crush tests) are isolated from the clean data. The method may then comprise a system user taking action in order to either for example confirm the presence of a new concrete mix design, or assign this as a variation on the name of an existing concrete mix design. Once the user performs the corrective action, the “bad” data may be added to the clean ones.

Corrective action may be assisted by machine learning models (e.g. fuzzy matching), and may employ any of the linkage and fingerprinting methods described elsewhere herein. In some embodiments, the user could choose whether such corrective actions can be performed automatically by the system based on a number of techniques including but not limited to string similarity metrics such as Levenshtein distance with some user-defined thresholds. The automatic corrective action may also only occur if only one possible match was found. For example, for the concrete mix design references ‘Mix C40/50 RC Slabs’ (correct one) and ‘Mix C40/50 RT Slabs’ (incorrect one), the Levenshtein distance is 1. The presence of one and only one possible concrete mix design reference would allow an automatic corrective action. If, however, there were multiple possible matches (e.g. ‘Mix C40/50 RC Slabs’, ‘Mix C40/50 PT Slabs’), then an incorrect concrete mix design reference such as ‘Mix C40/50 RT Slabs’ may not be automatically corrected without user input. This similarity metric could also be used to automatically correct delivery ticket numbers on crush results and/or other attributes. Additionally or alternatively, AI methods may be used to implement most likely corrections to incorrect references, with associated probabilities/likelihoods for matching. This may be done using any method herein as well as in the linkage portion of this document.

In some embodiments, the method as described herein may include methods for data display. Graphs may be produced and displayed onto the platform using methods for GUI graphical display. The same may apply for tabular data. Displayed data must be in a format understandable by the user. In some embodiments, the method may comprise one or multiple step(s) wherein the ingested data passes through a translation layer that converts the input data into a domain that is understandable and/or expected by the user. In some embodiments, this may be a platform-wide domain which defines that displayed names for each attribute. In other embodiments, this may be predefined formats set for each user or user group, these user groups may be defined according to any grouping, including but not limited to geography, organisation membership, or project site association. In some embodiments, the data may be localised and internationalised by the geography of the site. In further embodiments, this may be overwritten by users manually. In some embodiments, data which does not adhere to a supported format/domain is not displayed, and a discrepancy may be flagged. In other embodiments, the method comprises parsing non-adherent data files and modifying them such that they adhere to a supported format and displaying them. In some embodiments, this may be done using data parsing methods, or AI based methods.

The system comprises methods for data association. Generally, any data listed herein may be associated with any other data type herein. This may generally be done by matching identifiers, dates, locations, and/or any other data type.

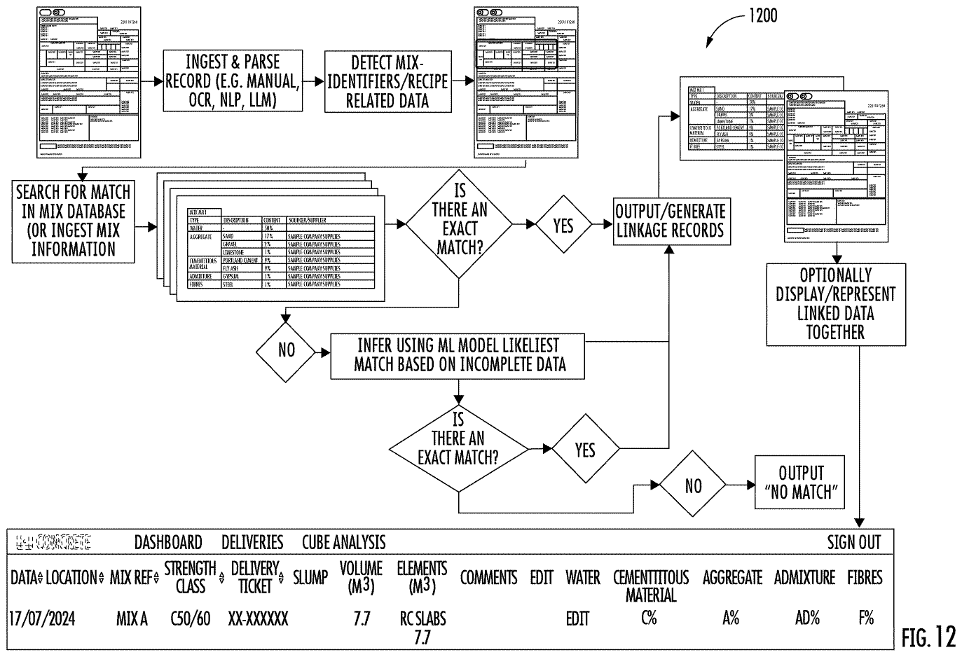

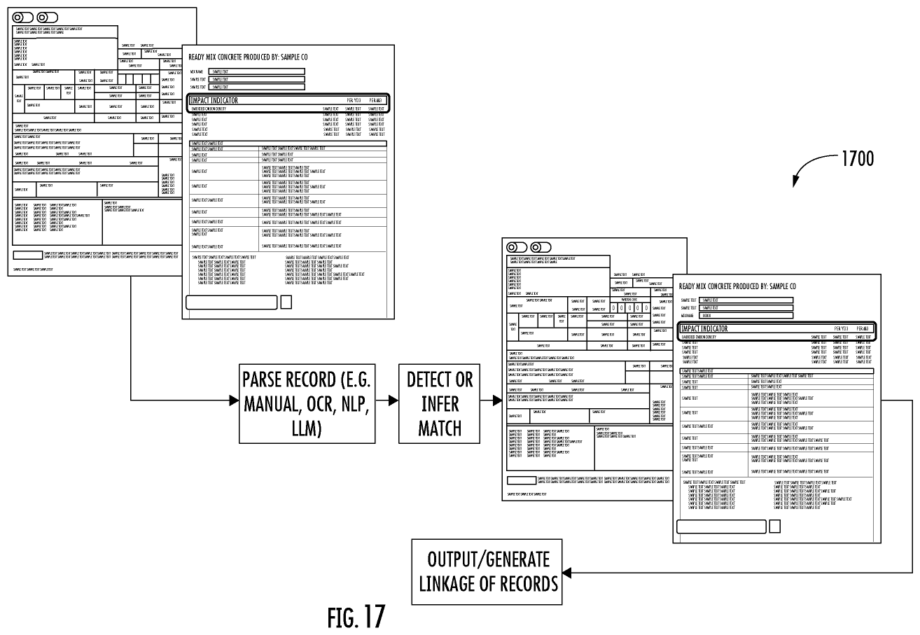

For example, FIG. 12 illustrates an example embodiment of data linkage. In some embodiments, the system 100 may ingest and parse a record (e.g., one of the plurality of data records) and detect relevant data. In some embodiments, the relevant data may include mix identifiers, mix recipes, related data, and the like. In some embodiments, the mix database (e.g., database 150) may be searched to find matching data or mix information may be ingested. In some embodiments, if an exact match is determined, linkage records may be generated and outputted as a representation. For example, and as shown in FIG. 17, the exact and/or direct match may be detected after parsing the record. The record may be parsed by user input 312, using NLP associated with the AI engine 208, using the LLM of the ML model 210, using OCR associated with the user device 140, or the like. Once the exact match is detected or inferred, the linkage of the records may be generated and/or outputted.

In some embodiments, if an exact match is not found, the ML model (e.g., ML model 210) may infer the most likely match based on the incomplete data. In some embodiments, if a likely match is determined to be found, then the linkage records may be generated and outputted. If a likely match is not found, a “no match” may be outputted.

In some embodiments, samples created from deliveries may be “tagged” with the ID of the delivery they were made from, which the system uses for direct association. In other embodiments, this tagging may not exist. In its absence, the system may be configured to find likely matches/associations using heuristics-based methods. For example, if the building material result does not have the delivery identifier, but the mix design data and date data are available, the system may be able to select deliveries that occurred on that date for that mix design and the system may be able to select the associated delivery for “cleaning data” purposes. Similarly, if a delivery ticket number is present but it cannot be matched directly, the system may show likely matches for that ticket. This may occur due to errors in the delivery ticket inputted for example.

In some embodiments, if certain key information is missing from the input data (e.g. missing mix design), clustering methods (for example based on performance indicators such as strength, physical attributes such as density, and others) may be used to determine the most likely concrete mix designs and/or most likely deliveries to associate this data/cubes to. Further, any of the methods described in the linkage section may be used for this data association.

The system may generally aggregate information into insights through summing over data points, or performing any other function that takes as input a group of datapoints. This may include any commonly used statistical functions such as mean, median, mode, variance, standard deviation, cumulative sum, probabilities, integrals/sums over probability distributions and others as would be clear to one skilled in the art.

The system may aggregate data based on the following groupings (non-exhaustive): date range selected; concrete mix design; element type; as well as concrete specification. For cube results data, they may also be aggregated by cube age (in some embodiments with certain allowances/tolerances for ±1 days for example). Another grouping embodiment may comprise grouping cubes based on their performance data and extracting insights based on that (e.g., determining whether the cubes were all crushed around the same time; determining a correlation between performance and season such that this may be a seasonal effect, etc.).

In one embodiment, a machine learning model is used to extract concrete volumes and carbon intensity data from delivery tickets and EPDs. This model is executed on all delivery tickets received per site. The output values are summed to determine an aggregate volume of concrete used on the site, and a total carbon run rate.

The following include examples of methods which may be used by the system to compute certain data aggregations. The total number of concrete deliveries to the site (e.g., the project site 310), wherein the method counts over every individual delivery ticket with a unique ID. The total volume of concrete to the site, wherein the method iterates over every delivery, cumulatively summing over each one. The breakdown of number of deliveries & volumes delivered by concrete mix. For example, for every delivery, the method comprises assigning a grouping by concrete mix, wherein the method counts over every delivery in every group, outputting a total number of deliveries for every mix type. It then outputs the counted output alongside the ID for the mix. In some embodiments, the ID displayed may go through a translation layer to turn it into a user understandable ID.

The total volume of concrete by element type, wherein the user may assign element types to individual deliveries (or groups of deliveries). These element types may comprise any element type described herein (e.g. column, slab etc. . . . ). Element Type may also comprise “Waste”. The system then sums concrete volume from deliveries over each element type group, and outputs the concrete volume alongside the corresponding element type. Additionally, or alternatively, element types may be a designated field in ingested documentation, which may be extracted using text parsing techniques and/or AI methods. Additionally, or alternatively, total volume of concrete by mix type, each broken down into element type. This uses the same methods as the individual summing over element type and mix type but adds an additional level of nesting over which things must be summed.

The total volume of concrete wasted (e.g., Sum over the volume from every delivery labelled as “Waste”. This may be indicative of deliveries that have been rejected or returned for non-compliance for example, or of concrete that was not used for other reasons). The total number of crush compliance reports (e.g., the method counts over every individual crush report ingested within the selected date range). The total number of crush reports by mix (e.g., Group crush reports by mix identifier. This may be done by automatically matching mix identifiers on crush reports data, e.g. through text parsing or AI methods. Alternatively or additionally, users may assign a mix ID for any given crush report. Method counts over every crush report mix ID group within date range, output result alongside every mix identifier). The total number of crush reports by crush age (e.g., 7 days, 28 days, 56 days, etc.) wherein the crush reports are grouped by crush age, which may be done by automatically matching crush age on crush reports data, e.g. through text parsing or AI methods. Alternatively or additionally, users may assign a crush age for any given crush report. Alternatively or additionally, if mix ID is known, clustering methods may be used to determine likely age of cube based on cube crush strength result. Method counts over every crush report age group within date range, output result alongside every mix identifier.

The total number of crush reports by rule status, wherein a rule may be assigned to any crush report result. For example, a rule assignment determination may be used, wherein the rule may be assigned automatically by the system based on some known assignment criteria. Alternatively or additionally, the rule may be assigned manually by a user. Alternatively or additionally, the rule may be automatically internally assigned to a crush report result but may require user approval before being assigned in the system. Assignment criteria for rule assignment may include the following: rule type (e.g., individual rules, pair rules, and/or aggregate rules may have different assignment criteria due to their difference in rule type), individual rule assignment criteria (e.g., Assignment of an individual rule may be dependent on specified mix design strength for the compliance sample tested. A different rule may be applied for a C40/50, than for a C32/40, or other variables may in some embodiments include: mix type, season, ambient temperature during crushing (e.g. rules below 2° C. may differ from above 2° C.), etc.), pair rule assignment criteria (e.g., specified mix design strength), or aggregate rule assignment criteria (e.g., specified mix design strength, and/or the size of bins considered for the moving average. For example, the rule assigned may be different when considering the last 2 pairs of crush results in the moving average calculation as opposed to when considering the last 6 pairs of crush results in the moving average calculation).

Further, rule assignment extraction may be used by the system 100 which may include rule assignment criteria created alongside rules by users. Additionally, or alternatively, these may be extracted from compliance documents, and converted into rules automatically through parsing methods and/or AI methods (e.g. LLM, GPT, multi-modal transformer methods and others). The system may comprise methods for determining the most likely rule to assign to a crush result if information is missing (e.g. mix ID or specified design strength is missing), based on analysing any other data associated with the crush e.g. may infer mix type by associating with delivery, or based on age and strength result, when compared to the known mix list being used for the given site.

Further, based on the comparison between the crush result(s) (individual, pair, or aggregate) and the rule assigned to this result or pair or aggregation of results, the system may determine the status of the result(s) with respect to the rule e.g. PASS, FAIL, WARNING etc. . . . . Such statuses may be assigned to any and every crush result or crush result pair or aggregation. In this regard, the rules may be grouped by rule type i.e. individual, pair, aggregate. Within each rule type, the system may count over rule statuses pertaining to rules applied in each type. The system may then output, for each rule type, the total number of each rule status/number of times each rule resulted in a given status. This may be equivalent to the crush reports that produced each (e.g. the number of individual rules that passed, or that failed etc. . . . , equivalently or alternatively, e.g. the number of reports results that produced a pass when applied with an individual rule, or the number of pair reports that produced a fail when applied to a pair rule etc.) Alternatively or additionally, the system may count the number of distinct rules applied over the whole set of crush results (e.g. how many different individual rules have been applied).

Further, the average delivery time may be determined. In this regard, the system 100 may, for every delivery data, extract the delivery time, sums over all of these times/durations, and divides them by the numbers of samples of delivery data (i.e. mean function).

Further, the average discharge time may be determined. In this way, similar to the calculations above, but mean function is used over every discharge time data field. Further still, the total embodied carbon may be determined. The embodied carbon density data (i.e. eCO2 by cubic metres, or kg of concrete) automatically extracted from EPDs (e.g. through parsing methods or AI methods), or provided by users. In some cases, concrete density data is also ingested. Total volume of concrete is determined by summing over the volume in all deliveries. This is multiplied by eCO2 density data to get the total eCO2 emitted. In some cases, the density of concrete is used to convert between total volume and total mass (kg) if necessary.

In addition, the total embodied carbon may be broken down by any field. For example, deliveries are grouped by relevant field in any of the ways listed elsewhere herein. Total embodied carbon is determined as above but for every grouping individually. The output of the calculation is outputted alongside the relevant grouping.

Additionally or alternatively, for any of the examples herein, the user may select a data range over which this aggregated data is considered, in which case the methods herein (e.g. counting, summing, averaging) may aggregate over data within this date range. Dates may be indicative of the date a delivery arrived to site, or the date a crush test occurred for example, as well as any other association of records with dates.

### EXAMPLE EMBODIMENTS

Other features of the system/method/platform described herein may include the following. In some embodiments, users may be able to upload data onto the platform as a method of data ingestion. In some embodiments, users may need to select the type of data they wish to upload before uploading, such that the system considers it in the correct format. In other embodiments, this is automatically detected, for example through AI methods. In some embodiments, users may be able to export data from the platform, in whole or in part. For example, users may be able to export all delivery data within a predetermined time frame or date range. In some embodiments, any of the data displayed in tabular format herein is sortable by any given field. In some embodiments, users may filter the data herein by any field or category (e.g. filter mixes by end element location). In some embodiments, notifications may be flagged and sent to users to make them aware of some data. For example, notifications may be sent to users to notify them that a certain aggregate cube rule has been failed. In some embodiment, any row or column in any tabular formatted data may be selected and edited (e.g. to add location).

In some embodiments, the present disclosure may include the following information. The internal data (e.g., for ingestion) may include Site information; Pour information; Sensor information; MixAI insights; or the like. The external data (e.g., for ingestion) may include Site/project information; Pour layout; BIM related information; Cost information; Mix specifications; Mix designs (contractor/supplier); Slump data; User comments; Cube crush results from labs; Delivery ticket information from concrete suppliers; Delivery location (element name and/or map location); CO2 information from contractors/EPD; Regulatory rules; Workability data (external API and/or manually entered). The data types may include Handwritten documents; Digital tables; or the like. The data association may be based on labels (delivery tickets, mix design name/ID, element type); Based on algorithmic insights from the data itself; Clustering recipes; Using date/time values to co-locate results; or the like. The data insights may Generate summaries of mix design performance on a specific site (based on mix name/ID). For example, the data insights may include Volume poured; CO2 consumption (cumulative); Total Cost (cumulative); Delivery efficiency-based insights (average delivery time, discharge time); Volume by Element; Number of deliveries; Compliance information (derived from cube crush results and regulatory/customer rules); Time-based tracking of waste; Time-based tracking of trends in performance (strength); Data exporting into user-defined formats; Insights about the degree to which a project is completed.

Further, in some embodiments, the present disclosure may include the following information. In some embodiments, a data prediction tool for managing materials on site for developers, specification engineers, contractors and ready mixers. This may comprise the following features (non-exhaustive), as well as other similar features as may be clear to one skilled in the art: Real-time ingestion of data from suppliers, contractors and labs; Real time predictions of compliance risk and predictions of site health from materials; AI based prediction on performance and logistics; adaptable UI/UX based on real-time questions asked by the user (e.g., “what happened yesterday” generates a view of all pertinent insights relating to yesterday); Automated inferences of impact to project from predicted deviations from program; Dynamic GEN AI specification writing for Concrete for engineering consultancies; Data record keeping & prediction tool for suppliers, which may comprise all compliance data and/or batching/kiln information, etc.; full Programme management integration to all of the project management tools; a qualification algorithm of a contractors performance based on their materials consumption and control; Consumption of every material on site and in the build progress assess for carbon and productivity and compliance; a regulator independent AI regulation to assess viability and compliance for all material in real time on every site in the world and drives and NCR's suppliers and contractors for the global concrete industry.

The methods, systems, techniques, and platform described herein may apply to any building material and element type going beyond readymix concrete. This may be used for prefabricated elements for example, including facade elements, precast blocks and others. This may also be used for materials (e.g., building materials 301) such as rebar; steel; glass; plastics; precast elements; MEP (mechanical assembly, electrical assembly, and plumbing assembly); facades. For example, ingested data associated with rebar may include Bend test; Visual inspection; Chemical composition analysis; Tensile strength test; Ultrasonic testing; QA of how it's been installed (e.g. Records on steel fixing itself, Visual inspection, Inspection sheets to see if it was fixed & material tests that might be done before rebar arrives to site).

Other features may include Ingesting documents and EPDs for any building material that arrive on site. For any material that is ordered, the platform may ingest and display data associated with delivery tickets & Purchase Orders. These may be used to calculate and track embodied carbon for every raw materials. Carbon associated with construction operations may also be tracked (e.g. transport carbon). In some embodiments, for every or any ordered material, carbon data is gathered and ingested by the system associated with, or from EPDs and other documentation or user/supplier input data. In addition, data associated with the carbon emitted in the transportation of the raw material to a batching plant or to site may also be gathered and ingested. This carbon data may be displayed on the platform. Aggregated carbon data which combines raw material embodied carbon with emitted delivery carbon and/or other carbon emitted through construction operations may also be displayed. In some embodiments, energy and/or carbon data associated with the batching of raw materials (e.g. of concrete) may also be gathered, and carbon data associated with the delivery/transport of the batched material to site may also be considered, and aggregated with any other carbon data herein. Data associated with the energy/carbon consumed/emitted during the material/concrete pumping process may also be gathered, ingested and displayed, as well as aggregated and displayed in an aggregated format with any other carbon data herein.

In some embodiments, carbon data may be displayed as groups, for example, delivery carbon may be displayed separately to embodied carbon; embodied carbon data may be grouped by material; carbon data may be grouped by batching plant.

In some embodiments, total carbon data may be grouped into embodied carbon data which may be subgrouped by material (e.g. steel, concrete etc. . . . ), and construction operation carbon which may be subgrouped by for example process location (e.g. batching plant, raw materials plant, construction site, prefabrication factory and others), or process type (e.g. crane lifts, forklift use, concrete mixing, concrete curing using heat ovens and others). These groupings may be subdivided into any sublevels. This may include for example subdividing concrete carbon into embodied carbon by mix type. These sublevels of groupings may exist at any level of granularity and at any nesting numbers. In some embodiments, concrete embodied carbon data is displayed by the lifecycle analysis stage. In some embodiments, the metric displayed may be carbon intensity rather than total carbon.

In some embodiments, carbon data may be categorised by stakeholder. For example, carbon data may be aggregated and grouped by supplier type, for comparison. The accounting methods and techniques as described herein with respect to carbon may without loss of generality be used for any other type of metric desired to be accounted for, in whole or in part. This may include cost (e.g. cost by mix, by delivery, by location, by material, by process etc. . . . ), progress and others. In some embodiments, the carbon tracking described herein may not be associated with building materials, but broader building/construction processes.

In some embodiments data sources may comprise user invoices or purchase orders, shipping deliveries data and more. (e.g. to accurately assess and account for ordered/purchased materials and materials quantities). In some embodiments, the system may be integrated into accounting and/or ERP software and/or any other user platform, interface, or system, and may request access to that platform. Note, it would be clear to one skilled in the art that any of the methods, techniques, platform systems, GUIs, visualisation, data formats, rules and others may be applicable to any other construction/building data and/or records associated with a construction project or building material.

In additional embodiments, the building material data entity may be determined based on a plurality of records and/or sensor devices. Additionally, or alternatively, in some embodiments, the plurality of records may include at least two of a concrete crush test result record, a concrete delivery ticket record and/or an environmental product declaration, and optionally one or more sensor measurements indicative of the properties of the concrete in its fresh or hardened state.

Additionally, or alternatively, in some embodiments, the sensor measurements may be indicative of the curing, strength, temperature, water to cement ratio, shrinkage, maturity, composition, workability of the concrete, at one or more times t, and/or one or more locations within a concrete pour. Additionally, or alternatively, in some embodiments, the sensor measurement may be indicative of one or more measures of, or the time evolution of, or the spatial distribution of the electrochemical, electromechanical or electromagnetic wave impedance at one or more of a plurality of frequencies, or impedance spectrum. Additionally, or alternatively, in some embodiments, the building material data is determined based on the nth order derivative or integral of the frequency dependent impedance spectrum of the concrete, at one or more times during the curing of the material. Additionally, or alternatively, in some embodiments, the building material data is determined based on a characteristic of the resonance peaks of the impedance spectrum. Additionally, or alternatively, in some embodiments, the determination involving the resonance peaks makes use of a machine learning model to which relates the resonance peaks to a material property.

Additionally, or alternatively, in some embodiments, a first compressive strength measurement of a material sample is extracted from the concrete crush test result record, and linked to the concrete delivery record from which the concrete used for the concrete crush test result record originates. Additionally, or alternatively, in some embodiments, the method may further include determining or receiving the location on a jobsite where the concrete originating from the associated delivery was poured and linking such location to the compressive strength results from the crush tests and the applicable concrete delivery ticket record. Additionally, or alternatively, in some embodiments, the method may further include identifying a compliance pass, warning, or fail at the predetermined location. Additionally, or alternatively, in some embodiments, the first compressive strength measurement is extracted and/or its linkage to a concrete delivery record is determined using a machine learning model, optionally wherein such machine learning model is a large language model or a GPT-based model. Additionally, or alternatively, in some embodiments, the plurality of records include a plurality of crush test result records from n times t_n, and a plurality of concrete delivery records from k times t_k, wherein t_n and/or t_k are at or after the commencement of the project, and at or prior to its completion, the method further includes extraction of compressive strength results from the crush test result records, and linkage of those to the delivery records. Additionally, or alternatively, in some embodiments, wherein the construction project has not yet completed, the method may further include the determination of a pass, warning, or fail based on a crush rule, indicative of a quality issue with the concrete. Additionally, or alternatively, in some embodiments, the relative, absolute, or global location on a jobsite where concrete associated to the plurality of concrete crush test results records or the plurality of concrete delivery records is received or determined, optionally wherein the location of a compliance pass, warning, or fail is then further notified to a user based on one or more crush test rules.

Additionally, or alternatively, in some embodiments, a volume of material may be determined from the concrete delivery record, and a volumetric embodied carbon intensity is determined from the environmental product declaration, and the total embodied carbon of the concrete delivery is determined by multiplying the volume of material by the volumetric embodied carbon intensity.

Additionally, or alternatively, in some embodiments, the plurality of records includes a plurality of concrete delivery records for n times t_n, and a one or more environmental product declaration for one or more of the mixes referenced by the plurality of concrete delivery records. Additionally, or alternatively, in some embodiments, the method may further include extracting the volume of concrete delivered to the project from each concrete delivery record, alongside the associated mix identifier and the time of delivery. Additionally, or alternatively, in some embodiments, the method may further include extracting the carbon intensity and associated mix identifier from each environmental product declaration, and optionally (if required) converting the carbon intensity to a volumetric carbon intensity (for example, the embodied carbon per cubic meter or cubic yard). Additionally, or alternatively, in some embodiments, the method may further include, for each distinct mix identifier, determining the total volume of concrete poured between time t_i and t_p by summing the extracted volumes associated to that mix identifier with a delivery time within the time period, wherein t_i and t_p represent a time period during the project's construction. Additionally, or alternatively, in some embodiments, the method may further include, for each distinct mix identifier, determining the aggregate embodied carbon for each mix identifier during the time period by multiplying the total volume of concrete poured in the time period by the volumetric carbon intensity for that mix identifier. Additionally, or alternatively, in some embodiments, the method may further include outputting the aggregate embodied carbon for the time period for one or more mix identifiers. Additionally, or alternatively, in some embodiments, the extraction of the volume of concrete delivered to the project, the associated time of delivery and mix identifier from each concrete delivery record, and/or the extraction of the carbon intensity and associated mix identifier from the environmental product declaration is done using machine learning model or optical character recognition system, optionally wherein such machine learning model is an LLM or GPT. Additionally, or alternatively, in some embodiments, the first carbon intensities for one or more mix identifiers is determined used a first model which takes as an input first data indicative of the material composition or properties, optionally wherein such first model is a predictive or generative machine learning model trained on preexisting second carbon intensity data for a plurality of second mix identifiers. Additionally, or alternatively, in some embodiments, the method may further include the comparison, for each mix identifier, of the volume of concrete actually delivered between t_i and t_k, to the expected planned volume for the project, wherein the expected planned volume is determined by reference to a drawing, floorplan or BIM model for the project, the method further including outputting the difference in volume between the plan and the actual deliveries for the time period.

Additionally, or alternatively, in some embodiments, the method may further include the comparison, for each completed element, of the volume of concrete actually delivered and poured in the element, and the expected planned volume for such element, wherein the expected planned volume is determined by reference to a drawing, floorplan or BIM model for the project, the method further including outputting the difference in volume between the plan and the actual deliveries for the element.

Additionally, or alternatively, in some embodiments, the method may further include receiving reinforcement delivery records for reinforcement bars and the extracting from such reinforcement delivery records of first data indicative of the total quantity of reinforcement bars, wherein such first data may be a mass, length, density, volume and/or number of bars, in association with an indication of the type of reinforcement bar, or material composition of the reinforcement bar, or a reinforcement bar identifier and further data indicative of the time of delivery and/or installation of such reinforcement bar. Additionally, or alternatively, in some embodiments, the method may further include receiving environmental product declarations and extracting from such environmental product declarations second data indicative of the carbon intensity of one or more reinforcement bar types. Additionally, or alternatively, in some embodiments, the method may include determining the total quantity of reinforcement bars delivered or installed with reference to the first data. Additionally, or alternatively, in some embodiments, the method may include determining, for each reinforcement bar type, the total embodied carbon delivered between t_i and t_k by converting the carbon intensity and quantity to a common set of units (e.g., carbon intensity by mass, and mass of rebar) and multiplying one by the other. Additionally, or alternatively, in some embodiments, the method may further include outputting the total embodied carbon for one or more multiple reinforcement bar types for the time period.

Additionally, or alternatively, in some embodiments, the method may further include associating reinforcement bar carbon data to concrete mix carbon data based on the locations wherein concrete has been poured, and the locations wherein reinforcement bars have been installed, to determine the aggregated embodied carbon for a reinforced concrete element.

As will be appreciated by one of ordinary skill in the art, the present disclosure may be embodied as an apparatus (including, for example, a system, a machine, a device, a computer program product, and/or the like), as a method (including, for example, a business process, a computer-implemented process, and/or the like), as a computer program product (including firmware, resident software, micro-code, and the like), or as any combination of the foregoing. Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and systems described herein, it is understood that various other components may also be part of the disclosures herein. In addition, the method described above may include fewer steps in some cases, while in other cases may include additional steps. Modifications to the steps of the method described above, in some cases, may be performed in any order and in any combination.

Therefore, it is to be understood that the present disclosure is not to be limited to the specific embodiments disclosed and that modifications and other embodiments are intended to be included within the scope of the appended claims. Although specific terms are employed herein, they are used in a generic and descriptive sense only and not for purposes of limitation.

### INCORPORATION BY REFERENCE

To supplement the present disclosure, this application further incorporates entirely by reference the following commonly assigned patent applications:

| International Patent | | |
|---|---|---|
| Application Ser. No. | Title | Filed On |
| PCT/US24/11507 | SYSTEMS AND METHODS | Jan. 12, |
| | FOR BUILDING MATERIAL | 2024 |
| | BASED DETERMINATIONS | |
| PCT/US24/37681 | SYSTEMS AND METHODS | Jul. 11, |
| | FOR INDUSTRIAL | 2024 |
| | OPERATIONS | |
| PCT/GB2024/050087 | METHODS AND SYSTEMS | Jan. 12, |
| | FOR DESIGN, SELECTION | 2024 |
| | AND MODELLING OF | |
| | MATERIALS | |
| | METHODS AND SYSTEMS | Oct. 11, |
| | FOR DESIGN, SELECTION | 2024 |
| | AND MODELLING OF | |
| | MATERIALS | |

1. A computer-implemented method for building material data management, the method comprising:
receiving a first dataset comprising one or more first data entries associated with a building material data source;
generating a building material data entity based upon the first dataset associated with the building material data source; and
outputting a representation of the building material data entity.

2. The method of claim 1, wherein receiving the first dataset comprises ingesting a plurality of data records.

3. The method of claim 2, wherein the plurality of data records further comprises at least one of:
a construction document;
a user input;
sensor data; or
machine data.

4. The method of claim 3, wherein the construction document comprises at least one of:
a material data;
delivery data; or
a regulation data.

5. The method of claim 1, wherein the building material data entity is associated with material data extracted from the first dataset, the method further comprising:
comparing material data of the building material data entity with one or more crush rules;
in an instance in which the material data fails to satisfy the one or more crush rules, generating a failure alert;
in an instance in which the material data satisfies the one or more crush rules, generating a passage alert; and
in an instance in which the material data is within a warning threshold associated with the one or more crush rules, generating a warning alert.

6. The method of claim 1, wherein the building material data source comprises a sensor device configured to generate data associated with the building material data source.

7. The method of claim 6, wherein the first dataset comprises carbon data comprising an amount of carbon associated with a building material associated with the building material data source.

8. The method of claim 1 further comprising performing a data operation of the first dataset to generate the building material data entity.

9. The method of claim 2 further comprising:
receiving the first dataset comprising a construction document; and
receiving sensor data comprising sensor data from the building material data source.

10. The method of claim 9, further comprising:
comparing the first dataset and a second dataset,
the first dataset comprising the sensor data comprising the construction document, and
the second dataset comprising the sensor data from the building material data source; and
generating the building material data entity based at least in part on the comparison.

11. The method of claim 8, wherein the data operation further comprises a functional computation comprising at least one of:
data preparation comprising transforming the building material data entity from a first format to a second format;
data association comprising generating linkages associated with the building material data entity; or
data analysis comprising performing a statistical analysis on the building material data entity.

12. The method of claim 11, wherein the representation comprises the data association of the building material data entity.

13. The method of claim 11, wherein the data analysis further comprises deploying an artificial intelligence (AI) engine to perform the statistical analysis on the building material data entity.

14. The method of claim 13, wherein the representation comprises the statistical analysis on the building material data entity performed by the AI engine.

15. The method of claim 1, wherein the representation comprises the building material data entity.

16. The method of claim 1, wherein the representation comprises generating a notification based on the building material data entity.

17. The method of claim 1, wherein the representation comprises generating a visual presentation of the building material data entity.

18. The method of claim 1, further comprising an artificial intelligence (AI) agent configured to receive the first dataset comprising the one or more first data entries associated with the building material data source.

19. The method of claim 1, further comprising an AI agent configured to generate the building material data entity based upon the first dataset associated with the building material data source.

20. A system for building material data management, the system comprising:
a building material data source;
a processing device;
a non-transitory storage device containing instructions that, when executed by the processing device, causes the processing device to:
receive, via the processing device, a first dataset comprising one or more first data entries associated with the building material data source;
generate, via the processing device, a building material data entity based upon the first dataset associated with the building material data source; and
output, via the processing device, a representation of the building material data entity.

21. A computer program product for building material data management, the computer program product comprising a non-transitory computer-readable medium comprising code causing an apparatus to:
receive a first dataset comprising one or more first data entries associated with a building material data source;
generate a building material data entity based upon the first dataset associated with the building material data source; and
output a representation of the building material data entity.
